(19) United States
(12) Patent Application Publication
(10) Pub. No.: US 2024/0352047 A1
(43) Pub. Date: Oct. 24, 2024

(54) ORGANIC COMPOUND AND ORGANIC LIGHT-EMITTING DEVICE

(71) Applicant: CANON KABUSHIKI KAISHA, Tokyo (JP)

(72) Inventors: HIROKI OHRUI, Tokyo (JP); JUN KAMATANI, Tokyo (JP); HIRONOBU IWAWAKI, Kanagawa (JP); YOSUKE NISHIDE, Kanagawa (JP); NAOKI YAMADA, Tokyo (JP); HIROKAZU MIYASHITA, Miyagi (JP)

(21) Appl. No.: 18/752,426

(22) Filed: Jun. 24, 2024

Related U.S. Application Data
(63) Continuation of application No. PCT/JP2022/046015, filed on Dec. 14, 2022.

(30) Foreign Application Priority Data
Dec. 27, 2021 (JP) 2021-212264

(51) Int. Cl. C07F 5/02; C09K 11/06; H10K 85/40; H10K 85/60; H10K 101/30

(52) U.S. Cl. CPC C07F 5/027; C09K 11/06; H10K 85/40; H10K 85/615; H10K 85/633; H10K 85/654; H10K 85/6572; H10K 85/6576; H10K 85/658; H10K 2101/30

(57) ABSTRACT

The present disclosure provides an organic compound represented by any of the following general formulae [1-1] and [1-2]:

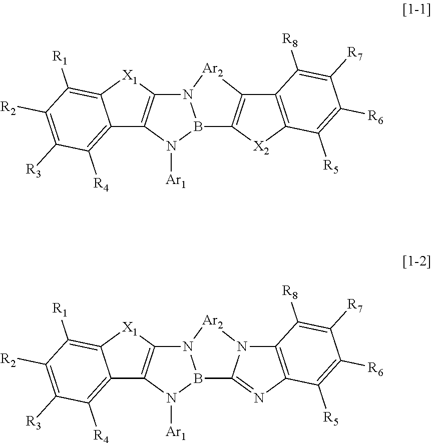

where R₁ to R₈ are each selected from a hydrogen atom, a halogen atom, a deuterium atom, and substituted or unsubstituted alkyl, alkoxy, amino, aryl, aryloxy, heteroaryl, cyano, and silyl groups, R₄ may be combined with Ar₁ to form a ring, Ar₁ is a substituted or unsubstituted aryl or heterocyclic group, Ar₂ is a substituted or unsubstituted divalent arylene group or divalent linking group, the divalent linking group being derived from a heterocyclic group, X₁ and X₂ are each selected from an oxygen atom, a sulfur atom, a selenium atom, a tellurium atom, and a nitrogen atom having substituent Z, and the substituent Z is a hydrogen atom, a deuterium atom, or a substituted or unsubstituted alkyl, aryl, or heteroaryl group.

### CROSS-REFERENCE TO RELATED APPLICATIONS

This application is a Continuation of International Patent Application No. PCT/JP2022/046015, filed Dec. 14, 2022, which claims the benefit of Japanese Patent Application No. 2021-212264, filed Dec. 27, 2021, both of which are hereby incorporated by reference herein in their entirety.

### TECHNICAL FIELD

The present invention relates to an organic compound and an organic light-emitting device containing the same.

### BACKGROUND ART

An organic light-emitting device (hereinafter, also referred to as an “organic electroluminescent device” or “organic EL device”) is an electronic device including a pair of electrodes and an organic compound layer disposed between these electrodes. The injection of electrons and holes from the pair of electrodes generates excitons of the light-emitting organic compound in the organic compound layer, and when the excitons return to the ground state, the organic light-emitting device emits light.

Recent progress in organic light-emitting devices has been remarkable, and their features include low driving voltage, various emission wavelengths, fast response time, and a contribution to enabling light-emitting apparatuses to be thinner and lighter.

In addition, sRGB and Adobe RGB standards have been used as color gamuts used for displays, and materials for reproducing them have been required. Recently, BT-2020 has been introduced as a standard for further expanding the color gamut.

Up to now, light-emitting organic compounds have been actively created. This is because the creation of a compound with excellent light emission characteristics is important in providing a high-performance organic light-emitting device. Patent Literature 1 describes the following compound 1-a.

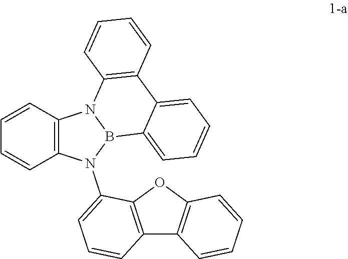 [SMILES: c1ccc2c(c1)B1N(c3ccccc3-2)c2ccccc2N1c1cccc2c1oc1ccccc12]

### CITATION LIST

### Patent Literature

PTL 1: U.S. Patent Application Publication No. 2016/0351811

Although the synthesis example of compound 1-a is disclosed in Patent Literature 1, there is no suggestion regarding luminous efficiency or emission color. In consideration of the color reproduction range of blue corresponding to sRGB, Adobe RGB, and BT2020 standards, it is desired to further improve the color purity of blue light emission. Further improvement in the color purity or durability characteristics of organic light-emitting devices using these compounds is desired.

### SUMMARY OF INVENTION

The present invention has been made in view of the above-described problems, and an object thereof is to provide a blue light-emitting material having excellent luminous efficiency, durability, and high color purity.

An organic compound of the present invention is characterized by being represented by any of the following general formulae [1-1] and [1-2].

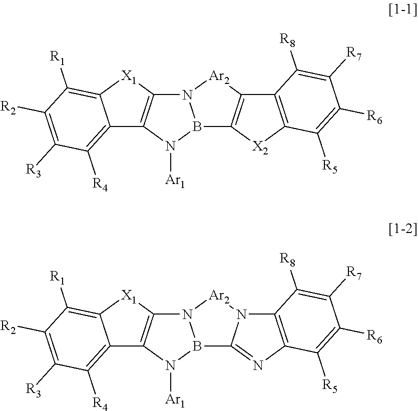

In formulae [1-1] and [1-2], R₁ to R₈ are each independently selected from a hydrogen atom, a halogen atom, a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a cyano group, a silyl group, and a deuterium atom, provided that R₄ may be combined with Ar₁ to form a ring.

Ar₁ is a substituted or unsubstituted aryl group or a substituted or unsubstituted heterocyclic group.

Ar₂ is a substituted or unsubstituted divalent arylene group or a substituted or unsubstituted divalent linking group derived from a heterocyclic group.

X₁ and X₂ are each independently selected from an oxygen atom, a sulfur atom, a selenium atom, a tellurium atom, and a nitrogen atom having a substituent Z, and the substituent Z is selected from a hydrogen atom, a substituted or unsubstituted alkyl group, a substituted or unsubstituted aryl group, a substituted or unsubstituted heteroaryl group, and a deuterium atom.

Further features of the present invention will become apparent from the following description of exemplary embodiments with reference to the attached drawings.

### BRIEF DESCRIPTION OF DRAWINGS

FIG. 1A is a schematic cross-sectional view of an example of a pixel of a display apparatus according to an embodiment of the present invention.

FIG. 1B is a schematic cross-sectional view of an example of a display apparatus including organic light-emitting devices according to an embodiment of the present invention.

FIG. 2A is a schematic view of an image-forming apparatus according to an embodiment of the present invention.

FIG. 2B is a schematic view illustrating a configuration of an exposure light source including multiple light-emitting portions arranged on a long substrate.

FIG. 2C is a schematic view illustrating a configuration of an exposure light source including multiple light-emitting portions arranged on a long substrate.

FIG. 3 is a schematic view of an example of a display apparatus according to an embodiment of the present invention.

FIG. 4A is a schematic view of an example of an image pickup apparatus according to an embodiment of the present invention.

FIG. 4B is a schematic view of an example of an electronic apparatus according to an embodiment of the present invention.

FIG. 5A is a schematic view of an example of a display apparatus according to an embodiment of the present invention.

FIG. 5B is a schematic view of an example of a foldable display apparatus.

FIG. 6A is a schematic view of an example of a lighting apparatus according to an embodiment of the present invention.

FIG. 6B is a schematic view of an example of an automobile including an automotive lighting unit according to an embodiment of the present invention.

FIG. 7A is a schematic view of an example of a wearable device according to an embodiment of the present invention.

FIG. 7B is a schematic view of an example of a wearable device according to an embodiment of the present invention, the wearable device including an image pickup apparatus.

### DESCRIPTION OF EMBODIMENTS

### Organic Compound

An organic compound of an embodiment of the present invention will be described. An organic compound of the present invention is an organic compound represented by any of the following general formulae [1-1] and [1-2].

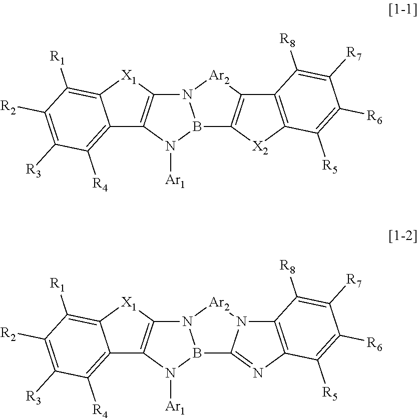

In formulae [1-1] and [1-2], R₁ to R₈ are each independently selected from a hydrogen atom, a halogen atom, a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a cyano group, a silyl group, and a deuterium atom, provided that R₄ may be combined with Ar₁ to form a ring.

Ar₁ is a substituted or unsubstituted aryl group or a substituted or unsubstituted heterocyclic group.

Ar₂ is a substituted or unsubstituted divalent arylene group or a substituted or unsubstituted divalent linking group derived from a heterocyclic group.

X₁ and X₂ are each independently selected from an oxygen atom, a sulfur atom, a selenium atom, a tellurium atom, and a nitrogen atom having a substituent Z, and the substituent Z is selected from a hydrogen atom, a substituted or unsubstituted alkyl group, a substituted or unsubstituted aryl group, a substituted or unsubstituted heteroaryl group, and a deuterium atom.

The halogen atom, the alkyl group, the alkoxy group, the amino group, the aryl group, the heteroaryl group, the aryloxy group, and the silyl group represented by R₁ to R₈ will be specifically described.

Examples of the halogen atom include, but are not limited to, a fluorine atom, a chlorine atom, a bromine atom, and an iodine atom.

Examples of the alkyl group include alkyl groups having 1 or more and 10 or less carbon atoms, such as a methyl group, an ethyl group, a n-propyl group, an isopropyl group, a n-butyl group, a tert-butyl group, a sec-butyl group, an octyl group, a cyclohexyl group, a 1-adamantyl group, and a 2-adamantyl group.

Examples of the alkoxy group include, but are not limited to, a methoxy group, an ethoxy group, a propoxy group, a 2-ethyloctyloxy group, and a benzyloxy group. Among these, an alkoxy group having 1 or more and 6 or less carbon atoms is preferred.

Examples of an amino group include, but are not limited to, an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-tert-butylphenyl)amino group, an N-phenyl-N-(4-trifluoromethylphenyl)amino group, and an N-piperidyl group.

Preferred examples of the aryl group include aryl groups having 6 or more and 18 or less carbon atoms, such as a phenyl group, a naphthyl group, an indenyl group, a biphenyl group, a terphenyl group, a fluorenyl group, a phenanthryl group, and a triphenylenyl group.

Preferred examples of the heteroaryl group include, but are not limited to, heteroaryl groups having 3 or more and 15 or less carbon atoms, such as a pyridyl group, a pyrazinyl group, a pyrimidinyl group, a triazinyl group, a quinolyl group, an isoquinolyl group, an oxazolyl group, a thiazolyl group, an imidazolyl group, a benzoxazolyl group, a benzothiazolyl group, a benzimidazolyl group, a thienyl group, a furanyl group, a pyrrolyl group, a benzothienyl group, a benzofuranyl group, an indolyl group, a dibenzothiophenyl group, and a dibenzofuranyl group.

Preferred examples of the aryloxy group include, but are not limited to, aryloxy groups having 6 to 18 carbon atoms, such as a phenoxy group and a thienyloxy group.

Examples of the silyl group include, but are not limited to, a trimethylsilyl group and a triphenylsilyl group.

Ar₁ and Ar₂ will be specifically described below.

Ar₁ is an aryl group or a heterocyclic group. The heterocyclic group is preferably a heteroaryl group. Ar₁ may be unsubstituted or substituted. Ar₁ is preferably an aryl group having 10 to 14 carbon atoms or a heteroaryl group having 5 to 12 carbon atoms.

Examples of the aryl group include a phenyl group, a naphthyl group, an indenyl group, a biphenyl group, a terphenyl group, a fluorenyl group, a phenanthryl group, and a triphenylenyl group. Among the aryl groups, a naphthyl group, a biphenyl group, or a phenanthryl group is particularly preferred.

Examples of the heteroaryl group include a pyridyl group, a pyrazinyl group, a pyrimidinyl group, a triazinyl group, a quinolyl group, an isoquinolyl group, an oxazolyl group, a thiazolyl group, an imidazolyl group, a benzoxazolyl group, a benzothiazolyl group, a benzimidazolyl group, a thienyl group, a furanyl group, a pyrrolyl group, a benzothienyl group, a benzofuranyl group, an indolyl group, a dibenzothiophenyl group, and a dibenzofuranyl group. Among the heteroaryl groups, a dibenzothienyl group, a pyridyl group, or an isoquinolyl group is preferred.

In each of formulae [1-1] and [1-2], R₄ may be combined with Ar₁ to form a ring serving as a divalent linking group.

Ar₂ is a divalent linking group derived from a divalent arylene or heterocyclic group. The heterocyclic group is preferably a heteroarylene group. Ar₂ may be unsubstituted or substituted. Ar₂ is preferably an arylene group having 6 to 12 carbon atoms or a heteroarylene group having 5 carbon atoms.

Examples of the arylene group include divalent linking groups derived from a phenyl group, a naphthyl group, an indenyl group, a biphenyl group, a terphenyl group, a fluorenyl group, a phenanthryl group, a triphenylenyl group, and so forth. Among the arylene groups, a divalent linking group derived from a phenyl group, a naphthyl group, or a biphenyl group is preferred.

Examples of the heteroarylene group include divalent linking groups derived from a pyridyl group, a pyrazinyl group, a pyrimidinyl group, a triazinyl group, a quinolyl group, an isoquinolyl group, an oxazolyl group, a thiazolyl group, an imidazolyl group, a benzoxazolyl group, a benzothiazolyl group, a benzimidazolyl group, a thienyl group, a furanyl group, a pyrrolyl group, a benzothienyl group, a benzofuranyl group, an indolyl group, a dibenzothiophenyl group, a dibenzofuranyl group, and so forth. Among the heteroarylene groups, a divalent linking group derived from a pyridyl group is preferred.

The case where X₁ and X₂ are each a nitrogen atom having substituent Z and where Z is an alkyl group, an aryl group, or a heteroaryl group will be specifically described below.

Preferred examples of the alkyl group include alkyl groups having 1 or more and 10 or less carbon atoms, such as a methyl group, an ethyl group, a n-propyl group, an isopropyl group, a n-butyl group, a tert-butyl group, a sec-butyl group, an octyl group, a cyclohexyl group, a 1-adamantyl group, and 2-adamantyl group.

Examples of the aryl group include aryl groups having 6 or more and 18 or less carbon atoms, such as a phenyl group, a naphthyl group, an indenyl group, a biphenyl group, a terphenyl group, a fluorenyl group, a phenanthryl group, and a triphenylenyl group.

The heteroaryl group is preferably a heteroaryl group having 3 or more and 15 or less carbon atoms. Examples thereof include a pyridyl group, a pyrazinyl group, a pyrimidinyl group, a triazinyl group, a quinolyl group, and an isoquinolyl group.

With regard to R₁ to R₈, Ar₁, Ar₂, and the substituent Z of X₁ and X₂, examples of substituents that may be further contained in the alkyl group, the alkoxy group, the amino group, the aryl group, the heteroaryl group, and the aryloxy group include, but are not limited to, alkyl groups, such as a methyl group, an ethyl group, a n-propyl group, an isopropyl group, a n-butyl group, and a tert-butyl group; aralkyl groups, such as a benzyl group; aryl groups, such as a phenyl group and a biphenyl group; amino groups, such as a dimethylamino group, a diethylamino group, a dibenzylamino group, a diphenylamino group, and a ditolylamino group; alkoxy groups, such as a methoxy group, an ethoxy group, and propoxy group; aryloxy groups, such as a phenoxy group; halogen atoms, such as fluorine, chlorine, bromine, and iodine; and a thienyl group and a thiol group.

A method for synthesizing an organic compound according to the present embodiment will be described below. Regarding the organic compound according to the present embodiment, for example, a compound represented by general formula [1-1] is synthesized according to the following synthesis route 1. A compound represented by general formula [1-2] is synthesized according to the following synthesis route 2.

### Synthesis Route 1

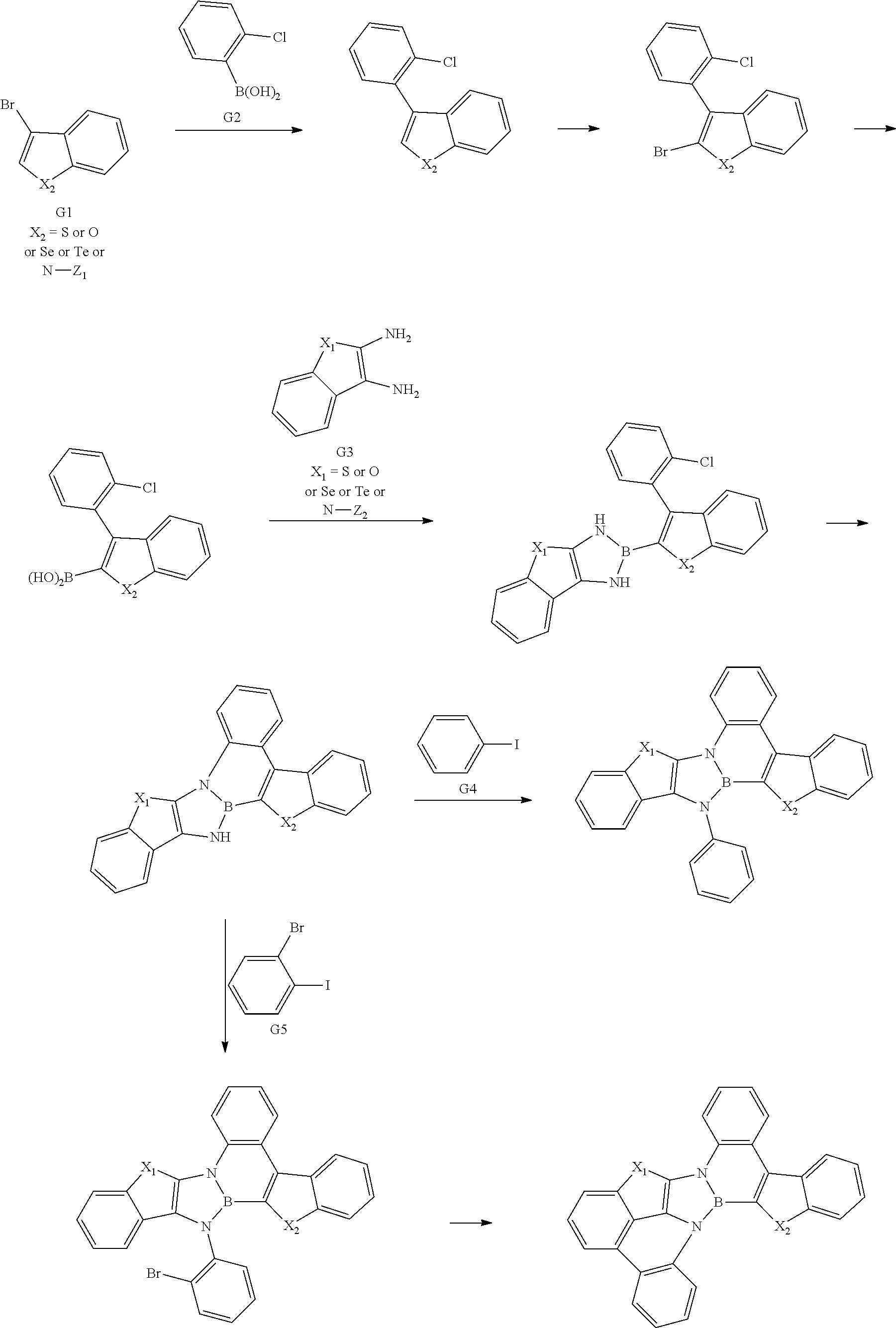

### Synthesis Route 2

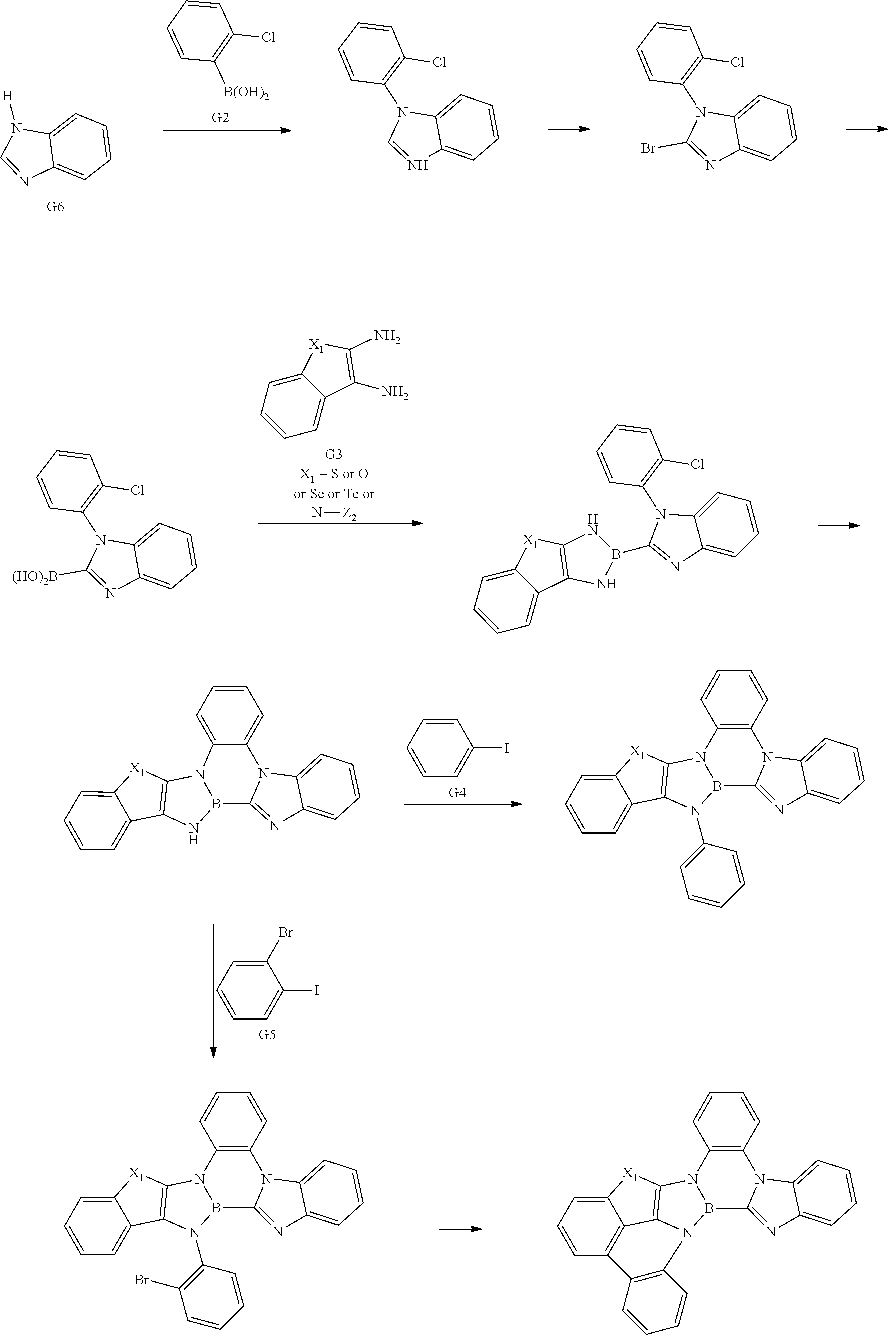

Compounds represented by general formulae [1-1 and [1-2] can be prepared by changing G1 to G6 as appropriate. The details of the synthesis method will be described in Examples.

The organic compound according to the present embodiment has the following features and thus is a compound that has high luminous efficiency, high color purity, a deep highest occupied molecular orbital (HOMO) level, and a deep lowest unoccupied molecular orbital (LUMO) level (far from the vacuum level), and that is stable against oxidation. Furthermore, when the organic compound according to the present embodiment is used, it is also possible to provide an organic light-emitting device having excellent color purity, luminous efficiency, and device durability.

(1) The emission wavelength of the basic skeleton itself is in the blue region, the oscillator strength is high, and the luminous efficiency is high.

(2) The organic compound has a low LUMO level and thus has high stability against oxygen, resulting in high durability.

Regarding these features, the characteristics of the basic skeleton of the organic compound according to the present embodiment will be described below while comparing with comparative compounds having structures similar to that of the organic compound according to the present embodiment. Specifically, the basic skeleton of comparative compound 1-a described in Patent Literature 1 is illustrated as comparative compound 1-b, and exemplified compounds A1 and B1 of the present embodiment are illustrated.

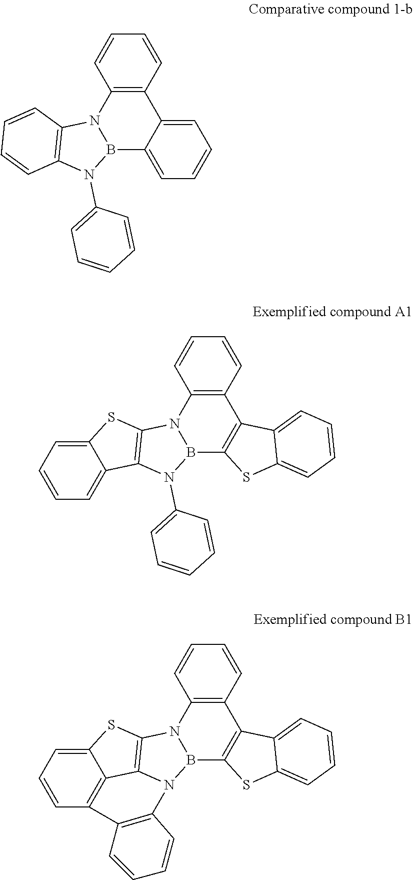 [SMILES: c1ccc(N2B3c4ccccc4-c4ccccc4N3c3ccccc32)cc1 ; c1ccc(N2B3c4sc5ccccc5c4-c4ccccc4N3c3sc4ccccc4c32)cc1 ; c1ccc2c(c1)-c1c(sc3ccccc13)B1N2c2sc3cccc4c3c2N1c1ccccc1-4]

(1) The emission wavelength of the basic skeleton itself is in the blue region, the oscillator strength is high, and the luminous efficiency is high.

The inventors have focused on the basic skeleton itself in the invention of the organic compounds represented by general formulae [1-1] and [1-2].

For blue light emission with high color purity, the emission wavelength of the basic skeleton itself needs to be in a blue region with high color purity. In the present embodiment, the desired emission wavelength region is a blue region with high color purity. Specifically, when the emission intensity at the maximum emission wavelength in a dilute solution is 1.0, the intensity ratio at 460 nm is 0.3 or more. The basic skeleton of the present embodiment is a skeleton suitable for desired blue light emission.

Table 1 presents the comparisons of the wavelengths of the lowest singlet excited states (S1) obtained by molecular orbital calculations and the emission spectra of exemplified compounds A1 and B1 according to the present embodiment and comparative compounds 1-a and 1-b in dilute toluene solutions. Specifically, after the emission spectra were measured, the emission intensity at 460 nm was compared when the maximum emission intensity was set to 1.0. The emission wavelength was measured by photoluminescence measurement of a dilute toluene solution with F-4500 manufactured by Hitachi, Ltd. at room temperature and at an excitation wavelength of 350 nm.

TABLE 1

| | | | PL intensity |
|---|---|---|---|
| | | S1 (cal.) | ratio |
| | Structural formula | [nm] | @460 nm |
| Exemplified compound A1 | 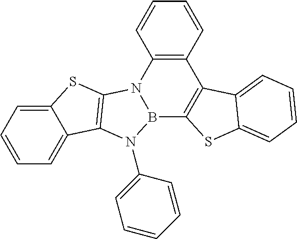 [SMILES: c1ccc(N2B3c4sc5ccccc5c4-c4ccccc4N3c3sc4ccccc4c32)cc1] | 376 | 0.7 |
| Exemplified compound B1 | 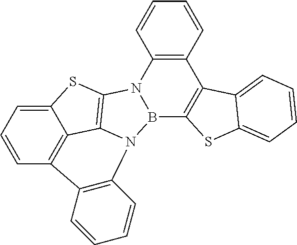 [SMILES: c1ccc2c(c1)-c1c(sc3ccccc13)B1N2c2sc3cccc4c3c2N1c1ccccc1-4] | 409 | 0.8 |
| Comparative compound 1-b | 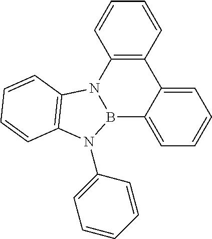 [SMILES: c1ccc(N2B3c4ccccc4-c4ccccc4N3c3ccccc32)cc1] | 318 | <0.1 |
| Comparative compound 1-a | 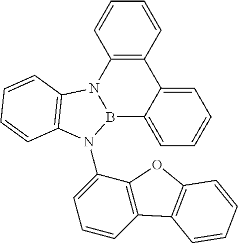 [SMILES: c1ccc2c(c1)B1N(c3ccccc3-2)c2ccccc2N1c1cccc2c1oc1ccccc12] | 329 | <0.1 |

Table 1 indicates that each diazaborole derivative having a fused-ring structure of the present embodiment has a longer S1 wavelength than comparative compounds 1-a and 1-b. Table 1 indicates that each diazaborole derivative having a fused-ring structure of the present embodiment has a longer S1 wavelength than comparative compounds 1-a and 1-b. The emission (PL) intensity at 460 nm, which is a wavelength required for a blue emission wavelength with high color purity, was <0.1 in comparative compounds 1-a and 1-b due to the shorter emission wavelength and 0.3 or more in the diazaborole derivatives having fused-ring structures according to the present embodiment. That is, each of the compounds according to the present embodiment has a longer emission wavelength and efficiently emits light in the blue region with high color purity.

As described above, it has been found that the diazaborole derivatives having the fused-ring structures exhibit highly efficient blue light emission with high color purity as a unique effect.

The electron orbital distributions of the HOMO and the LUMO and the S1 and Ti₁ energies were visualized by molecular orbital calculations. As the molecular orbital calculation method, the density functional theory (DFT), which is widely used at present, was used with the B3LYP functional and 6-31G* as the basis function. The molecular orbital calculation method was performed using Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010), which is widely used at present.

In this specification, hereinafter, the same method is employed for molecular orbital calculations.

(2) The organic compound has low LUMO level and thus has high stability against oxygen, resulting in high durability.

In organic semiconductors, in the case of compounds having similar band gaps, a compound having lower HOMO-LUMO levels (farther from the vacuum level) has higher stability against oxygen. Lowering the energy level of the LUMO increases the stability against oxygen, thereby improving the durability of the compound itself and the durability of the organic light-emitting device.

For this reason, the inventors have focused on LUMO. In Table 2, comparisons of the LUMO levels by molecular orbital calculations were made between exemplified compounds A1 and B1 according to the present embodiment and comparative compounds 1-a and 1-b.

TABLE 2

| | | LUMO | LUMO (cal.) |
|---|---|---|---|
| | | (cal.) | orbital |
| | Structural formula | [nm] | distribution |
| Exemplified compound A1 | 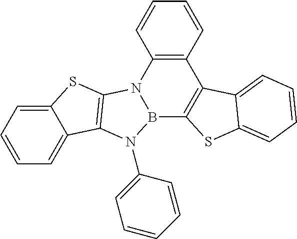 [SMILES: c1ccc(N2B3c4sc5ccccc5c4-c4ccccc4N3c3sc4ccccc4c32)cc1] | −1.29 | [symbol] |
| Exemplified compound B1 | 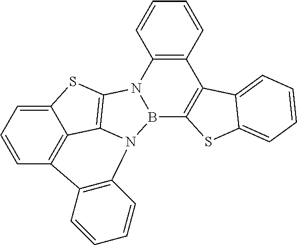 [SMILES: c1ccc2c(c1)-c1c(sc3ccccc13)B1N2c2sc3cccc4c3c2N1c1ccccc1-4] | −1.40 | [symbol] |
| Comparative compound 1-b | 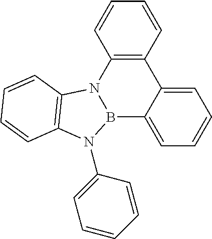 [SMILES: c1ccc(N2B3c4ccccc4-c4ccccc4N3c3ccccc32)cc1] | −0.93 | [symbol] |
| Comparative compound 1-a | 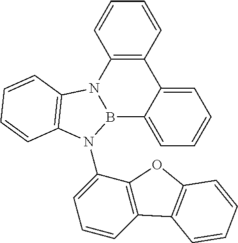 [SMILES: c1ccc2c(c1)B1N(c3ccccc3-2)c2ccccc2N1c1cccc2c1oc1ccccc12] | −0.92 | [symbol] |

From Table 2, it was found that, as compared with comparative compounds 1-b and 1-a, each of the diazaborole derivatives having fused-ring structures of the present embodiment is characterized in that the orbital distribution of LUMO extends not only in the long-axis direction of the molecule but also in the entire molecule, thereby extending the conjugation length and lowering the LUMO level (far from the vacuum level). That is, as a unique effect of the diazaborole derivatives having fused-ring structures, it was found that they have low LUMO levels and thus have high stability against oxygen, resulting in high device durability.

The LUMO level is greatly influenced by a boron atom having electron-withdrawing ability. A compound having higher electron-withdrawing ability has a lower LUMO level. Therefore, the diazaborole derivatives of the present invention in which the effect of the electron-withdrawing ability of the boron atom in the basic skeleton is conjugated with the orbital of the entire molecule has a lower LUMO level than comparative compounds 1-a and 1-b.

That is, as a unique effect of the diazaborole derivatives having fused-ring structures, it was found that they have low LUMO levels and thus have high stability against oxygen, resulting in high device durability.

As described above, since each of the organic compounds according to the present embodiment is a compound having the above-described characteristics (1) and (2), the organic compound exhibits high-efficiency blue light emission with high color purity and is a chemically stable compound having a large reduction potential, compared with the comparative compound. Therefore, when the organic compound according to the present embodiment is used, it is possible to provide an organic light-emitting device having excellent color purity, luminous efficiency, and device durability.

Preferred structures of the organic compounds represented by general formulae [1-1] and [1-2] are illustrated below in [1] to [11].

[1] An organic compound is represented by any of the following general formulae [2-1] and [2-2] and has a structure in which R₄ and Ar₁ are combined with each other in general formulae [1-1] and [1-2].

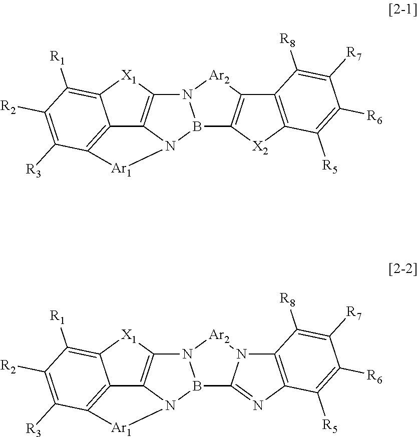

[2] An organic compound is represented by any of the following general formulae [3-1] and [3-2], in which in general formula [1-1] or [1-2], Ar₁ and Ar₂ are each a six-membered ring.

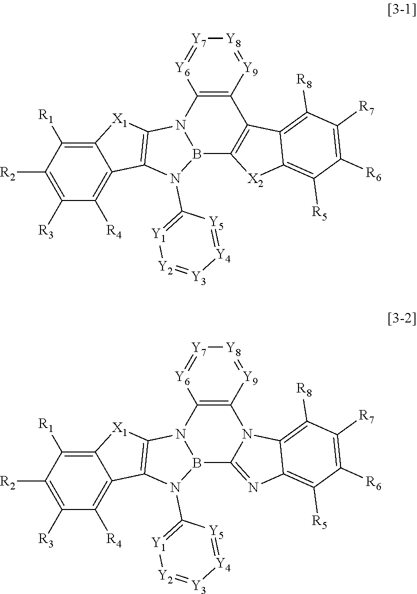

Y₁ to Y₉ are each independently a carbon atom or a nitrogen atom, each of the carbon atom and the nitrogen atom has a hydrogen atom or substituent W₁ and constitutes a ring, when adjacent elements are carbon atoms, these carbon atoms may further form a ring.

The substituent W₁ is selected from a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a cyano group, a silyl group, and a deuterium atom.

[3] An organic compound is represented by any of the following general formulae [4-1] and [4-2], in which in general formula [2-1] or [2-2] of [1], Ar₁ and Ar₂ are each a six-membered ring.

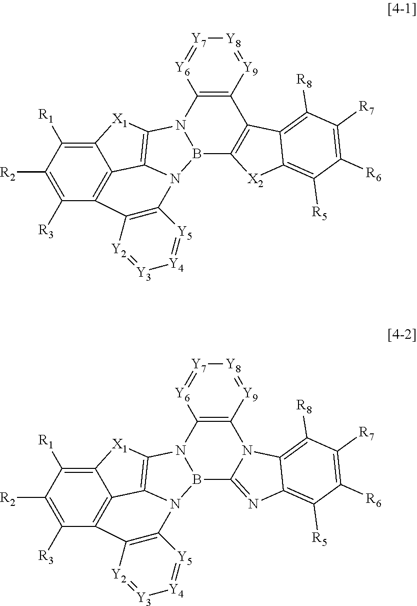

Y₂ to Y₉ are each independently a carbon atom or a nitrogen atom, and each of the carbon atom and the nitrogen atom has a hydrogen atom or substituent W₂ and constitutes a ring. When adjacent elements are carbon atoms, these carbon atoms may further form a ring.

The substituent W₂ is independently selected from a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a cyano group, a silyl group, and a deuterium atom.

(4) An organic compound is represented by any of the following general formulae [5-1] and [5-2], in which in general formula [1-1] or [1-2], Ar₁ is a five-membered ring, and Ar₂ is a six-membered ring.

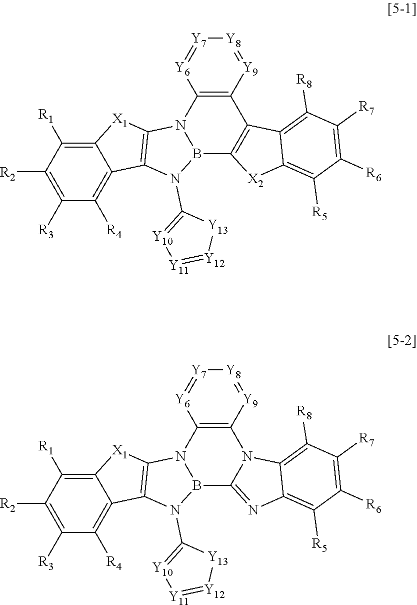

Y₆ to Y₉ are each independently a carbon atom or a nitrogen atom, and each of the carbon atom and the nitrogen atom has a hydrogen atom or substituent W₃ and constitutes a ring.

Y₁₀ to Y₁₃ are each a carbon atom, a nitrogen atom, an oxygen atom, or a sulfur atom, each of the carbon atom, the nitrogen atom, the oxygen atom, and the sulfur atom has a hydrogen atom or substituent Q₁ and constitutes a ring, one of Y₁₀ to Y₁₃ is the nitrogen atom, the oxygen atom, or the sulfur atom.

When adjacent elements of Y₆ to Y₁₃ are carbon atoms, these carbon atoms may further form a ring.

The substituents W₃ and Q₁ are each independently selected from a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a cyano group, a silyl group, and a deuterium atom.

[5] An organic compound is represented by any of the following general formulae [6-1] and [6-2], in which in general formula [1-1] or [1-2], Ar₁ and Ar₂ are each a five-membered ring.

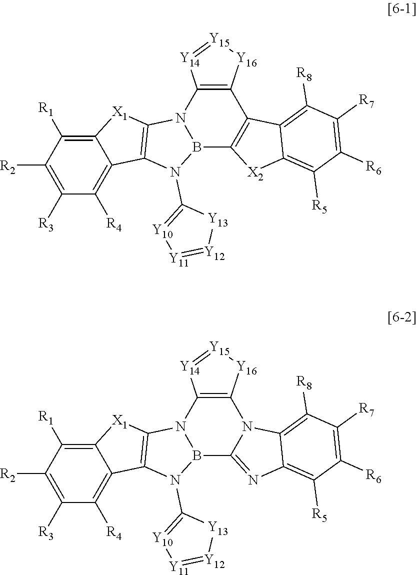

Y₁₀ to Y₁₆ are each independently a carbon atom, a nitrogen atom, an oxygen atom, or a sulfur atom, each of the carbon atom, the nitrogen atom, the oxygen atom, and the sulfur atom has a hydrogen atom or substituent Q₂ and constitutes a ring, and one of Y₁₀ to Y₁₃ and one of Y₁₄ to Y₁₆ are each the nitrogen atom, the oxygen atom, or the sulfur atom.

When adjacent elements of Y₁₀ to Y₁₆ are carbon atoms, these carbon atoms may further form a ring.

The substituent Q₂ is independently selected from a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a cyano group, a silyl group, and a deuterium atom.

[6] An organic compound is represented by the following general formula [7], in which X₁ and X₂ in general formula [3-1] of [2] are each a sulfur atom.

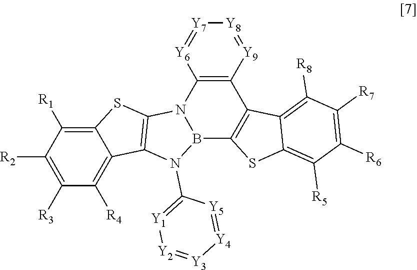

[7] An organic compound is represented by the following general formula [8], in which X₁ and X₂ in general formula [3-1] of [2] are each an oxygen atom.

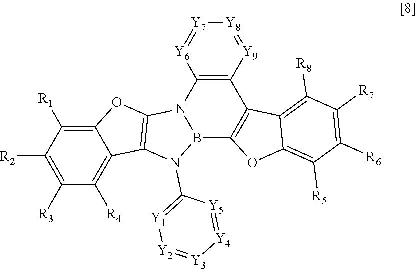

[8] An organic compound is represented by the following general formula [9], in which X₁ in general formula [3-1] of [2] is an oxygen atom, and X₂ is a nitrogen atom having substituent Z₁.

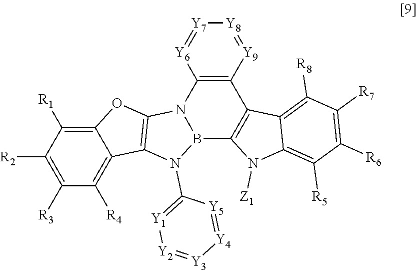

The substituent Z₁ is selected from a hydrogen atom, a substituted or unsubstituted alkyl group, a substituted or unsubstituted aryl group, a substituted or unsubstituted heteroaryl group, and a deuterium atom.

[9] An organic compound is represented by the following general formula [10], in which X₁ in general formula [3-2] of [2] is a sulfur atom.

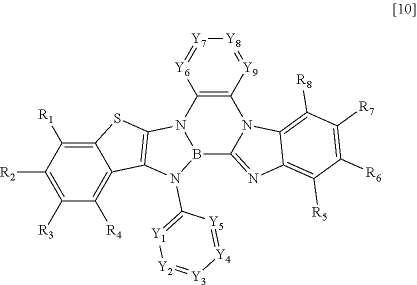

[10] An organic compound is represented by the following general formula [11], in which X₁ in general formula [3-2] of [2] is an oxygen atom.

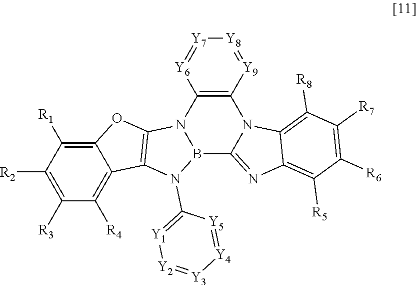

[11] An organic compound is represented by the following general formula [12], in which X₁ in general formula [3-2] of [2] is a nitrogen atom having substituent Z₂.

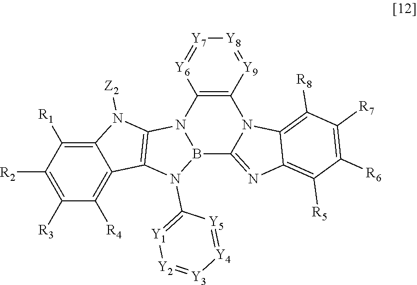

The substituent Z₂ is selected from a hydrogen atom, a substituted or unsubstituted alkyl group, a substituted or unsubstituted aryl group, a substituted or unsubstituted heteroaryl group, and a deuterium atom.

Regarding the substituents W₁, W₂, W₃, Q₁, Q₂, Z₁, and Z₂ in the preferred organic compounds of [1] to [11], examples of substituents that may be further contained in the alkyl group, the alkoxy group, the amino group, the aryl group, the aryloxy group, and the heteroaryl group include, but are not limited to, alkyl groups, such as a methyl group, an ethyl group, a n-propyl group, an isopropyl group, a n-butyl group, and a tert-butyl group; aralkyl groups, such as a benzyl group; aryl groups, such as a phenyl group and a biphenyl group; amino groups, such as a dimethylamino group, a diethylamino group, a dibenzylamino group, a diphenylamino group, and a ditolylamino group; alkoxy groups, such as a methoxy group, an ethoxy group, and propoxy group; aryloxy groups, such as a phenoxy group; halogen atoms, such as fluorine, chlorine, bromine, and iodine; and a thienyl group and a thiol group.

Specific examples of the organic compound according to the present embodiment are illustrated below. However, the present embodiment is not limited thereto.

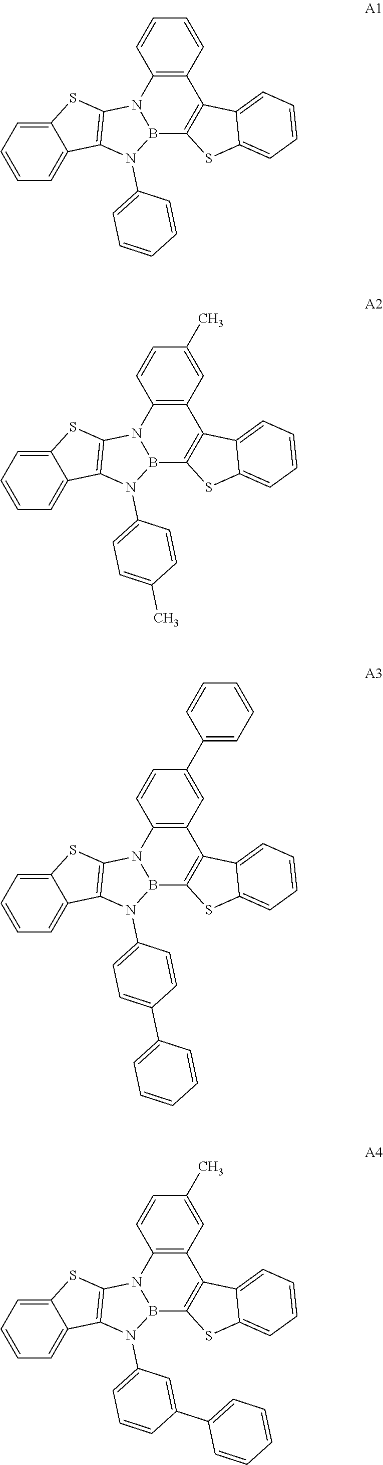 [SMILES: c1ccc(N2B3c4sc5ccccc5c4-c4ccccc4N3c3sc4ccccc4c32)cc1 ; Cc1ccc(N2B3c4sc5ccccc5c4-c4cc(C)ccc4N3c3sc4ccccc4c32)cc1 ; c1ccc(-c2ccc(N3B4c5sc6ccccc6c5-c5cc(-c6ccccc6)ccc5N4c4sc5ccccc5c43)cc2)cc1 ; Cc1ccc2c(c1)-c1c(sc3ccccc13)B1N2c2sc3ccccc3c2N1c1cccc(-c2ccccc2)c1]

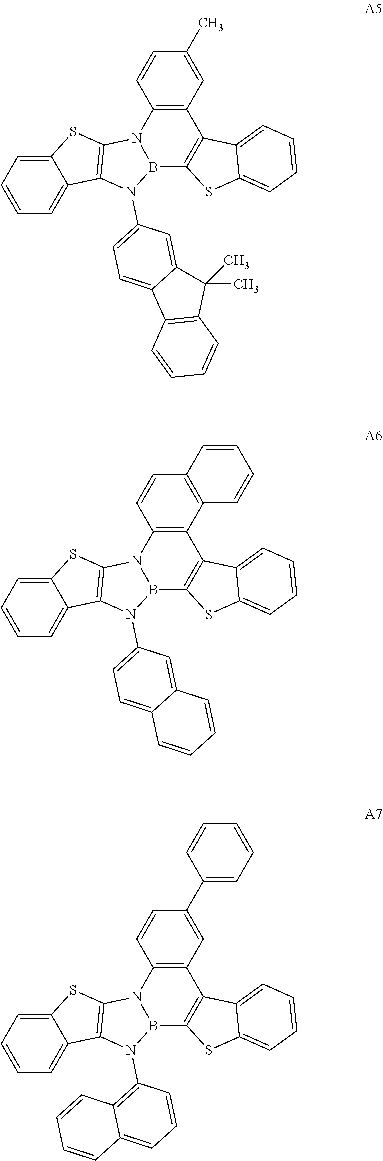 [SMILES: Cc1ccc2c(c1)-c1c(sc3ccccc13)B1N2c2sc3ccccc3c2N1c1ccc2c(c1)C(C)(C)c1ccccc1-2 ; c1ccc2cc(N3B4c5sc6ccccc6c5-c5c(ccc6ccccc56)N4c4sc5ccccc5c43)ccc2c1 ; c1ccc(-c2ccc3c(c2)-c2c(sc4ccccc24)B2N3c3sc4ccccc4c3N2c2cccc3ccccc23)cc1]

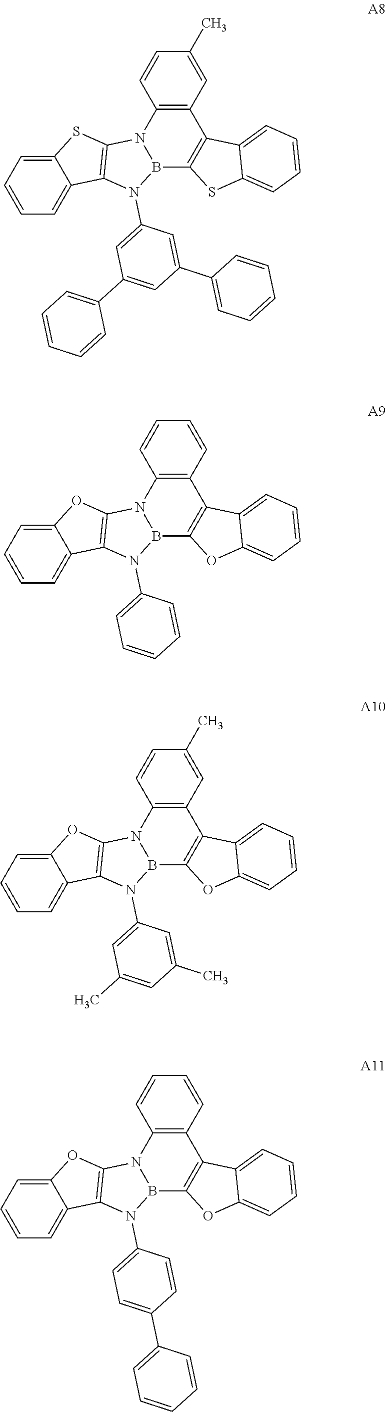 [SMILES: Cc1ccc2c(c1)-c1c(sc3ccccc13)B1N2c2sc3ccccc3c2N1c1cc(-c2ccccc2)cc(-c2ccccc2)c1 ; c1ccc(N2B3c4oc5ccccc5c4-c4ccccc4N3c3oc4ccccc4c32)cc1 ; Cc1cc(C)cc(N2B3c4oc5ccccc5c4-c4cc(C)ccc4N3c3oc4ccccc4c32)c1 ; c1ccc(-c2ccc(N3B4c5oc6ccccc6c5-c5ccccc5N4c4oc5ccccc5c43)cc2)cc1]

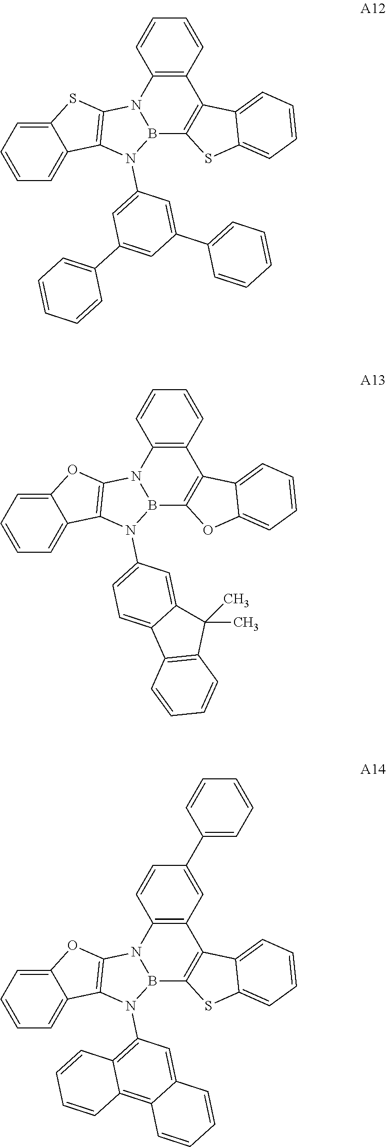 [SMILES: c1ccc(-c2cc(-c3ccccc3)cc(N3B4c5sc6ccccc6c5-c5ccccc5N4c4sc5ccccc5c43)c2)cc1 ; CC1(C)c2ccccc2-c2ccc(N3B4c5oc6ccccc6c5-c5ccccc5N4c4oc5ccccc5c43)cc21 ; c1ccc(-c2ccc3c(c2)-c2c(sc4ccccc24)B2N3c3oc4ccccc4c3N2c2cc3ccccc3c3ccccc23)cc1]

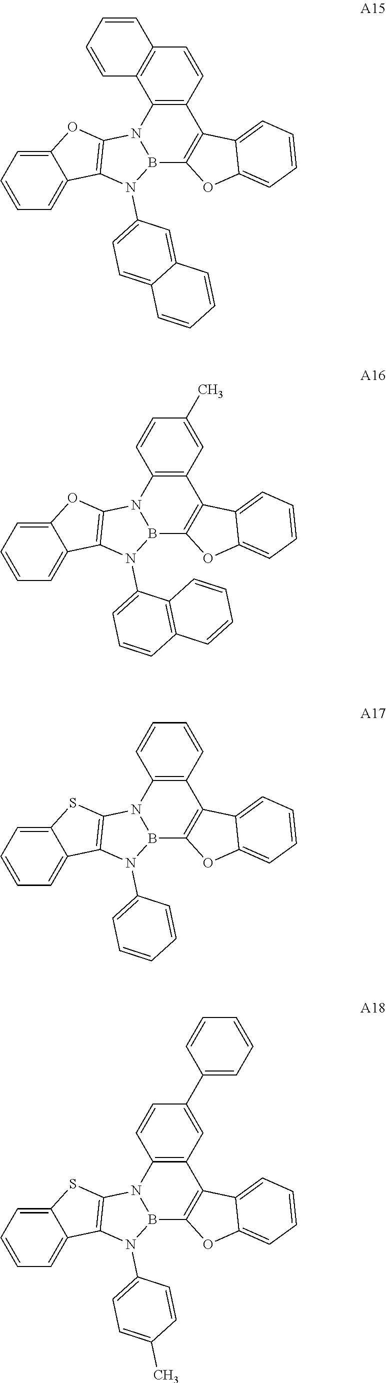 [SMILES: c1ccc2cc(N3B4c5oc6ccccc6c5-c5ccc6ccccc6c5N4c4oc5ccccc5c43)ccc2c1 ; Cc1ccc2c(c1)-c1c(oc3ccccc13)B1N2c2oc3ccccc3c2N1c1cccc2ccccc12 ; c1ccc(N2B3c4oc5ccccc5c4-c4ccccc4N3c3sc4ccccc4c32)cc1 ; Cc1ccc(N2B3c4oc5ccccc5c4-c4cc(-c5ccccc5)ccc4N3c3sc4ccccc4c32)cc1]

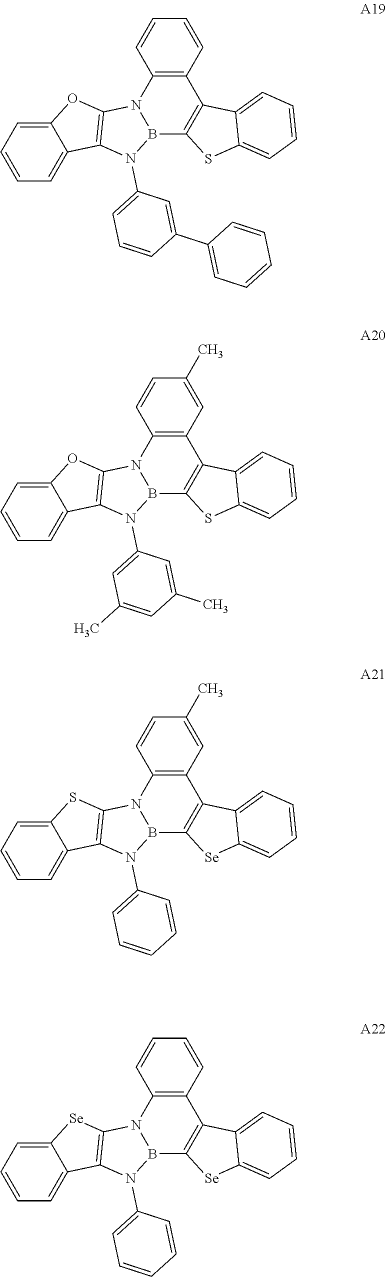 [SMILES: c1ccc(-c2cccc(N3B4c5sc6ccccc6c5-c5ccccc5N4c4oc5ccccc5c43)c2)cc1 ; Cc1cc(C)cc(N2B3c4sc5ccccc5c4-c4cc(C)ccc4N3c3oc4ccccc4c32)c1 ; Cc1ccc2c(c1)-c1c([se]c3ccccc13)B1N2c2sc3ccccc3c2N1c1ccccc1 ; c1ccc(N2B3c4[se]c5ccccc5c4-c4ccccc4N3c3[se]c4ccccc4c32)cc1]

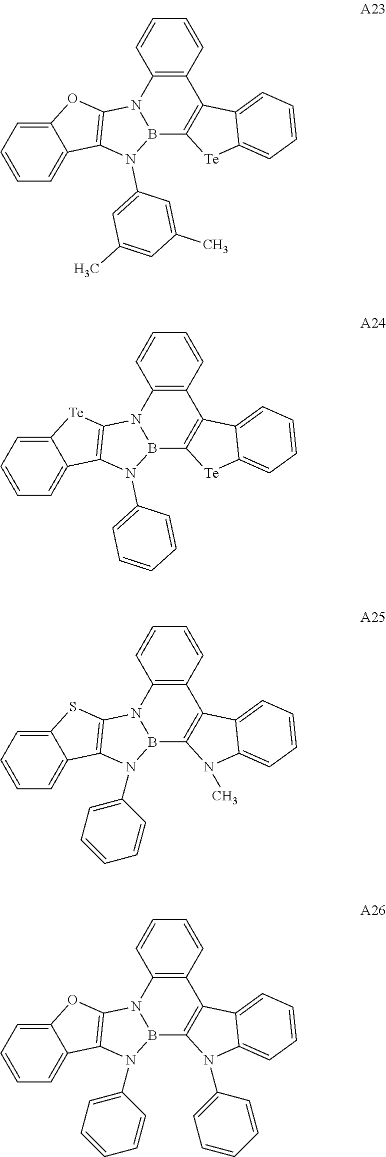

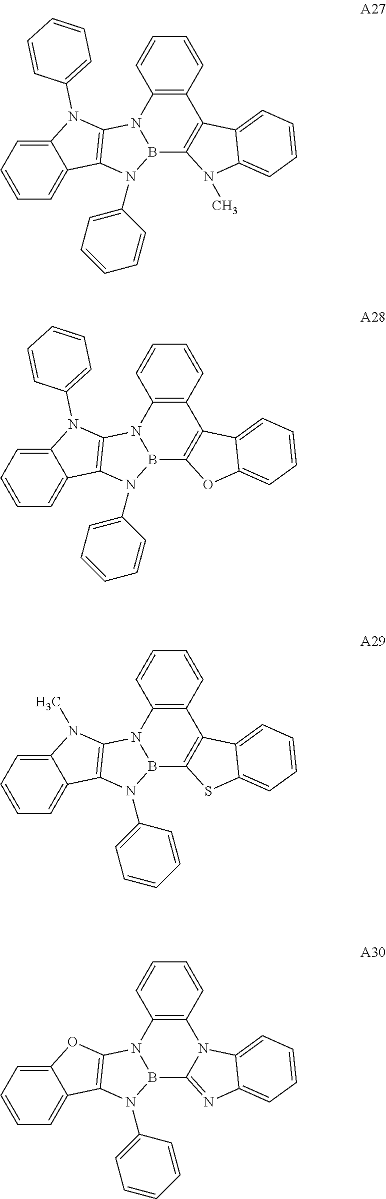 [SMILES: Cn1c2c(c3ccccc31)-c1ccccc1N1B2N(c2ccccc2)c2c1n(-c1ccccc1)c1ccccc21 ; c1ccc(N2B3c4oc5ccccc5c4-c4ccccc4N3c3c2c2ccccc2n3-c2ccccc2)cc1 ; Cn1c2c(c3ccccc31)N(c1ccccc1)B1c3sc4ccccc4c3-c3ccccc3N12 ; c1ccc(N2B3c4nc5ccccc5n4-c4ccccc4N3c3oc4ccccc4c32)cc1]

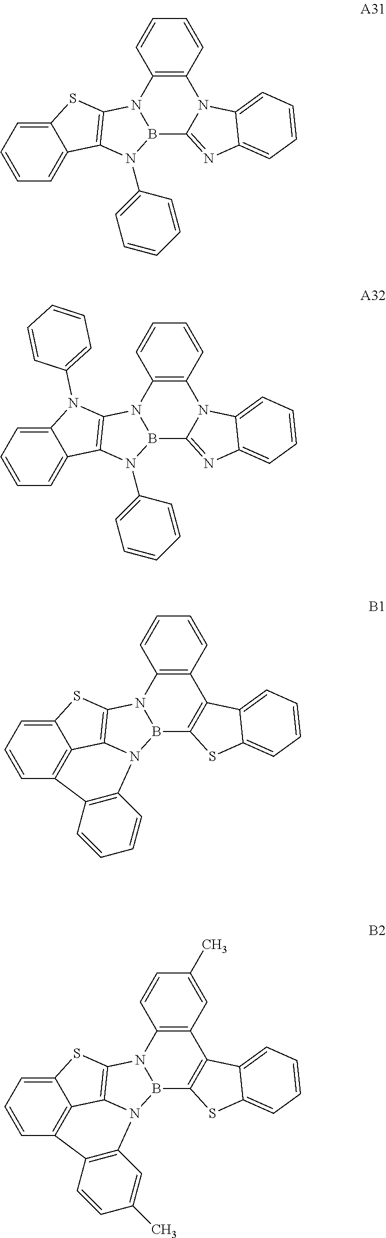 [SMILES: c1ccc(N2B3c4nc5ccccc5n4-c4ccccc4N3c3sc4ccccc4c32)cc1 ; c1ccc(N2B3c4nc5ccccc5n4-c4ccccc4N3c3c2c2ccccc2n3-c2ccccc2)cc1 ; c1ccc2c(c1)-c1c(sc3ccccc13)B1N2c2sc3cccc4c3c2N1c1ccccc1-4 ; Cc1ccc2c(c1)-c1c(sc3ccccc13)B1N2c2sc3cccc4c3c2N1c1cc(C)ccc1-4]

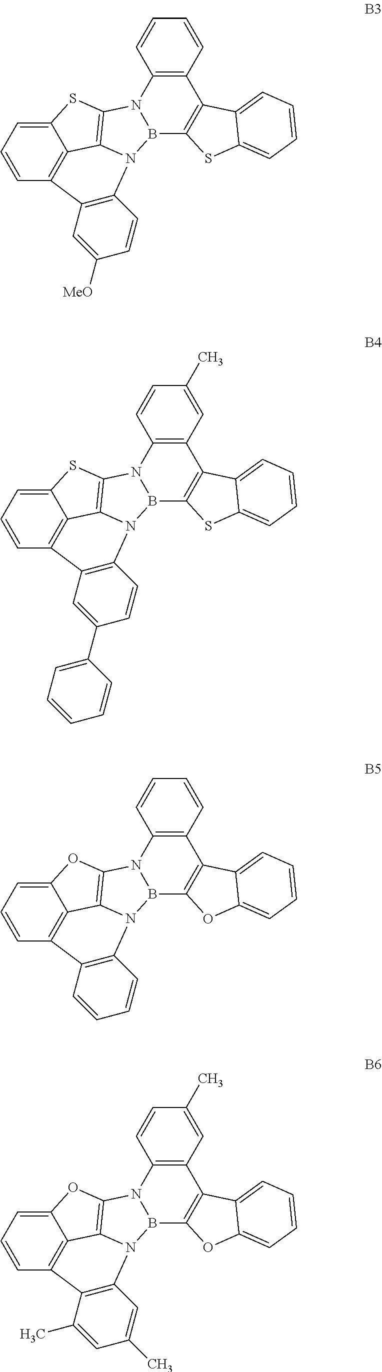 [SMILES: COc1ccc2c(c1)-c1cccc3sc4c(c13)N2B1c2sc3ccccc3c2-c2ccccc2N14 ; Cc1ccc2c(c1)-c1c(sc3ccccc13)B1N2c2sc3cccc4c3c2N1c1ccc(-c2ccccc2)cc1-4 ; c1ccc2c(c1)-c1c(oc3ccccc13)B1N2c2oc3cccc4c3c2N1c1ccccc1-4 ; Cc1ccc2c(c1)-c1c(oc3ccccc13)B1N2c2oc3cccc4c3c2N1c1cc(C)cc(C)c1-4]

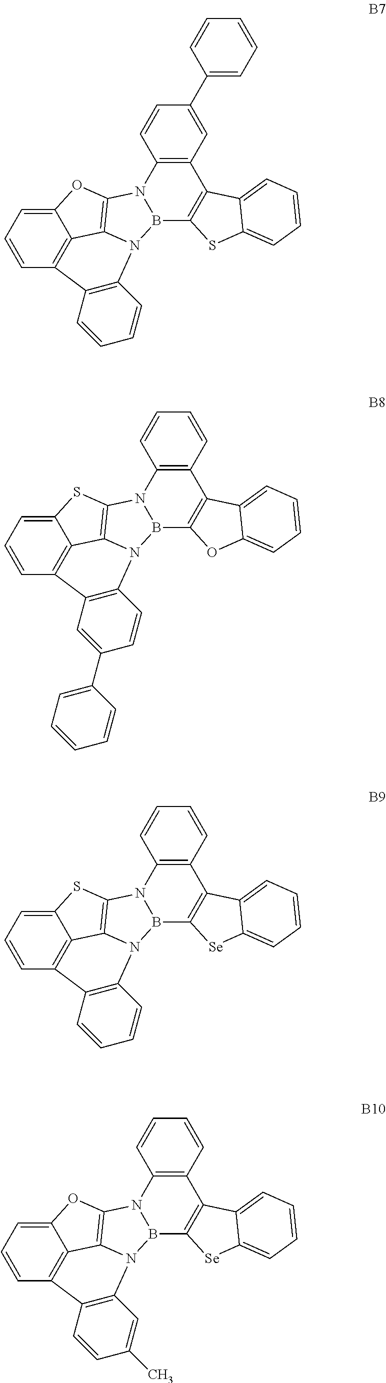 [SMILES: c1ccc(-c2ccc3c(c2)-c2c(sc4ccccc24)B2N3c3oc4cccc5c4c3N2c2ccccc2-5)cc1 ; c1ccc(-c2ccc3c(c2)-c2cccc4sc5c(c24)N3B2c3oc4ccccc4c3-c3ccccc3N25)cc1 ; c1ccc2c(c1)-c1c([se]c3ccccc13)B1N2c2sc3cccc4c3c2N1c1ccccc1-4 ; Cc1ccc2c(c1)N1B3c4[se]c5ccccc5c4-c4ccccc4N3c3oc4cccc-2c4c31]

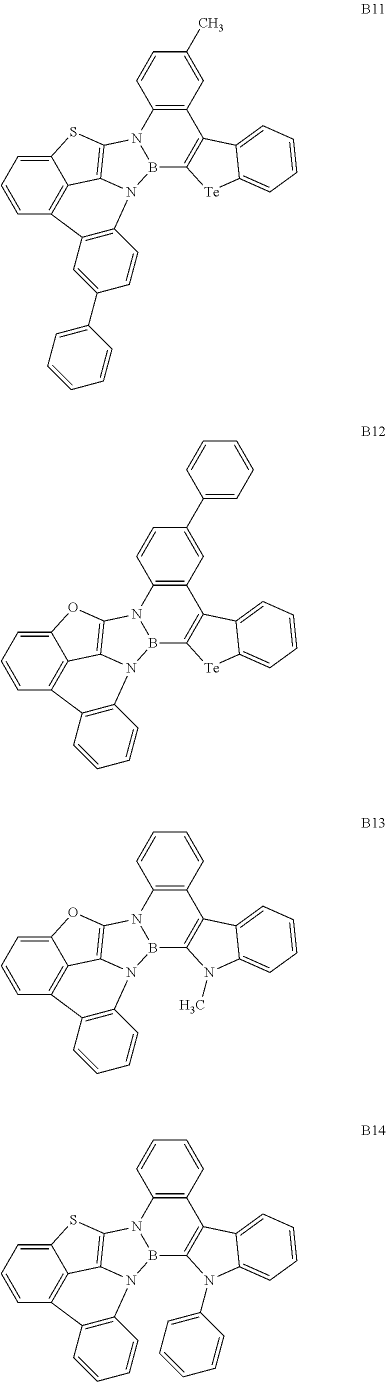

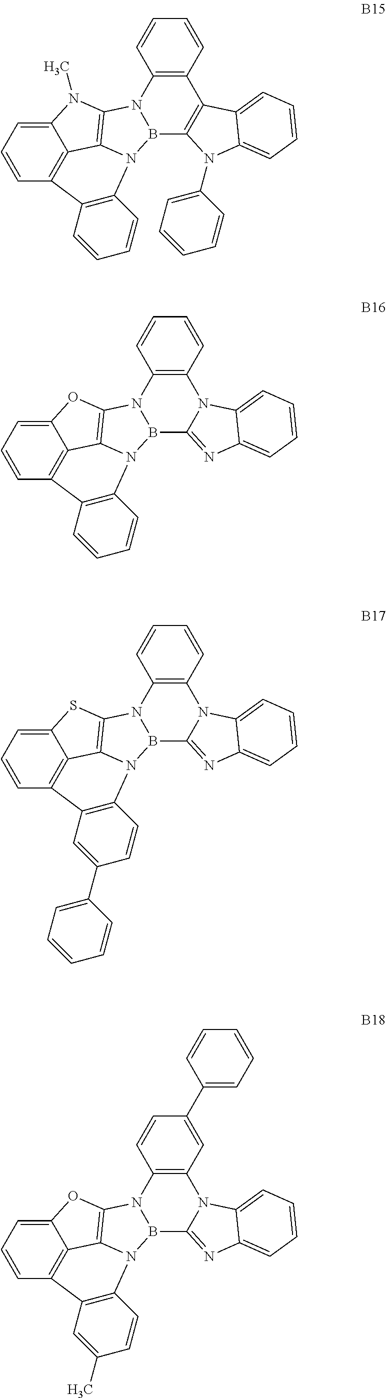 [SMILES: Cn1c2c3c4c(cccc41)-c1ccccc1N3B1c3c(c4ccccc4n3-c3ccccc3)-c3ccccc3N12 ; c1ccc2c(c1)-c1cccc3oc4c(c13)N2B1c2nc3ccccc3n2-c2ccccc2N14 ; c1ccc(-c2ccc3c(c2)-c2cccc4sc5c(c24)N3B2c3nc4ccccc4n3-c3ccccc3N25)cc1 ; Cc1ccc2c(c1)-c1cccc3oc4c(c13)N2B1c2nc3ccccc3n2-c2cc(-c3ccccc3)ccc2N14]

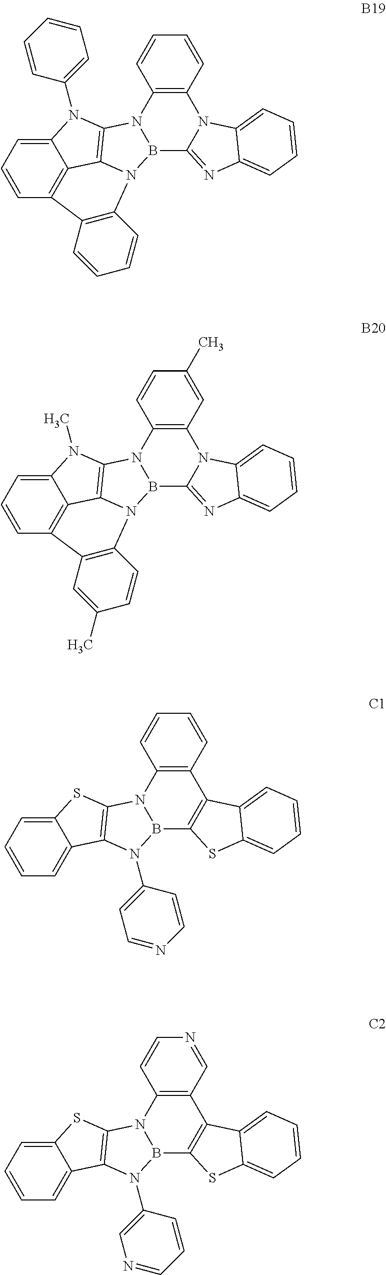 [SMILES: c1ccc(-n2c3c4c5c(cccc52)-c2ccccc2N4B2c4nc5ccccc5n4-c4ccccc4N23)cc1 ; Cc1ccc2c(c1)-c1cccc3c1c1c(n3C)N3B(c4nc5ccccc5n4-c4cc(C)ccc43)N21 ; c1ccc2c(c1)-c1c(sc3ccccc13)B1N2c2sc3ccccc3c2N1c1ccncc1 ; c1cncc(N2B3c4sc5ccccc5c4-c4cnccc4N3c3sc4ccccc4c32)c1]

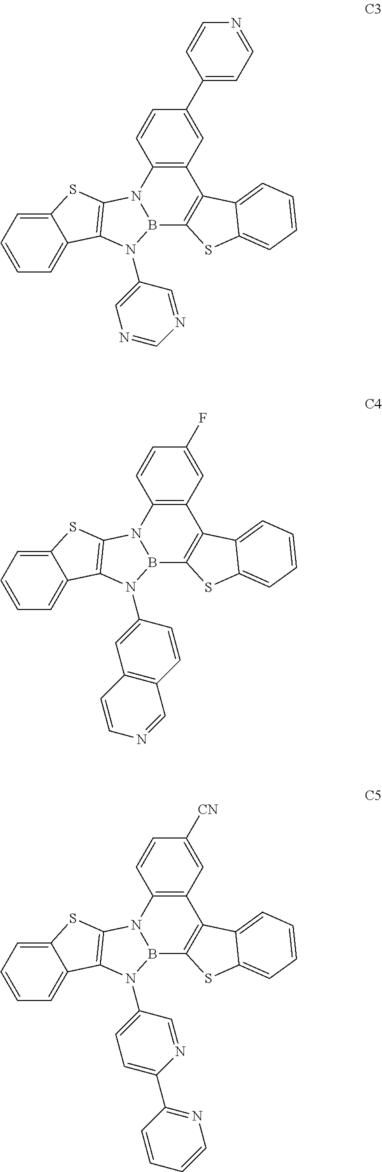 [SMILES: c1ccc2c3c(sc2c1)B1N(c2ccc(-c4ccncc4)cc2-3)c2sc3ccccc3c2N1c1cncnc1 ; Fc1ccc2c(c1)-c1c(sc3ccccc13)B1N2c2sc3ccccc3c2N1c1ccc2cnccc2c1 ; N#Cc1ccc2c(c1)-c1c(sc3ccccc13)B1N2c2sc3ccccc3c2N1c1ccc(-c2ccccn2)nc1]

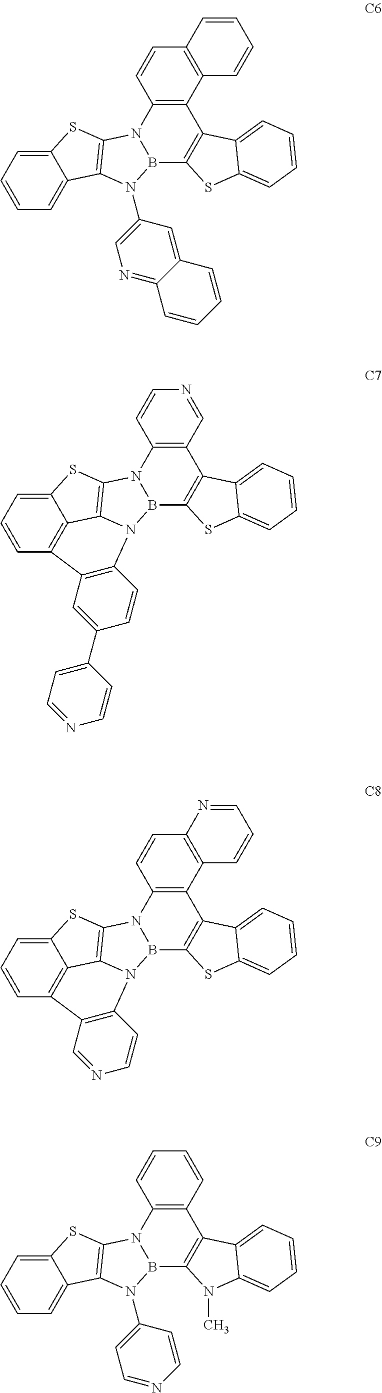 [SMILES: c1ccc2ncc(N3B4c5sc6ccccc6c5-c5c(ccc6ccccc56)N4c4sc5ccccc5c43)cc2c1 ; c1ccc2c3c(sc2c1)B1N(c2ccncc2-3)c2sc3cccc4c3c2N1c1ccc(-c2ccncc2)cc1-4 ; c1ccc2c3c(sc2c1)B1N(c2ccc4ncccc4c2-3)c2sc3cccc4c3c2N1c1ccncc1-4 ; Cn1c2c(c3ccccc31)-c1ccccc1N1B2N(c2ccncc2)c2c1sc1ccccc21]

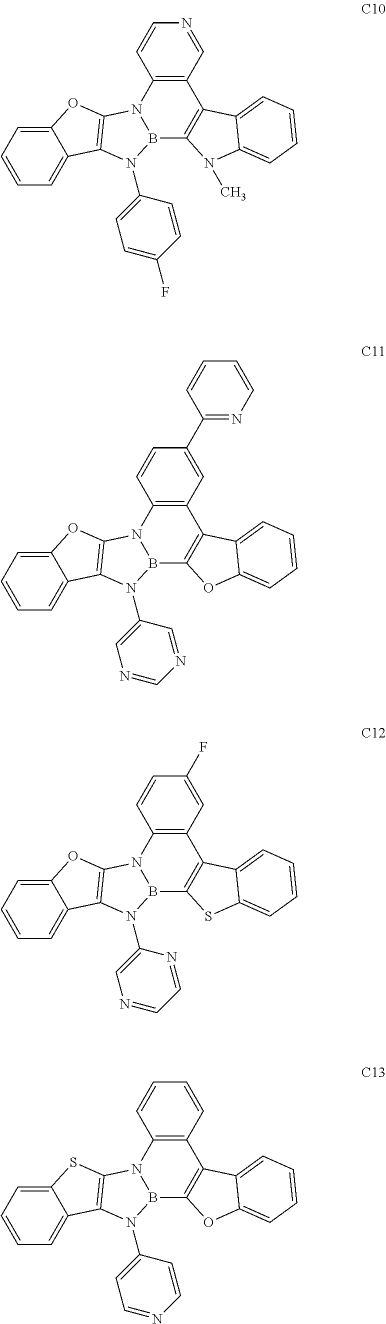 [SMILES: Cn1c2c(c3ccccc31)-c1cnccc1N1B2N(c2ccc(F)cc2)c2c1oc1ccccc21 ; c1ccc(-c2ccc3c(c2)-c2c(oc4ccccc24)B2N3c3oc4ccccc4c3N2c2cncnc2)nc1 ; Fc1ccc2c(c1)-c1c(sc3ccccc13)B1N2c2oc3ccccc3c2N1c1cnccn1 ; c1ccc2c(c1)-c1c(oc3ccccc13)B1N2c2sc3ccccc3c2N1c1ccncc1]

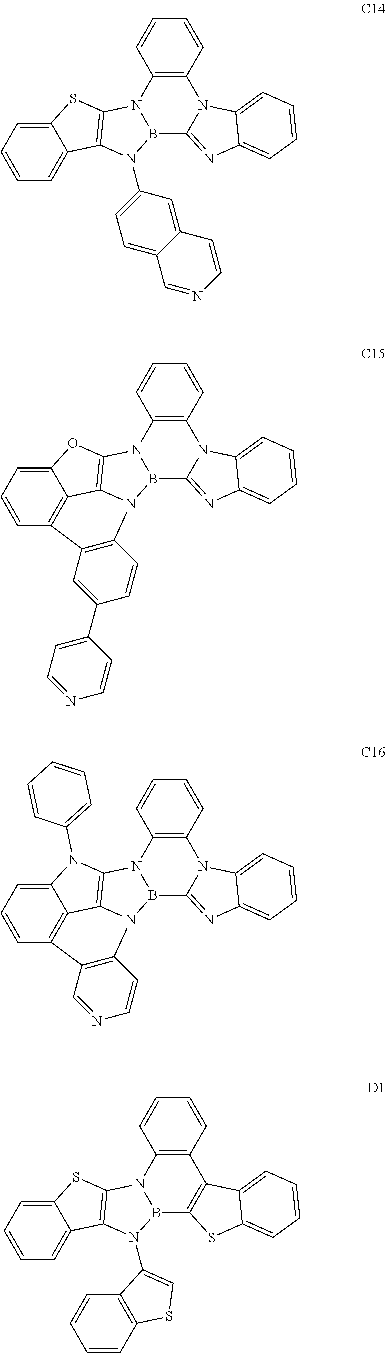 [SMILES: c1ccc2c(c1)N1B(c3nc4ccccc4n3-2)N(c2ccc3cnccc3c2)c2c1sc1ccccc21 ; c1ccc2c(c1)N1B(c3nc4ccccc4n3-2)N2c3ccc(-c4ccncc4)cc3-c3cccc4oc1c2c34 ; c1ccc(-n2c3c4c5c(cccc52)-c2cnccc2N4B2c4nc5ccccc5n4-c4ccccc4N23)cc1 ; c1ccc2c(c1)-c1c(sc3ccccc13)B1N2c2sc3ccccc3c2N1c1csc2ccccc12]

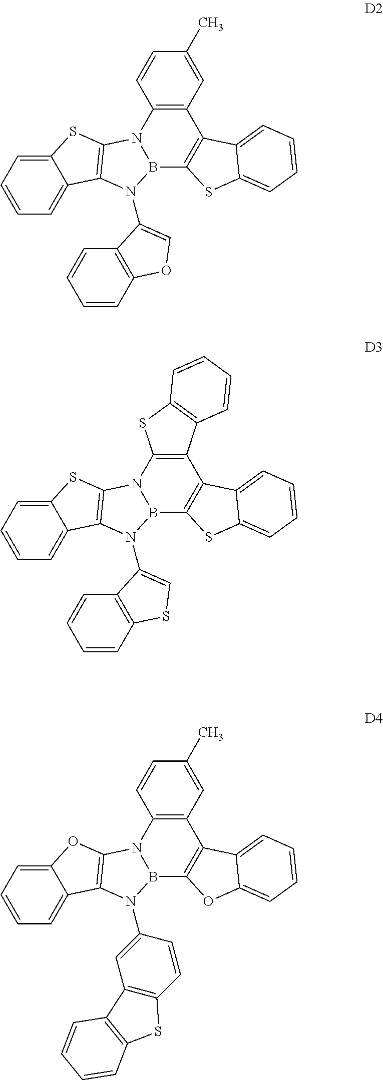 [SMILES: Cc1ccc2c(c1)-c1c(sc3ccccc13)B1N2c2sc3ccccc3c2N1c1coc2ccccc12 ; c1ccc2c(N3B4c5sc6ccccc6c5-c5c(sc6ccccc56)N4c4sc5ccccc5c43)csc2c1 ; Cc1ccc2c(c1)-c1c(oc3ccccc13)B1N2c2oc3ccccc3c2N1c1ccc2sc3ccccc3c2c1]

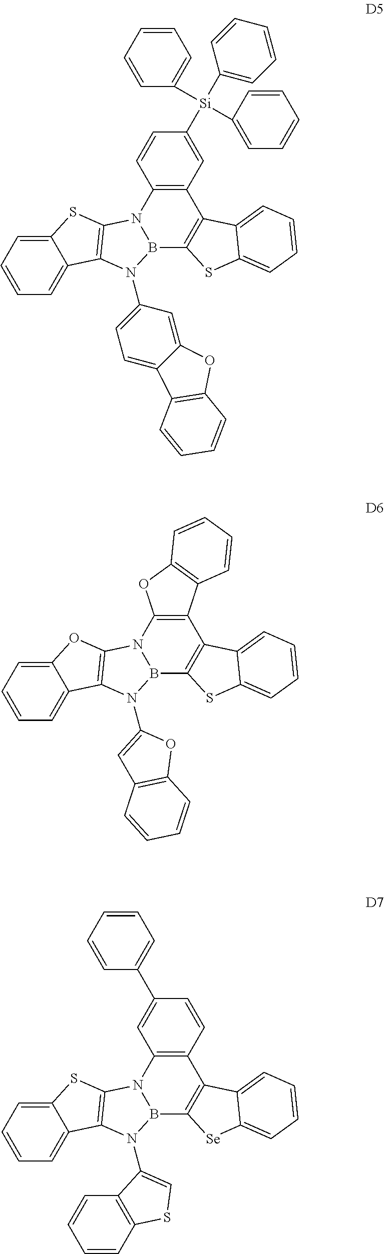 [SMILES: c1ccc([Si](c2ccccc2)(c2ccccc2)c2ccc3c(c2)-c2c(sc4ccccc24)B2N3c3sc4ccccc4c3N2c2ccc3c(c2)oc2ccccc23)cc1 ; c1ccc2oc(N3B4c5sc6ccccc6c5-c5c(oc6ccccc56)N4c4oc5ccccc5c43)cc2c1 ; c1ccc(-c2ccc3c(c2)N2B(c4[se]c5ccccc5c4-3)N(c3csc4ccccc34)c3c2sc2ccccc32)cc1]

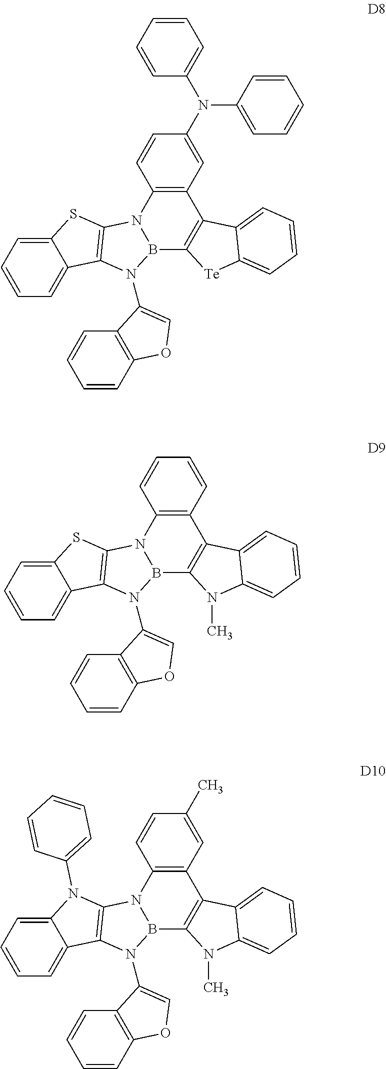

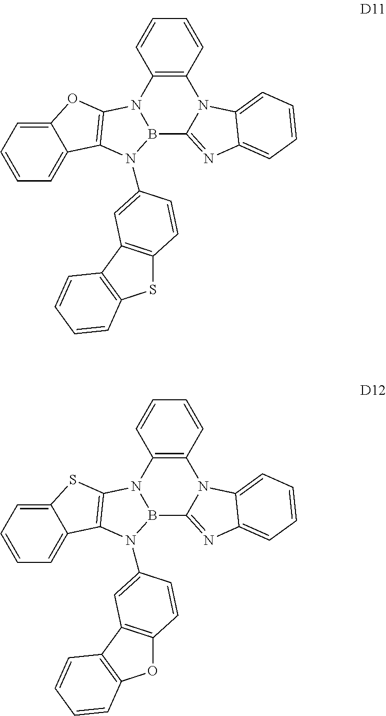 [SMILES: c1ccc2c(c1)N1B(c3nc4ccccc4n3-2)N(c2ccc3sc4ccccc4c3c2)c2c1oc1ccccc21 ; c1ccc2c(c1)N1B(c3nc4ccccc4n3-2)N(c2ccc3oc4ccccc4c3c2)c2c1sc1ccccc21]

Among the foregoing exemplified compounds, the compounds belonging to group A are compounds in which in formulae [1-1] and [1-2], each of the substituents Ar₁ and Ar₂ attached to the basic skeletons has an aryl group, such as a phenyl group, a biphenyl group, or a naphthyl group, or a divalent linking group derived from any of these substituents.

The compounds belonging to group A exhibit shorter-wavelength blue light emission and higher emission intensity among the compounds according to the present embodiment. That is, the compounds belonging to group A exhibit blue light emission with higher color purity and high luminous efficiency when used in light-emitting layers.

Among the foregoing exemplified compounds, the compounds belonging to group B are a group of compounds in which in formulae [1-1] and [1-2], each of the substituents Ar₁ and Ar₂ attached to the basic skeletons has an aryl group, such as a phenyl group, a biphenyl group, or a naphthyl group, or a divalent linking group derived from any of these substituents, and, furthermore, Ar₁ forms a ring with R₄, serving as a single bond, in formula [1-1] or [1-2]. Group B is a group of compounds which have increased thermal stability and high reducibility due to an increase in the number of fused-ring structures, and in which blue light emission and reduction potential can be finely adjusted.

Among the foregoing exemplified compounds, the compounds belonging to group C are compounds in which in formulae [1-1] and [1-2], each of the substituents Ar₁ and Ar₂ attached to the basic skeletons has a heteroaryl group, such as a pyridyl group, a pyrimidinyl group, or a quinolyl group, or a divalent linking group derived from any of these substituents. These heteroaryl groups have the properties of electron-withdrawing groups, and thus the compounds can have higher electron-accepting abilities and exhibit blue light emission with high color purity.

Among the foregoing exemplified compounds, the compounds belonging to group D are compounds in which each of the substituents Ar₁ and Ar₂ attached to the basic skeletons has a heteroaryl group, such as a benzofuranyl group, a dibenzofuranyl group, benzothienyl, or dibenzothiophenyl, or a divalent linking group derived from any of these substituents. Although the electron-accepting ability is reduced as compared with the substituents of group C, the compounds have improved Tg due to higher molecular weight and thus can have high thermal resistance and exhibit blue light emission with good color purity.

The organic compounds according to the present embodiment are compounds that exhibit light emission suitable for blue light emission with high efficiency and have high chemical stability. Accordingly, the use of such an organic compound according to the present embodiment as a constituent material for an organic light-emitting device enables the organic light-emitting device to have good light emission characteristics and superior durability characteristics.

### Organic Light-Emitting Device

An organic light-emitting device according to the present embodiment will be described below. The organic light-emitting device according to the present embodiment at least includes an anode and a cathode, which are a pair of electrodes, and an organic compound layer disposed between these electrodes. In the organic light-emitting device of the present embodiment, the organic compound layer may be formed of a single layer or a laminate including multiple layers, as long as it includes a light-emitting layer. When the organic compound layer is formed of a laminate including multiple layers, the organic compound layer may include, in addition to the light-emitting layer, a hole injection layer, a hole transport layer, an electron-blocking layer, a hole/exciton-blocking layer, an electron transport layer, and an electron injection layer, for example. The light-emitting layer may be formed of a single layer or a laminate including multiple layers.

In the organic light-emitting device according to the present embodiment, at least one layer in the organic compound layer contains the organic compound according to the present embodiment. Specifically, the organic compound according to the present embodiment is contained in any one of the light-emitting layer, the hole injection layer, the hole transport layer, the electron-blocking layer, the hole/exciton-blocking layer, the electron transport layer, the electron injection layer, and so forth. The organic compound according to the present embodiment is preferably contained in the light-emitting layer.

In the organic light-emitting device of the present embodiment, when the organic compound according to the present embodiment is contained in the light-emitting layer, the light-emitting layer may consist of only the organic compound according to the present embodiment or may be made of the organic compound according to the present embodiment and another compound. When the light-emitting layer is composed of the organic compound according to the present embodiment and another compound, the organic compound according to the present embodiment may be used, in the light-emitting layer, as a first compound (hereinafter, also referred to as a “host” or “host material”) or as a guest. When the organic compound according to the present invention is used as a guest, the light-emitting layer may contain a first compound. The organic compound may be used as a second compound (hereinafter, also referred to as an “assist” or “assist material”) that can be contained in the light-emitting layer. The term “host” used here refers to a compound having the highest proportion by mass in compounds contained in the light-emitting layer. The term “guest” refers to a compound that has a lower proportion by mass than the host in the compounds contained in the light-emitting layer and that is responsible for main light emission. The term “assist material” refers to a compound that has a lower proportion by mass than the host in the compounds contained in the light-emitting layer and that assists the light emission of the guest. The assist material is also referred to as a second host.

When the organic compound according to the present embodiment is used as a guest in the light-emitting layer, the concentration of the guest is preferably 0.01% or more by mass and 20% or less by mass, more preferably 0.1% or more by mass and 5% or less by mass, based on the entire light-emitting layer.

When the organic compound according to the present embodiment is used as a guest in the light-emitting layer, a material having a higher LUMO level than the organic compound according to the present embodiment (a material having a LUMO level closer to the vacuum level) can be used as a host. This is because when a material having a higher LUMO level than the organic compound according to the present embodiment is used as a host, the organic compound according to the embodiment can receive more electrons supplied to the host of the light-emitting layer. In particular, the organic compounds represented by general formulae [1-1] and [1-2] each have a high electron-accepting ability, that is, a low LUMO level. This is because when a material having a higher LUMO level than the organic compounds represented by general formulae [1-1] and [1-2] is used as a host, the organic compound according to the present embodiment can receive more electrons supplied to the host of the light-emitting layer.

The inventors have conducted various studies and have found that when the organic compound according to the present embodiment is used as a host or guest of a light-emitting layer, especially as a guest of a light-emitting layer, a device that emits light with high efficiency and high luminance and that is extremely durable can be provided. This light-emitting layer can be formed of a single layer or multiple layers and can also contain a light-emitting material having another emission color in order to conduct the color mixture of the blue emission color of the present embodiment and another emission color. The term “multiple layers” refers to a state in which the first light-emitting layer and the second light-emitting layer are stacked. In this case, the emission color of the organic light-emitting device is not limited to blue. More specifically, the emission color may be white or intermediate color. In the case of white, the second light-emitting layer emits light of a color other than blue, that is, red or green. Regarding a film-forming method, a film is formed by vapor deposition or a coating method. The details thereof will be described in Examples below.

The organic compound according to the present embodiment can be used as a constituent material of an organic compound layer other than the light-emitting layer included in the organic light-emitting device of the present embodiment. Specifically, the organic compound may be used as a constituent material for the electron transport layer, the electron injection layer, the hole transport layer, the hole injection layer, the hole-blocking layer, and so forth. In this case, the emission color of the organic light-emitting device is not limited to blue. More specifically, the emission color may be white or intermediate color.

For example, a hole injection compound, a hole transport compound, a compound to be used as a host, a light-emitting compound, an electron injection compound, or an electron transport compound, which is known and has a low or high molecular weight, can be used together with the organic compound according to the present embodiment, as needed. Examples of these compounds will be illustrated below.

As a hole injection-transport material, a material having a high hole mobility is preferably used so as to facilitate the injection of holes from the anode and to transport the injected holes to the light-emitting layer. To reduce a deterioration in film quality, such as crystallization, in the organic light-emitting device, a material having a high glass transition temperature is preferred. Examples of a low- or high-molecular-weight material having the ability to inject and transport holes include triarylamine derivatives, aryl carbazole derivatives, phenylenediamine derivatives, stilbene derivatives, phthalocyanine derivatives, porphyrin derivatives, poly(vinyl carbazole), polythiophene, and other conductive polymers. Moreover, the hole injection-transport material is also suitably used for the electron-blocking layer. Specific examples of a compound used as the hole injection-transport material are illustrated below, but of course, the compound is not limited thereto.

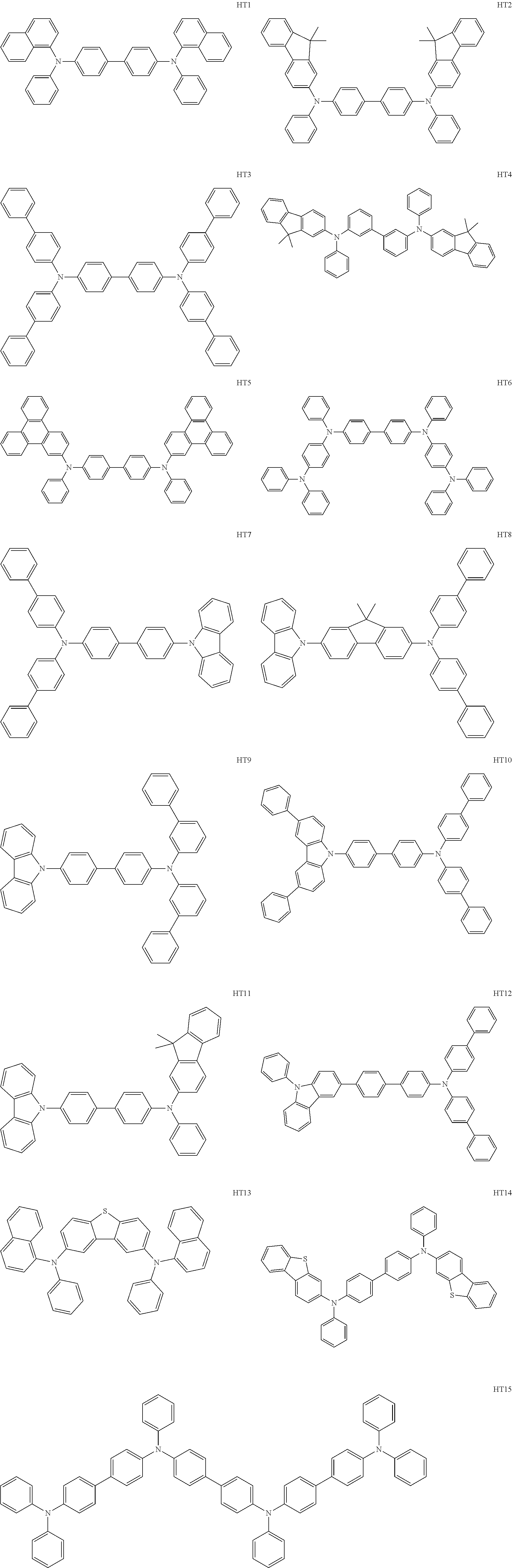

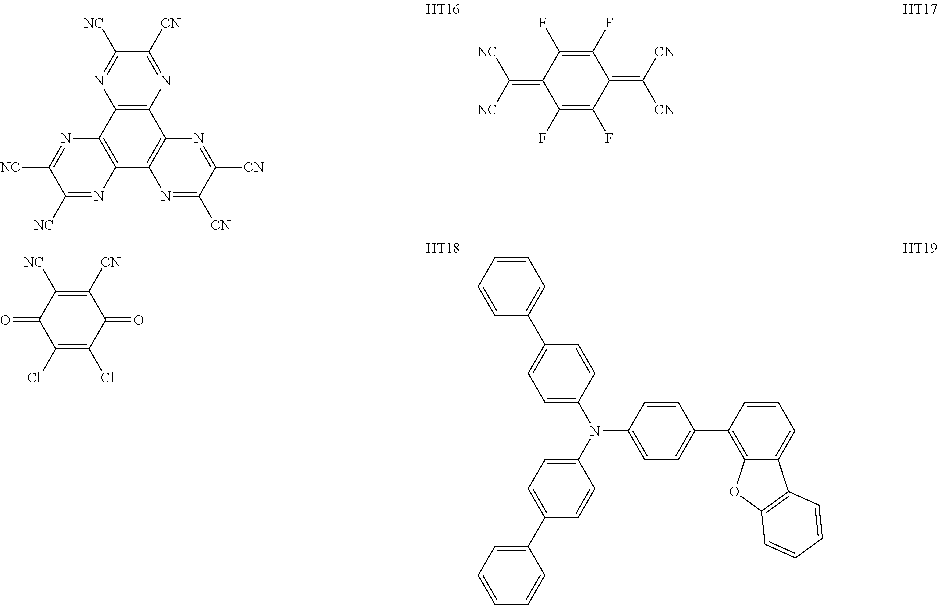

Examples of the light-emitting material mainly related to the light-emitting function include, in addition to the organic compounds represented by general formulae [1-1] and [1-2], fused-ring compounds (such as fluorene derivatives, naphthalene derivatives, pyrene derivatives, perylene derivatives, tetracene derivatives, anthracene derivatives, and rubrene), quinacridone derivatives, coumarin derivatives, stilbene derivatives, organoaluminum complexes, such as tris(8-quinolinolato)aluminum, iridium complexes, platinum complexes, rhenium complexes, copper complexes, europium complexes, ruthenium complexes, and polymer derivatives, such as poly(phenylene vinylene) derivatives, polyfluorene derivatives, and polyphenylene derivatives. Specific examples of a compound used as a light-emitting material are illustrated below, but of course, the light-emitting material is not limited thereto.

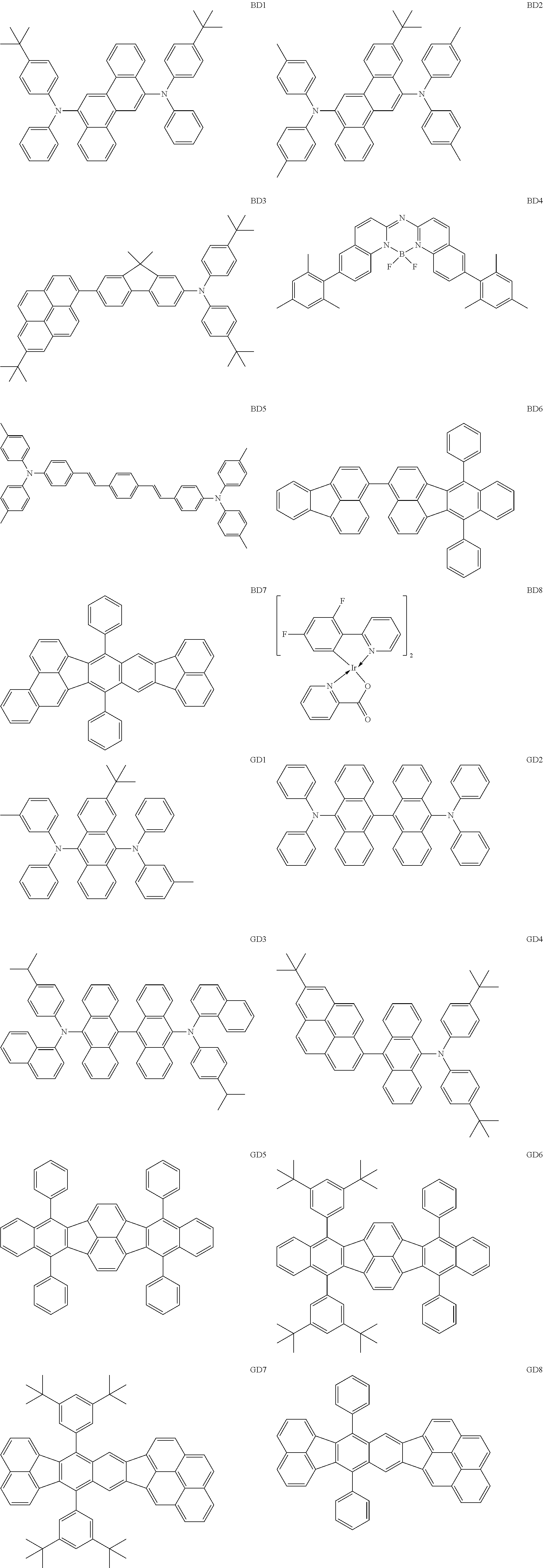

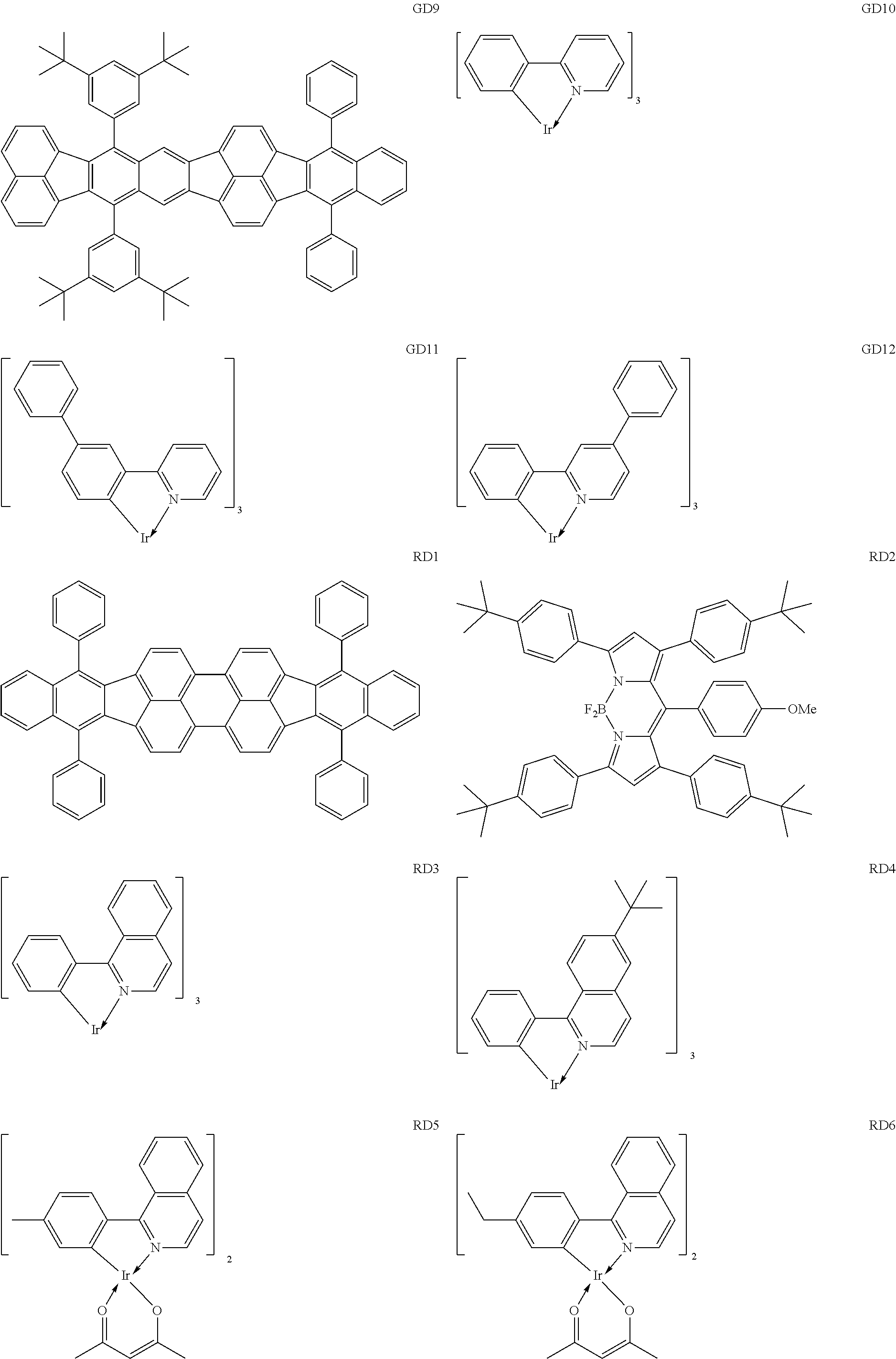

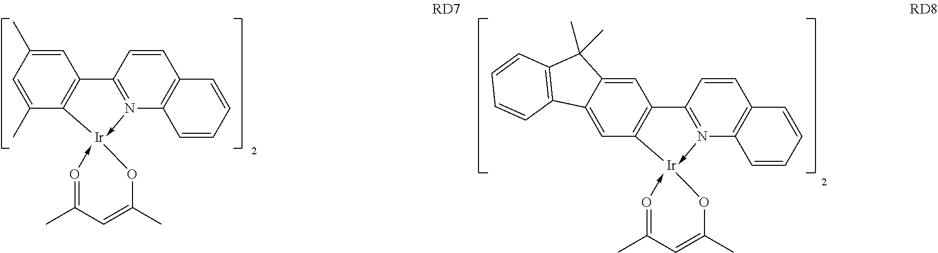

Examples of a light-emitting layer host or a light-emission assist material in the light-emitting layer include aromatic hydrocarbon compounds and derivatives thereof, carbazole derivatives, dibenzofuran derivatives, dibenzothiophene derivatives, organoaluminum complexes, such as tris(8-quinolinolato)aluminum, and organoberyllium complexes. Specific examples of the compound for the light-emitting layer host or light-emission assist material contained in the light-emitting layer are illustrated below, but of course, the compound is not limited thereto. In the organic light-emitting device according to the present invention, the host material is preferably a hydrocarbon compound, more preferably a hydrocarbon compound containing a fused polycyclic group having three or more rings, and particularly preferably a hydrocarbon compound having at least one of an anthracene skeleton, a fluoranthene skeleton, and a triphenylene skeleton.

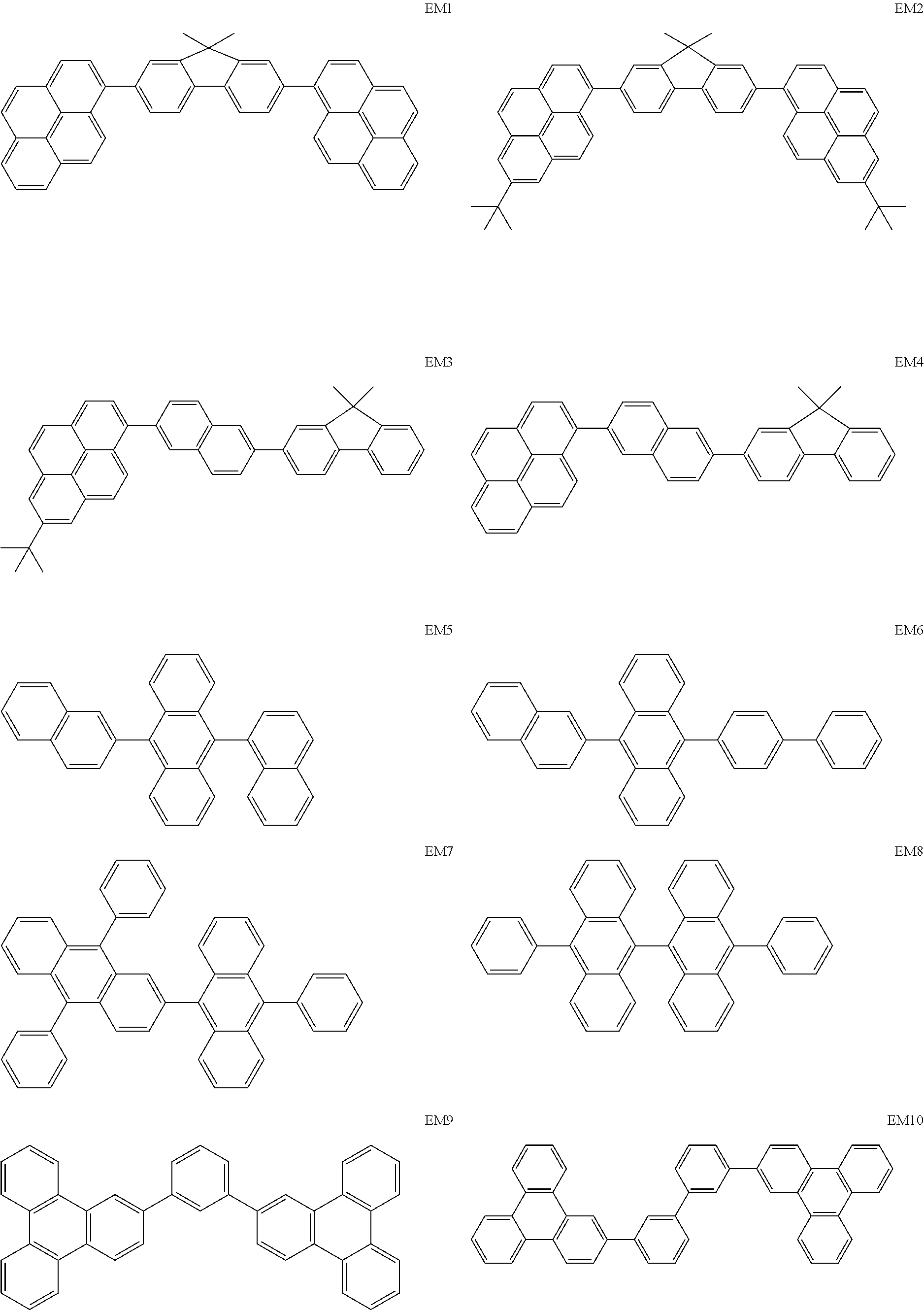

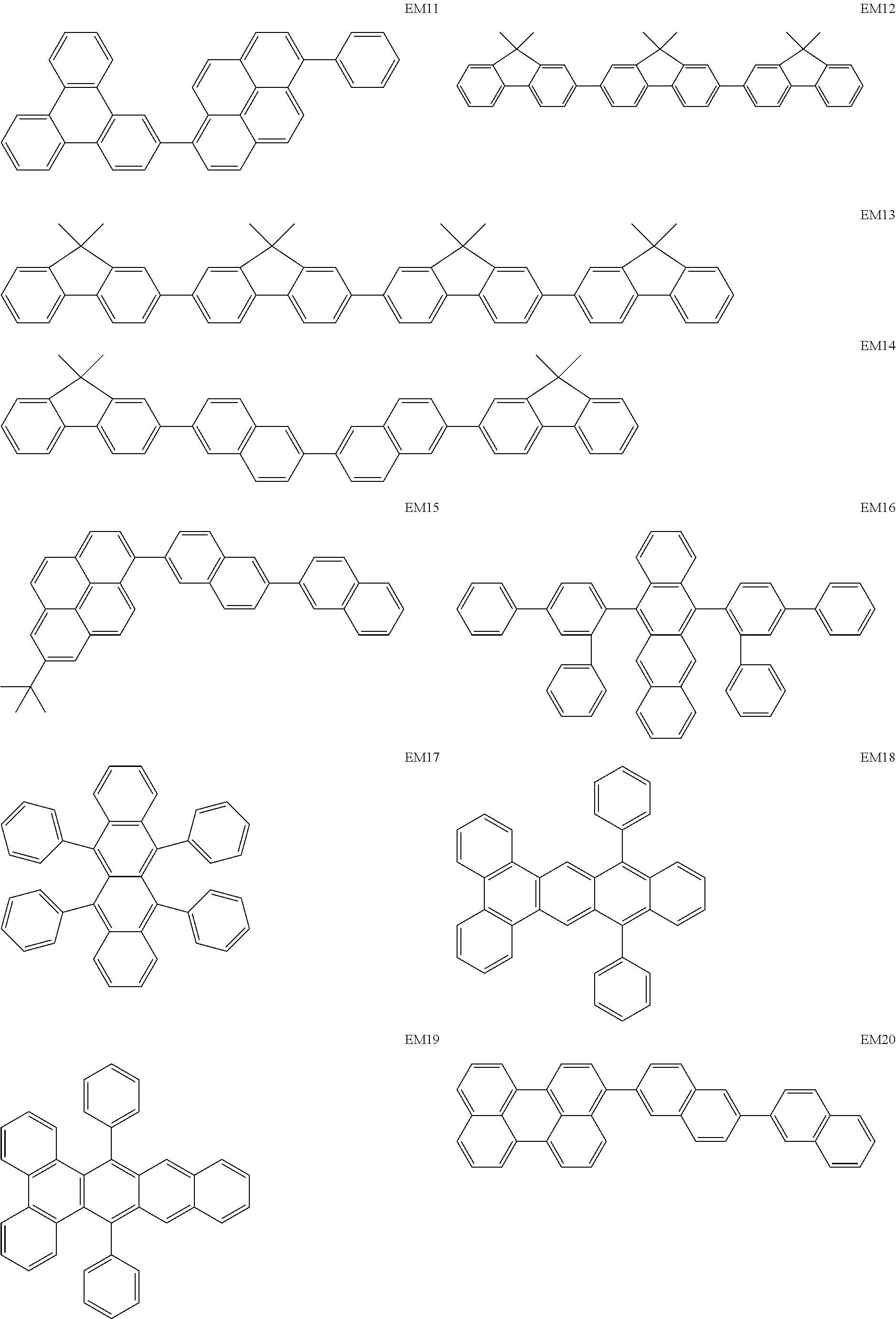

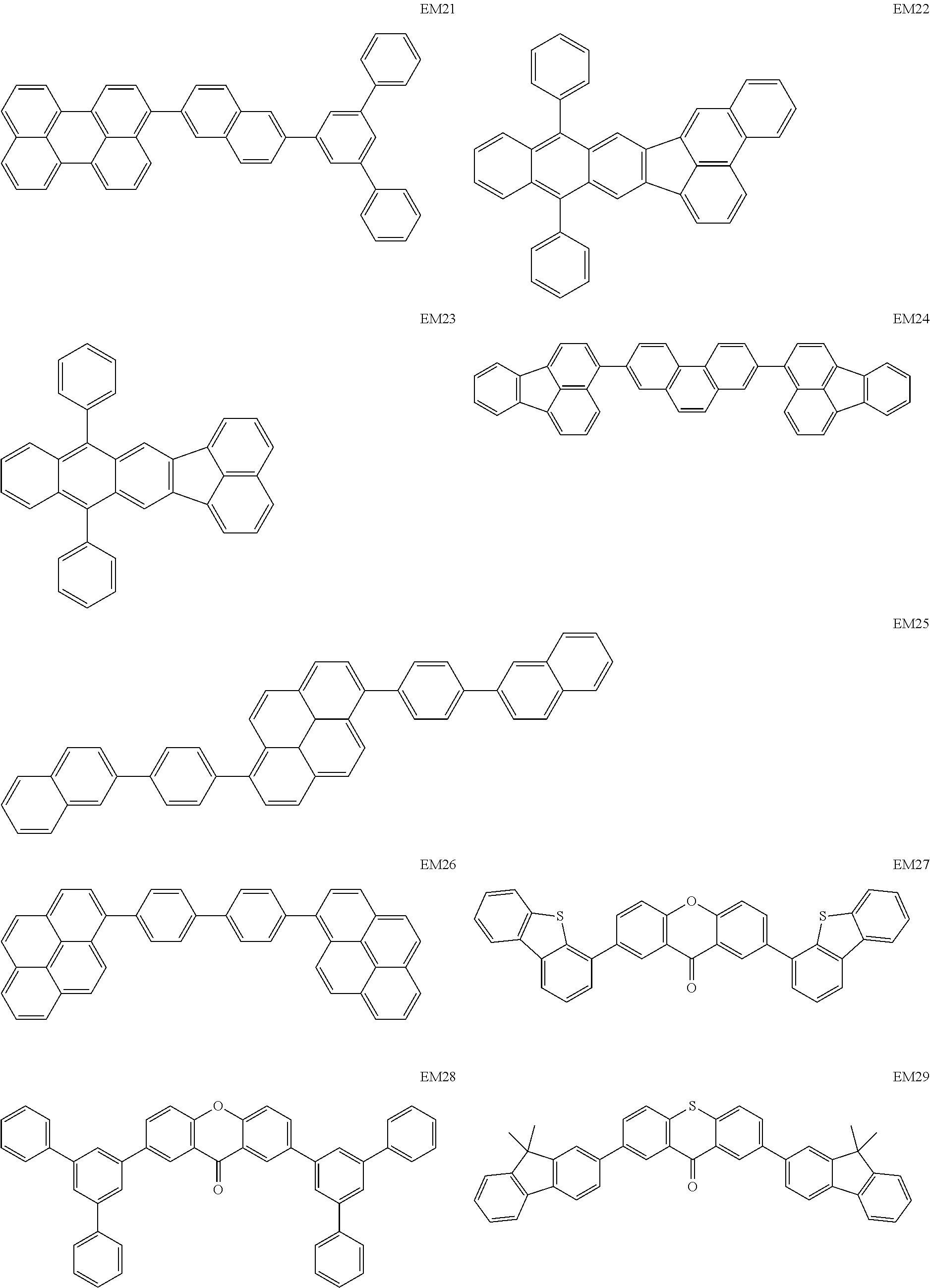

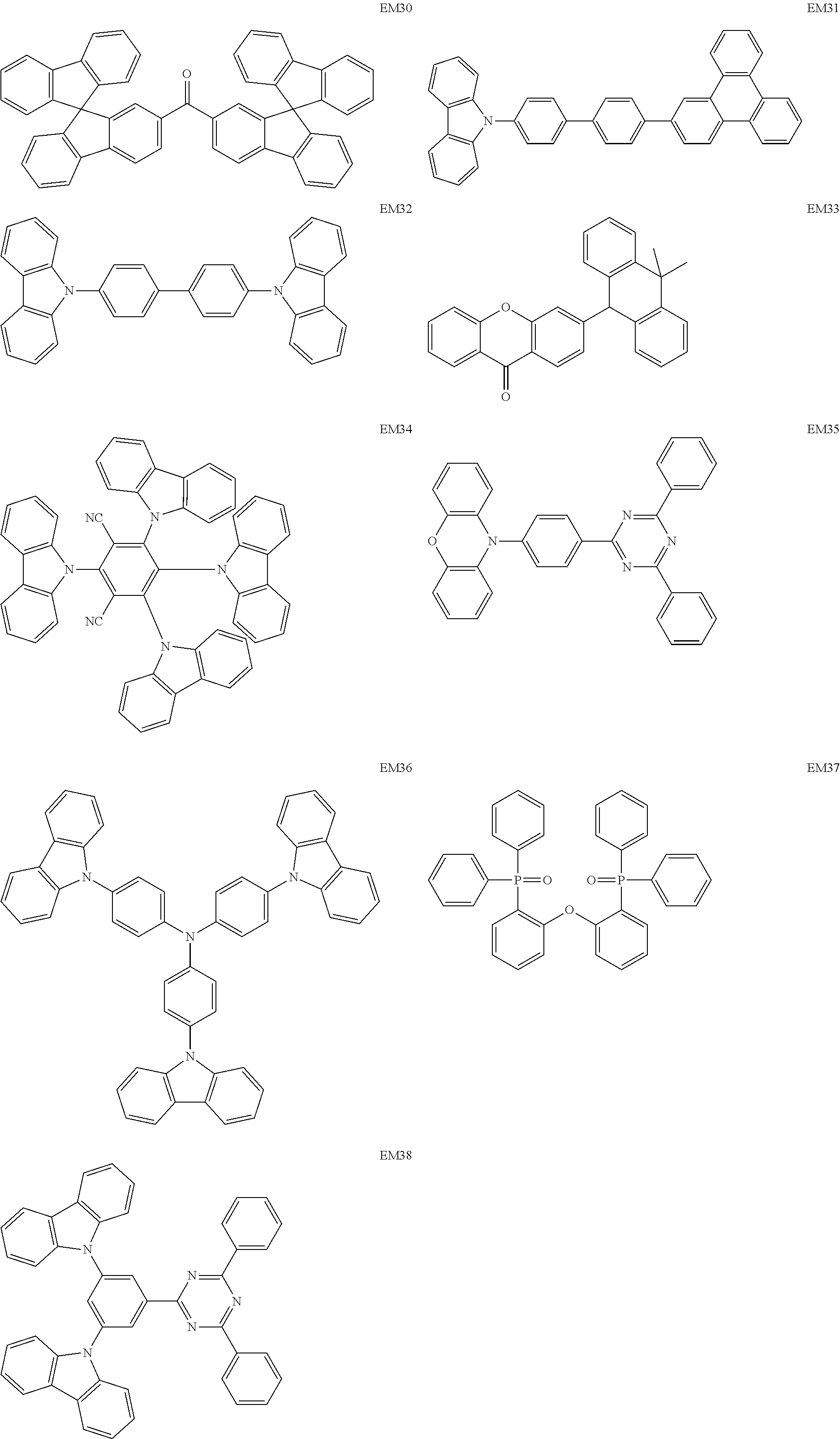

The electron transport material can be freely-selected from materials that can transport electrons injected from the cathode to the light-emitting layer, and is selected in consideration of, for example, the balance with the hole mobility of the hole transport material. Examples of a material having the ability to transport electrons include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused-ring compounds (such as fluorene derivatives, naphthalene derivatives, chrysene derivatives, and anthracene derivatives). The above-described electron transport materials are also suitably used for the hole-blocking layer. Specific examples of a compound used as the electron transport material are illustrated below, but of course, the electron transport material is not limited thereto.

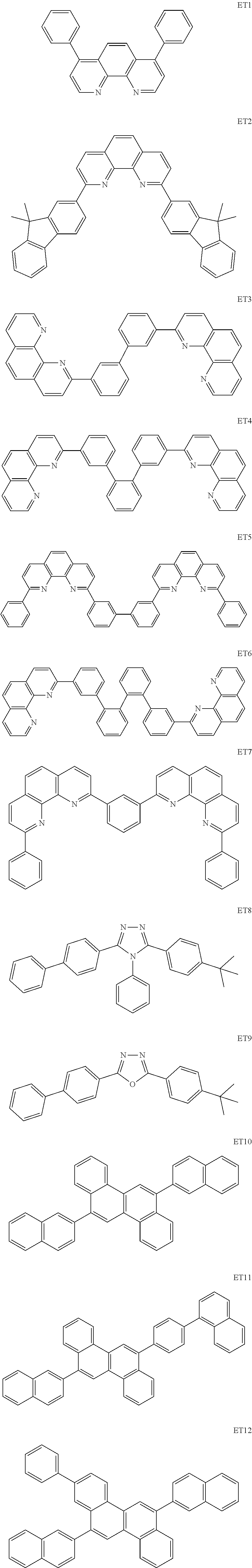

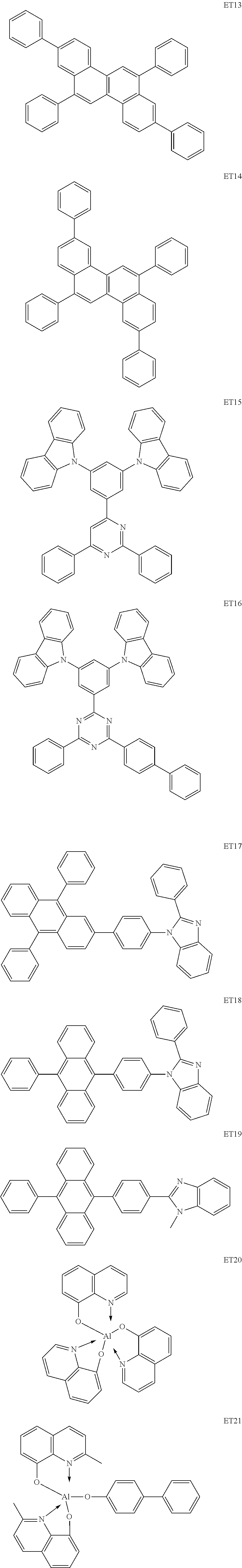

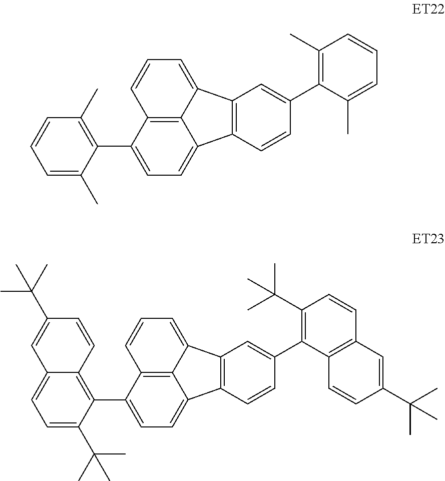

### Configuration of Organic Light-Emitting Device

The organic light-emitting device includes an insulating layer, a first electrode, an organic compound layer, and a second electrode over a substrate. A protective layer, a color filter, a microlens, and so forth may be disposed over a cathode. When the color filter is provided, a planarization layer may be provided between the color filter and the protective layer. The planarization layer can be composed of, for example, an acrylic resin. The same applies when a planarization layer is provided between the color filter and the microlens.

### Substrate

Examples of the substrate include quartz, glass, silicon wafers, resins, and metals. The substrate may include a switching device, such as a transistor, a line, and an insulating layer thereon. Any material can be used for the insulating layer as long as a contact hole can be formed in such a manner that a line can be coupled to the first electrode and as long as insulation with a non-connected line can be ensured. For example, a resin, such as polyimide, silicon oxide, or silicon nitride, can be used.

### Electrode

A pair of electrodes can be used. The pair of electrodes may be an anode and a cathode. When an electric field is applied in the direction in which the organic light-emitting device emits light, an electrode having a higher potential is the anode, and the other is the cathode. It can also be said that the electrode that supplies holes to the light-emitting layer is the anode and that the electrode that supplies electrons is the cathode.

As the component material of the anode, a material having a work function as high as possible can be used. Examples of the material that can be used include elemental metals, such as gold, platinum, silver, copper, nickel, palladium, cobalt, selenium, vanadium, and tungsten, mixtures thereof, alloys of combinations thereof, and metal oxides, such as tin oxide, zinc oxide, indium oxide, indium-tin oxide (ITO), and indium-zinc oxide. Additionally, conductive polymers, such as polyaniline, polypyrrole, and polythiophene, can be used.

These electrode materials may be used alone or in combination of two or more. The anode may be formed of a single layer or multiple layers.

When the anode is used as a reflective electrode, for example, chromium, aluminum, silver, titanium, tungsten, molybdenum, an alloy thereof, or a stack thereof can be used. These materials can also be used to act as a reflective film that does not have the role of an electrode. When the anode is used as a transparent electrode, a transparent conductive oxide layer composed of, for example, indium-tin oxide (ITO) or indium-zinc oxide can be used; however, the anode is not limited thereto.

The electrode can be formed by photolithography.

As the component material of the cathode, a material having a lower work function can be used. Examples thereof include elemental metals such as alkali metals, e.g., lithium, alkaline-earth metals, e.g., calcium, aluminum, titanium, manganese, silver, lead, and chromium, and mixtures thereof. Alloys of combinations of these elemental metals can also be used. For example, magnesium-silver, aluminum-lithium, aluminum-magnesium, silver-copper, and zinc-silver can be used. Metal oxides, such as indium-tin oxide (ITO), can also be used. These electrode materials may be used alone or in combination of two or more. The cathode may have a single-layer structure or a multilayer structure. Among them, it is preferable to use silver. To reduce the aggregation of silver, it is more preferable to use a silver alloy. Any alloy ratio may be used as long as the aggregation of silver can be reduced. The ratio of silver to another metal may be, for example, 1:1 or 3:1.

A top emission device may be provided using the cathode formed of a conductive oxide layer composed of, for example, ITO. A bottom emission device may be provided using the cathode formed of a reflective electrode composed of, for example, aluminum (Al). Any type of cathode may be used. Any method for forming the cathode may be employed. For example, a direct-current or alternating-current sputtering technique is more preferably employed because good film coverage is obtained and thus the resistance is easily reduced.

The organic compound layer may be formed of a single layer or multiple layers. When multiple layers are present, they may be referred to as a hole injection layer, a hole transport layer, an electron-blocking layer, a light-emitting layer, a hole-blocking layer, an electron transport layer, or an electron injection layer in accordance with their functions. The organic compound layer is mainly composed of an organic compound, and may contain inorganic atoms and an inorganic compound. For example, the organic compound layer may contain, for example, copper, lithium, magnesium, aluminum, iridium, platinum, molybdenum, or zinc. The organic compound layer may be disposed between the first electrode and the second electrode, and may be disposed in contact with the first electrode and the second electrode.

### Protective Layer

A protective layer may be disposed on the cathode. For example, a glass member provided with a moisture absorbent can be bonded to the cathode to reduce the entry of, for example, water into the organic compound layer, thereby reducing the occurrence of display defects. In another embodiment, a passivation film composed of, for example, silicon nitride may be disposed on the cathode to reduce the entry of, for example, water into the organic compound layer. For example, after the formation of the cathode, the substrate may be transported to another chamber without breaking the vacuum, and a silicon nitride film having a thickness of 2 μm may be formed by a CVD method to provide a protective layer. After the film deposition by the CVD method, a protective layer may be formed by an atomic layer deposition (ALD) method. Examples of the material of the layer formed by the ALD method may include, but are not limited to, silicon nitride, silicon oxide, and aluminum oxide. Silicon nitride may be deposited by the CVD method on the layer formed by the ALD method. The film formed by the ALD method may have a smaller thickness than the film formed by the CVD method. Specifically, the thickness may be 50% or less, even 10% or less.

### Color Filter

A color filter may be disposed on the protective layer. For example, a color filter may be disposed on another substrate in consideration of the size of the organic light-emitting device and bonded to the substrate provided with the organic light-emitting device. A color filter may be formed by patterning on the protective layer using photolithography. The color filter may be composed of a polymer.

### Planarization Layer

A planarization layer may be disposed between the color filter and the protective layer. The planarization layer is provided for the purpose of reducing the unevenness of the layer underneath. The planarization layer may be referred to as a “material resin layer” without limiting its purpose. The planarization layer may be composed of an organic compound. A low- or high-molecular-weight organic compound may be used. A high-molecular-weight organic compound is preferred. The planarization layers may be disposed above and below (or on) the color filter and may be composed of the same or different component materials. Specific examples thereof include poly(vinyl carbazole) resins, polycarbonate resins, polyester resins, ABS resins, acrylic resins, polyimide resins, phenolic resins, epoxy resins, silicone resins, and urea resins.

### Microlens

An organic light-emitting apparatus may include an optical component, such as a microlens, on the outgoing light side. The microlens can be composed of, for example, an acrylic resin or an epoxy resin. The microlens may be used to increase the amount of light emitted from the organic light-emitting apparatus and to control the direction of the light emitted. The microlens may have a hemispherical shape. In the case of a hemispherical shape, among tangents to the hemisphere, there is a tangent parallel to the insulating layer. The point of contact of the tangent with the hemisphere is the vertex of the microlens. The vertex of the microlens can be determined in the same way for any cross-sectional view. That is, among the tangents to the semicircle of the microlens in the cross-sectional view, there is a tangent parallel to the insulating layer, and the point of contact of the tangent with the semicircle is the vertex of the microlens.

The midpoint of the microlens can be defined. In the cross section of the microlens, when a segment is hypothetically drawn from the point where an arc shape ends to the point where another arc shape ends, the midpoint of the segment can be referred to as the midpoint of the microlens. The cross section to determine the vertex and midpoint may be a cross section perpendicular to the insulating layer.

### Opposite Substrate

An opposite substrate may be disposed on the planarization layer. The opposite substrate is disposed at a position corresponding to the substrate described above and thus is called an opposite substrate. The opposite substrate may be composed of the same material as the substrate described above. When the above-described substrate is referred to as a first substrate, the opposite substrate may be referred to as a second substrate.

### Organic Compound Layer

The organic compound layer (such as the hole injection layer, the hole transport layer, the electron-blocking layer, the light-emitting layer, the hole-blocking layer, the electron transport layer, or the electron injection layer) included in the organic light-emitting device according to the present embodiment is formed by a method described below.

For the organic compound layer, a dry process, such as a vacuum evaporation method, an ionized evaporation method, sputtering, or plasma, may be employed. Alternatively, instead of the dry process, it is also possible to employ a wet process in which a material is dissolved in an appropriate solvent and then a film is formed by a known coating method (such as spin coating, dipping, a casting method, an LB technique, or an ink jet method). When the layer is formed by, for example, the vacuum evaporation method or the solution coating method, crystallization and so forth are less likely to occur, and good stability with time is obtained. In the case of forming a film by the coating method, the film may be formed in combination with an appropriate binder resin.

Examples of the binder resin include, but are not limited to, poly(vinyl carbazole) resins, polycarbonate resins, polyester resins, ABS resins, acrylic resins, polyimide resins, phenolic resins, epoxy resins, silicone resins, and urea resins. These binder resins may be used alone as a homopolymer or copolymer or in combination as a mixture of two or more. Furthermore, additives, such as a known plasticizer, antioxidant, and ultraviolet absorber, may be used, as needed.

### Pixel Circuit

A light-emitting apparatus may include pixel circuits coupled to the light-emitting devices. Each of the pixel circuits may be of an active matrix type, which independently controls the emission of first and second light-emitting devices. The active matrix type circuit may be voltage programming or current programming. A driving circuit includes the pixel circuit for each pixel. The pixel circuit may include a light-emitting device, a transistor to control the luminance of the light-emitting device, a transistor to control the timing of the light emission, a capacitor to retain the gate voltage of the transistor to control the luminance, and a transistor to connect to GND without using the light-emitting device.

The light-emitting apparatus includes a display area and a peripheral area disposed around the display area. The display area includes a pixel circuit, and the peripheral area includes a display control circuit. The mobility of a transistor contained in the pixel circuit may be lower than the mobility of a transistor contained in the display control circuit. The gradient of the current-voltage characteristics of the transistor contained in the pixel circuit may be smaller than the gradient of the current-voltage characteristic of the transistor contained in the display control circuit. The gradient of the current-voltage characteristics can be measured by what is called Vg-Ig characteristics. The transistor contained in the pixel circuit is a transistor coupled to a light-emitting device, such as a first light-emitting device.

### Pixel

An organic light-emitting apparatus including an organic light-emitting device may include multiple pixels. Each pixel includes subpixels configured to emit colors different from each other. The subpixels may have respective red, green, and blue (RGB) emission colors.

Light emerges from a region of the pixel, also called a pixel aperture. This region is also referred to as a first region. The pixel aperture may be 15 μm or less, and may be 5 μm or more. More specifically, the pixel aperture may be, for example, 11 μm, 9.5 μm, 7.4 μm, or 6.4 μm. The distance between subpixels may be 10 μm or less. Specifically, the distance may be 8 μm, 7.4 μm, or 6.4 μm.

The pixels may be arranged in a known pattern in plan view. For example, a stripe pattern, a delta pattern, a Pen Tile matrix pattern, or the Bayer pattern may be used. The shape of each subpixel in plan view may be any known shape. Examples of the shape of the subpixel include quadrilaterals, such as rectangles and rhombi, and hexagons. Of course, if the shape is close to a rectangle, rather than an exact shape, it is included in the rectangle. The shape of the subpixel and the pixel arrangement can be used in combination.

### Application of Organic Light-Emitting Device

The organic light-emitting device according to an embodiment can be used as a component member of a display apparatus or lighting apparatus. Other applications include exposure light sources for electrophotographic image-forming apparatuses, backlights for liquid crystal displays, and light-emitting apparatuses including white-light sources and color filters.

The display apparatus may be an image information-processing unit having an image input unit that receives image information from an area CCD, a linear CCD, a memory card, or the like, an information-processing unit that processes the input information, and a display unit that displays the input image. The display apparatus includes multiple pixels, and at least one of the multiple pixels may include the organic light-emitting device of the present embodiment and a transistor coupled to the organic light-emitting device.

The display unit of an image pickup apparatus or an inkjet printer may have a touch panel function. The display unit of an image pickup apparatus or an inkjet printer may have a touch panel function. The driving mode of the touch panel function may be, but is not particularly limited to, an infrared mode, an electrostatic capacitance mode, a resistive film mode, or an electromagnetic inductive mode. The display apparatus may also be used for a display unit of a multifunction printer.

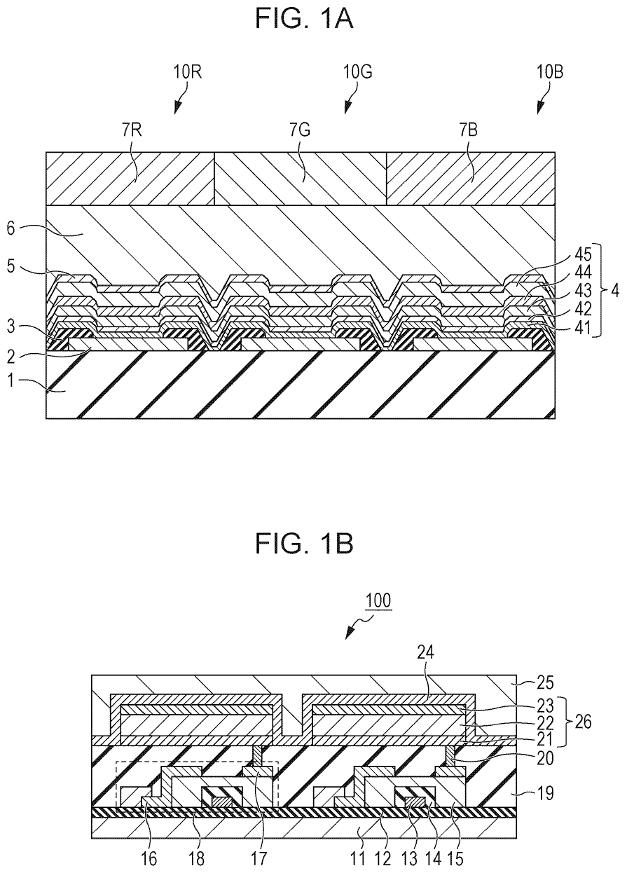

The following describes a display apparatus according to the present embodiment with reference to the attached drawings. FIGS. 1A and 1B are each a schematic cross-sectional view of an example of a display apparatus including organic light-emitting devices and transistors coupled to the respective organic light-emitting devices. Each of the transistors is an example of an active element. The transistors may be thin-film transistors (TFTs).

FIG. 1A is an example of pixels that are components of the display apparatus according to the present embodiment. Each of the pixels includes subpixels 10. The subpixels are separated into 10R, 10G, and 10B according to their light emission. The emission color may be distinguished based on the wavelength of light emitted from the light-emitting layer. Alternatively, light emitted from the subpixels may be selectively transmitted or color-converted with, for example, a color filter. Each subpixels 10 includes a reflective electrode serving as a first electrode 2, an insulating layer 3 covering the edge of the first electrode 2, an organic compound layer 4 covering the first electrode 2 and the insulating layer 3, a transparent electrode serving as a second electrode 5, a protective layer 6, and a color filter 7 over an interlayer insulating layer 1.

The transistors and capacitive elements may be disposed under or in the interlayer insulating layer 1. Each transistor may be electrically coupled to a corresponding one of the first electrodes through a contact hole, which is not illustrated.

The insulating layer 3 is also called a bank or pixel separation film. The insulating layer 3 covers the edge of each first electrode 2 and surrounds the first electrode 2. Portions that are not covered with the insulating layer 3 are in contact with the organic compound layer 4 and serve as light-emitting regions.

The organic compound layer 4 includes a hole injection layer 41, a hole transport layer 42, a first light-emitting layer 43, a second light-emitting layer 44, and an electron transport layer 45.

The second electrode 5 may be a transparent electrode, a reflective electrode, or a semi-transparent electrode.

The protective layer 6 reduces the penetration of moisture into the organic compound layer 4. Although the protective layer 6 is illustrated as a single layer, the protective layer 6 may include multiple layers, and each layer may be an inorganic compound layer or an organic compound layer.

The color filter 7 is separated into 7R, 7G, and 7B according to its color. The color filter 7 may be disposed on a planarization film, which is not illustrated. A resin protective layer, not illustrated, may be disposed on the color filter 7. The color filter 7 may be disposed on the protective layer 6. Alternatively, the color filter 7 may be disposed on an opposite substrate, such as a glass substrate, and then bonded.

A display apparatus 100 illustrated in FIG. 1B includes organic light-emitting devices 26 and TFTs 18 as an example of transistors. A substrate 11 composed of a material, such as glass or silicon is provided, and an insulating layer 12 is disposed thereon. Active elements, such as the TFTs 18, are disposed on the insulating layer 12. The gate electrode 13, the gate insulating film 14, and the semiconductor layer 15 of each of the active elements are disposed thereon. Each TFT 18 further includes a drain electrode 16 and a source electrode 17. The TFTs 18 are overlaid with an insulating film 19. Anode 21 included in the organic light-emitting devices 26 is coupled to the source electrodes 17 through contact holes 20 provided in the insulating film 19.

The mode of electrical connection between the electrodes (anode 21 and cathode 23) included in each organic light-emitting device 26 and the electrodes (source electrode 17 and drain electrode 16) included in a corresponding one of the TFTs 18 is not limited to the mode illustrated in FIG. 1B. That is, it is sufficient that any one of the anode 21 and the cathode 23 is electrically coupled to any one of the source electrode 17 and the drain electrode 16 of the TFT 18. The term “TFT” refers to a thin-film transistor.

In the display apparatus 100 illustrated in FIG. 1B, although each organic compound layer 22 is illustrated as a single layer, the organic compound layer 22 may include multiple layers. To reduce the deterioration of the organic light-emitting devices 26, a first protective layer 24 and a second protective layer 25 are disposed on the cathodes 23.

In the display apparatus 100 illustrated in FIG. 1B, although the transistors are used as switching devices, other switching devices may be used instead.

The transistors used in the display apparatus 100 illustrated in FIG. 1B are not limited to transistors using a single-crystal silicon wafer, but may also be thin-film transistors including active layers on the insulating surface of a substrate. Examples of the material of the active layers include single-crystal silicon, non-single-crystal silicon, such as amorphous silicon and microcrystalline silicon; and non-single-crystal oxide semiconductors, such as indium zinc oxide and indium gallium zinc oxide. Thin-film transistors are also called TFT elements.

The transistors in the display apparatus 100 illustrated in FIG. 1B may be formed in the substrate, such as a Si substrate. The expression “formed in the substrate” indicates that the transistors are produced by processing the substrate, such as a Si substrate. In the case where the transistors are formed in the substrate, the substrate and the transistors can be deemed to be integrally formed.

In the organic light-emitting device according to the present embodiment, the luminance is controlled by the TFT devices, which are an example of switching devices; thus, an image can be displayed at respective luminance levels by arranging multiple organic light-emitting devices in the plane. The switching devices according to the present embodiment are not limited to the TFT devices and may be low-temperature polysilicon transistors or active-matrix drivers formed on a substrate such as a Si substrate. The expression “on a substrate” can also be said to be “in the substrate”. Whether transistors are formed in the substrate or TFT devices are used is selected in accordance with the size of a display unit. For example, when the display unit has a size of about 0.5 inches, organic light-emitting devices are preferably disposed on a Si substrate.

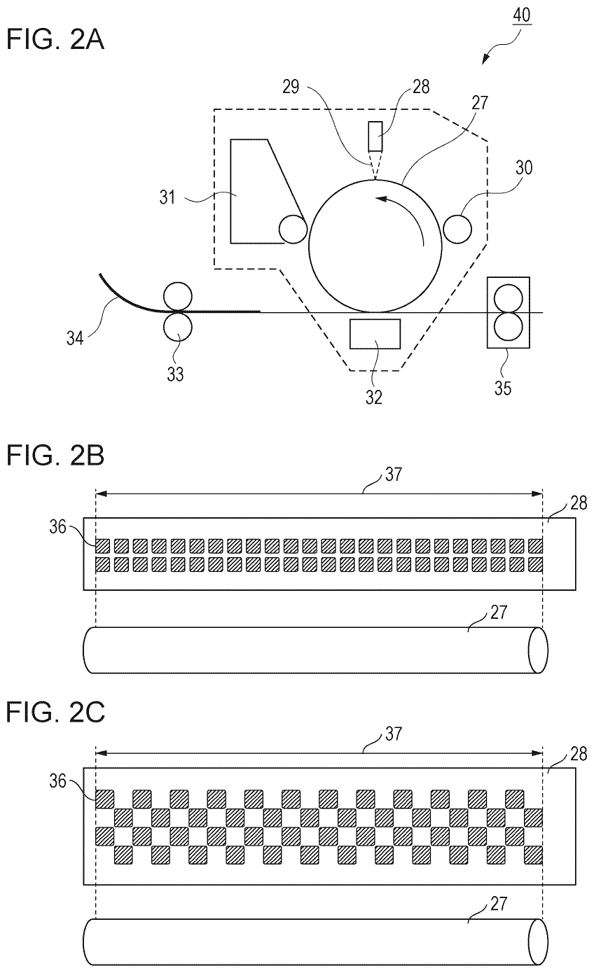

FIG. 2A is a schematic view of an example of an image-forming apparatus according to an embodiment of the present invention. An image-forming apparatus 40 is an electrophotographic image-forming apparatus and includes a photoconductor 27, an exposure light source 28, a charging unit 30, a developing unit 31, a transfer unit 32, a transport roller 33, and a fusing unit 35. The irradiation of light 29 is performed from the exposure light source 28 to form an electrostatic latent image on the surface of the photoconductor 27. The exposure light source 28 includes the organic light-emitting device according to the present embodiment. The developing unit 31 contains, for example, a toner. The charging unit 30 charges the photoconductor 27. The transfer unit 32 transfers the developed image to a recording medium 34. The transport roller 33 transports the recording medium 34. The recording medium 34 is paper, for example. The fusing unit 35 fixes the image formed on the recording medium 34.

FIGS. 2B and 2C each illustrate the exposure light source 28 and are each a schematic view illustrating multiple light-emitting portions 36, which are the organic light-emitting devices according to the present embodiment, arranged on a long substrate. Arrows 37 are parallel to the axis of the photoconductor 27 and each represent the row direction in which the light-emitting portions 36 are arranged. The row direction is the same as the direction of the axis on which the photoconductor 27 rotates. This direction can also be referred to as the long-axis direction of the photoconductor 27. FIG. 2B illustrates a configuration in which the light-emitting portions 36 are arranged in the long-axis direction of the photoconductor 27. FIG. 2C is different from FIG. 2B in that the light-emitting portions 36 are arranged alternately in the row direction in a first row and a second row.

The first row and the second row are located at different positions in the column direction. In the first row, the multiple light-emitting portions 36 are spaced apart. The second row has the light-emitting portions 36 at positions corresponding to the positions between the light-emitting portions 36 in the first row. In other words, the multiple light-emitting portions 36 are also spaced apart in the column direction. The arrangement in FIG. 2C can be rephrased as, for example, a lattice arrangement, a staggered arrangement, or a checkered pattern.

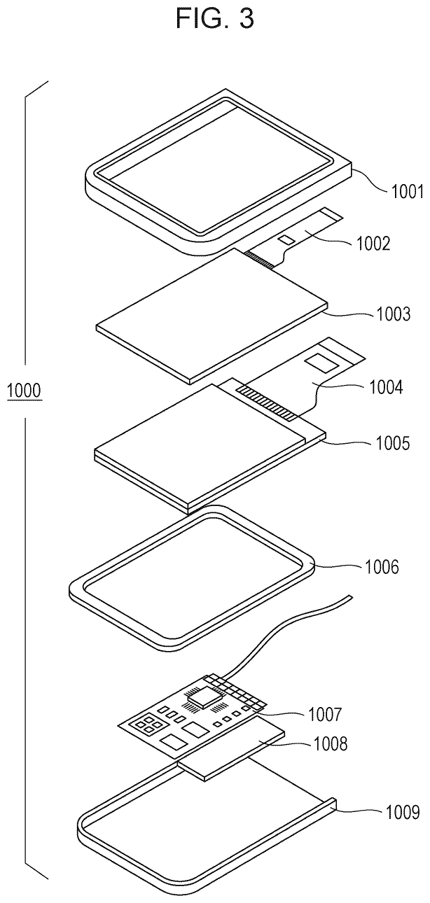

FIG. 3 is a schematic view illustrating an example of a display apparatus according to the present embodiment. A display apparatus 1000 may include a touch panel 1003, a display panel 1005, a frame 1006, a circuit substrate 1007, and a battery 1008 disposed between an upper cover 1001 and a lower cover 1009. The touch panel 1003 and the display panel 1005 are coupled to flexible printed circuits FPCs 1002 and 1004, respectively. The circuit substrate 1007 includes printed transistors. The battery 1008 need not be provided unless the display apparatus is a portable apparatus. The battery 1008 may be disposed at a different position even if the display apparatus is a portable apparatus.

The display apparatus according to the present embodiment may include a color filter having red, green, and blue portions. In the color filter, the red, green, and blue portions may be arranged in a delta arrangement.

The display apparatus according to the present embodiment may be used for the display unit of a portable terminal. In that case, the display apparatus may have both a display function and an operation function. Examples of the portable terminal include mobile phones such as smartphones, tablets, and head-mounted displays.

The display apparatus according to the present embodiment may be used for a display unit of an image pickup apparatus including an optical unit including multiple lenses and an image pickup device that receives light passing through the optical unit. The image pickup apparatus may include a display unit that displays information acquired by the image pickup device. The display unit may be a display unit exposed to the outside of the image pickup apparatus or a display unit disposed in a finder. The image pickup apparatus may be a digital camera or a digital camcorder.

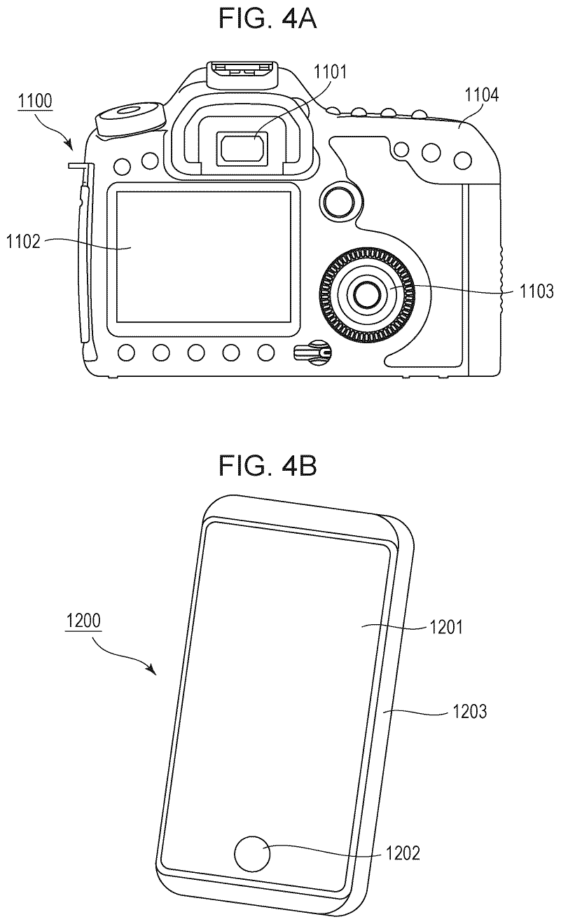

FIG. 4A is a schematic view illustrating an example of an image pickup apparatus according to the present embodiment. An image pickup apparatus 1100 may include a viewfinder 1101, a rear display 1102, an operation unit 1103, and a housing 1104. The viewfinder 1101 may include the display apparatus according to the present embodiment. In this case, the display apparatus may display environmental information, imaging instructions, and so forth in addition to an image to be captured. The environmental information may include, for example, the intensity of external light, the direction of external light, the moving speed of a subject, and the possibility that a subject is shielded by a shielding material.

The timing suitable for imaging is only for a short time; thus, the information may be displayed as soon as possible. Accordingly, it is preferable to use a display apparatus including the organic light-emitting device of the present embodiment. This is because the organic light-emitting device has a fast response time. The display apparatus including the organic light-emitting device can be used more suitably than liquid crystal displays for such apparatuses required to have a high display speed.

The image pickup apparatus 1100 includes an optical unit, which is not illustrated. The optical unit includes multiple lenses and is configured to form an image on an image pickup device in the housing 1104. The relative positions of the multiple lenses can be adjusted to adjust the focal point. This operation can also be performed automatically. The image pickup apparatus may translate to a photoelectric conversion apparatus. Examples of an image capturing method employed in the photoelectric conversion apparatus may include a method for detecting a difference from the previous image and a method of cutting out an image from images always recorded, instead of sequentially capturing images.

FIG. 4B is a schematic view illustrating an example of an electronic apparatus according to the present embodiment. An electronic apparatus 1200 includes a display unit 1201, an operation unit 1202, and a housing 1203. The housing 1203 may accommodate a circuit, a printed circuit board including the circuit, a battery, and a communication unit. The operation unit 1202 may be a button or a touch-screen-type reactive unit. The operation unit 1202 may be a biometric recognition unit that recognizes a fingerprint to release the lock or the like. An electronic apparatus having a communication unit can also be referred to as a communication apparatus. The electronic apparatus 1200 may further have a camera function by being equipped with a lens and an image pickup device. An image captured by the camera function is displayed on the display unit 1201. Examples of the electronic apparatus 1200 include smartphones and notebook computers.

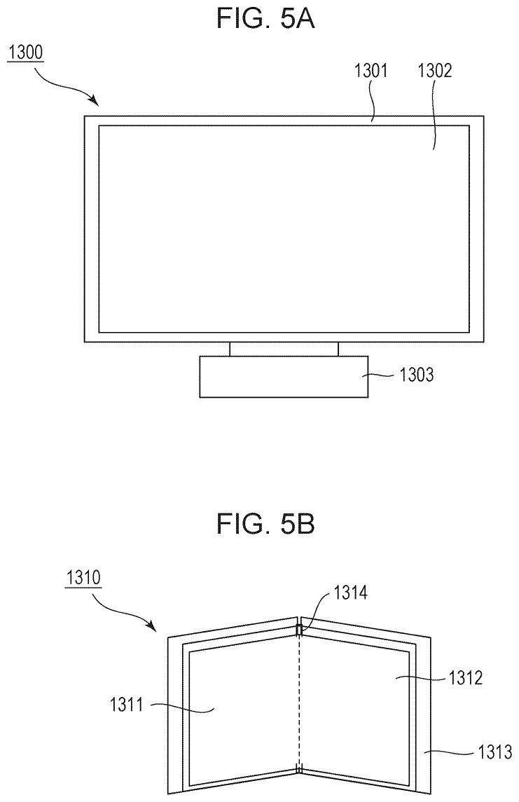

FIGS. 5A and 5B are each a schematic view illustrating an example of the display apparatus according to the present embodiment. FIG. 5A illustrates a display apparatus, such as a television monitor or a PC monitor. A display apparatus 1300 includes a frame 1301 and a display unit 1302. The light-emitting device according to the present embodiment may be used for the display unit 1302. The display apparatus 1300 includes a base 1303 that supports the frame 1301 and the display unit 1302. The base 1303 is not limited to the structure illustrated in FIG. 5A. The lower side of the frame 1301 may also serve as a base. The frame 1301 and the display unit 1302 may be curved. These may have a radius of curvature of 5,000 mm or more and 6,000 mm or less.

FIG. 5B is a schematic view illustrating another example of a display apparatus according to the present embodiment. A display apparatus 1310 illustrated in FIG. 5B can be folded and is what is called a foldable display apparatus. The display apparatus 1310 includes a first display portion 1311, a second display portion 1312, a housing 1313, and an inflection point 1314. The first display portion 1311 and the second display portion 1312 may include the light-emitting device according to the present embodiment. The first display portion 1311 and the second display portion 1312 may be a single, seamless display apparatus. The first display portion 1311 and the second display portion 1312 can be divided from each other at the inflection point. The first display portion 1311 and the second display portion 1312 may display different images. Alternatively, a single image may be displayed in the first and second display portions.

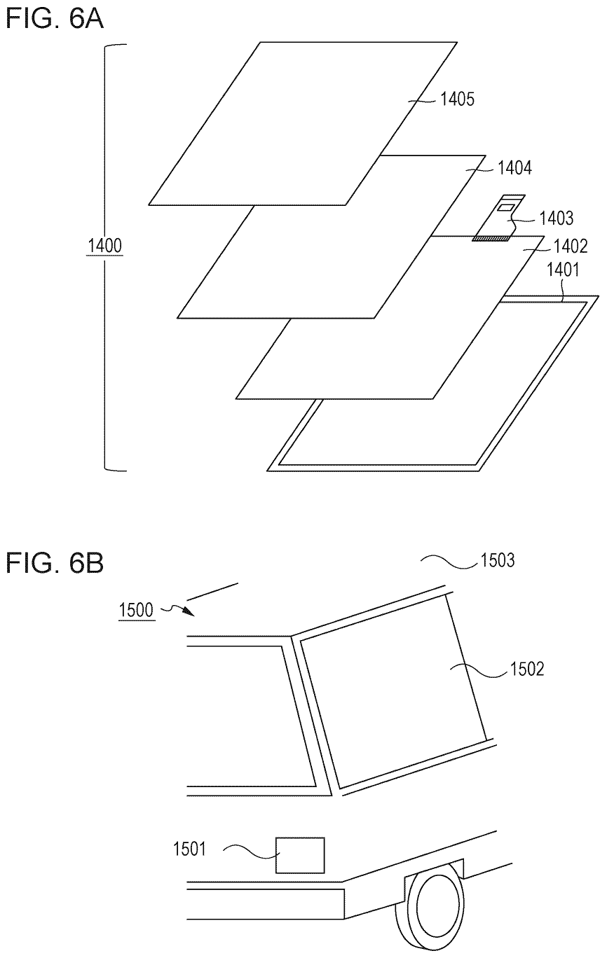

FIG. 6A is a schematic view illustrating an example of a lighting apparatus according to the present embodiment. A lighting apparatus 1400 may include a housing 1401, a light source 1402, a circuit board 1403, an optical filter 1404 that transmits light emitted from the light source 1402, and a light diffusion unit 1405. The light source 1402 may include an organic light-emitting device according to the present embodiment. The optical filter 1404 may be a filter that improves the color rendering properties of the light source. The light diffusion unit 1405 can effectively diffuse light from the light source to deliver the light to a wide range when used for illumination and so forth. The optical filter 1404 and the light diffusion unit 1405 may be disposed at the light emission side of the lighting apparatus. A cover may be disposed at the outermost portion, as needed.

The lighting apparatus is, for example, an apparatus that lights a room. The lighting apparatus may emit light of white, neutral white, or any color from blue to red. A light control circuit that controls the light may be provided. The lighting apparatus may include the organic light-emitting device of the present embodiment and a power supply circuit coupled thereto. The power supply circuit is a circuit that converts an AC voltage into a DC voltage. The color temperature of white is 4,200 K, and the color temperature of neutral white is 5,000 K. The lighting apparatus may include a color filter.

The lighting apparatus according to the present embodiment may include a heat dissipation unit. The heat dissipation unit is configured to release heat in the device to the outside of the device and is composed of, for example, a metal having a high specific heat and liquid silicone.

FIG. 6B is a schematic view illustrating an automobile as an example of a moving object according to the present embodiment. The automobile includes a tail lamp, which is an example of lighting units. An automobile 1500 includes a tail lamp 1501 and may be configured to light the tail lamp when a brake operation or the like is performed.

The tail lamp 1501 may include an organic light-emitting device according to the present embodiment. The tail lamp 1501 may include a protective member that protects the organic light-emitting device. The protective member may be composed of any transparent material with some degree of high strength and is preferably composed of polycarbonate, for example. The polycarbonate may be mixed with, for example, a furandicarboxylic acid derivative or an acrylonitrile derivative.

The automobile 1500 may include an automobile body 1503 and windows 1502 attached thereto. The windows 1502 may be transparent displays if the windows are not used to check the front and back of the automobile. The transparent displays may include an organic light-emitting device according to the present embodiment.

In this case, the components, such as the electrodes, of the organic light-emitting device are formed of transparent members.

The moving object according to the present embodiment may be, for example, a ship, an aircraft, or a drone. The moving object may include a body and a lighting unit attached to the body. The lighting unit may emit light to indicate the position of the body. The lighting unit includes the organic light-emitting device according to the present embodiment.

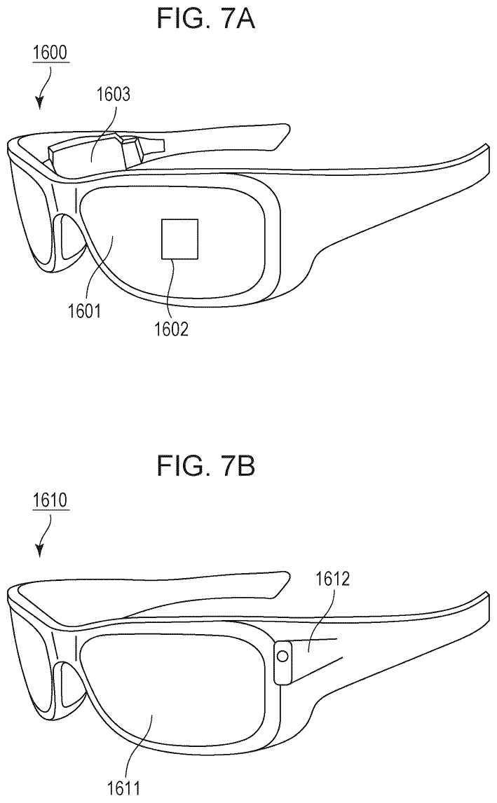

Examples of applications of the display apparatuses of the above embodiments will be described with reference to FIGS. 7A and 7B. The display apparatuses can be used for systems that can be worn as wearable devices, such as smart glasses, HMDs, and smart contacts. An image pickup and display apparatus used in such an example of the applications has an image pickup apparatus that can photoelectrically convert visible light and a display apparatus that can emit visible light.

FIG. 7A is a schematic view illustrating an example of a wearable device according to an embodiment of the present invention. Glasses 1600 (smart glasses) according to an example of applications will be described with reference to FIG. 7A. An image pickup apparatus 1602, such as a CMOS sensor or SPAD, is provided on a front side of a lens 1601 of the glasses 1600. The display apparatus according to any of the above-mentioned embodiments is provided on the back side of the lens 1601.

The glasses 1600 further include a control unit 1603. The control unit 1603 functions as a power source that supplies electric power to the image pickup apparatus 1602 and the display apparatus. The control unit 1603 controls the operation of the image pickup apparatus 1602 and the display apparatus. The lens 1601 has an optical system for focusing light on the image pickup apparatus 1602.

FIG. 7B is a schematic view illustrating another example of a wearable device according to an embodiment of the present invention. Glasses 1610 (smart glasses) according to an example of applications will be described with reference to FIG. 7B. The glasses 1610 include a control unit 1612. The control unit 1612 includes an image pickup apparatus corresponding to the image pickup apparatus 1602 illustrated in FIG. 7A and a display apparatus. A lens 1611 is provided with the image pickup apparatus in the control unit 1612 and an optical system that projects light emitted from the display apparatus. An image is projected onto the lens 1611. The control unit 1612 functions as a power source that supplies electric power to the image pickup apparatus and the display apparatus and controls the operation of the image pickup apparatus and the display apparatus.

The control unit 1612 may include a gaze detection unit that detects the gaze of a wearer. Infrared light may be used for gaze detection. An infrared light-emitting unit emits infrared light to an eyeball of a user who is gazing at a displayed image. An image of the eyeball is captured by detecting the reflected infrared light from the eyeball with an image pickup unit having light-receiving elements. The deterioration of image quality is reduced by providing a reduction unit that reduces light from the infrared light-emitting unit to the display unit when viewed in plan. The user's gaze at the displayed image is detected from the image of the eyeball captured with the infrared light. Any known method can be employed to the gaze detection using the captured image of the eyeball. As an example, a gaze detection method based on a Purkinje image of the reflection of irradiation light on a cornea can be employed. More specifically, the gaze detection process is based on a pupil-corneal reflection method. Using the pupil-corneal reflection method, the user's gaze is detected by calculating a gaze vector representing the direction (rotation angle) of the eyeball based on the image of the pupil and the Purkinje image contained in the captured image of the eyeball.

A display apparatus according to an embodiment of the present invention may include an image pickup apparatus including light-receiving elements, and may control an image displayed on the display apparatus based on the gaze information of the user from the image pickup apparatus. Specifically, in the display apparatus, a first field-of-view area at which the user gazes and a second field-of-view area other than the first field-of-view area are determined on the basis of the gaze information. The first field-of-view area and the second field-of-view area may be determined by the control unit of the display apparatus or may be determined by receiving those determined by an external control unit. In the display area of the display apparatus, the display resolution of the first field-of-view area may be controlled to be higher than the display resolution of the second field-of-view area. That is, the resolution of the second field-of-view area may be lower than that of the first field-of-view area.

The display area includes a first display area and a second display area different from the first display area. Based on the gaze information, an area of higher priority is determined from the first display area and the second display area. The first display area and the second display area may be determined by the control unit of the display apparatus or may be determined by receiving those determined by an external control unit. The resolution of an area of higher priority may be controlled to be higher than the resolution of an area other than the area of higher priority. In other words, the resolution of an area of a relatively low priority may be low.

Artificial intelligence (AI) may be used to determine the first field-of-view and the high-priority area. The AI may be a model configured to estimate the angle of gaze from the image of the eyeball and the distance to a target object located in the gaze direction, using the image of the eyeball and the actual direction of gaze of the eyeball in the image as teaching data. The AI program may be stored in the display apparatus, the image pickup apparatus, or an external apparatus. When the AI program is stored in the external apparatus, the AI program is transmitted to the display apparatus via communications.

In the case of controlling the display based on visual detection, smart glasses that further include an image pickup apparatus that captures an external image can be used. The smart glasses can display the captured external information in real time.

As described above, the use of an apparatus including the organic light-emitting device according to the present embodiment enables a stable display with good image quality even for a long time.

### EXAMPLES

Examples will be described below. However, the present invention is not limited thereto.

### Example 1 (Synthesis of Exemplified Compound A1)

Exemplified compound A1 was synthesized according to the following synthesis route.

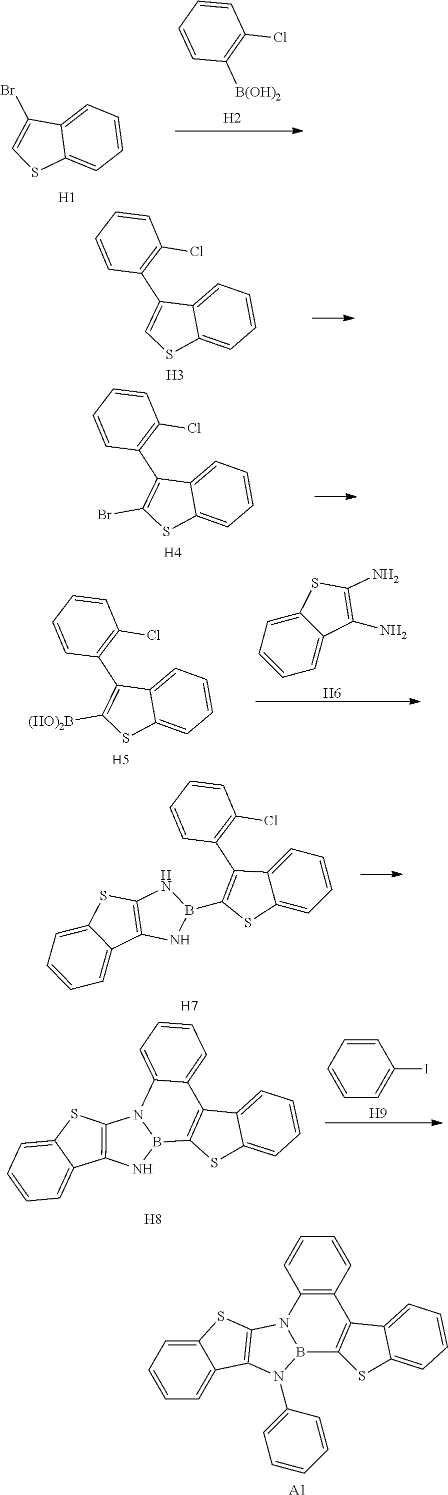

### (1) Synthesis of Compound H3

Compounds, reagents, and solvents below were placed in a 1-L recovery flask.
Compound H1: 10.00 g (46.7 mmol)
Compound H2: 10.94 g (70.1 mmol)
Pd(PPh₃)₄ (tetrakis(triphenylphosphine)palladium: 2.70 g (2.34 mmol)
Na₂CO₃: 9.90 g (93.4 mmol)
Toluene: 500 ml
Ethanol: 100 ml
Water: 100 ml

The reaction solution was heated to 90° C. under a stream of nitrogen and stirred at this temperature (90° C.) for 5 hours. After completion of the reaction, extraction was performed with toluene and water, followed by concentration. The resulting concentrate was purified by silica gel column chromatography (heptane:toluene=1:10). The resulting product was then dispersed and washed in methanol to give 9.71 g (yield: 85%) of white compound H3.

### (2) Synthesis of Compound H4

The compound, a reagent, and a solvent below were placed in a 1-L recovery flask.
Compound H3: 9.50 g (38.8 mmol)
N-Bromosuccinimide: 7.25 g (40.7 mmol)
Acetonitrile: 500 ml

The reaction solution was stirred for 2 hours under a stream of nitrogen. After completion of the reaction, water was added, followed by filtration. The resulting residue was recrystallized from cyclohexane to give 10.30 g (yield: 82%) of white compound H4.

### (3) Synthesis of Compound H5

The compound, a reagent, and a solvent below were placed in a 500-mL recovery flask.
Compound H4: 5.00 g (15.4 mmol)
Trimethyl borate: 2.40 g (23.1 mmol)
Tetrahydrofuran: 250 ml

The reaction solution was cooled to −78° C. under a stream of nitrogen, followed by the dropwise addition of and the following reagent: N-butyl lithium (1.6 M hexane solution) 10.56 ml (16.9 mmol).

The reaction solution was stirred at −78° C. for 30 minutes, and then slowly warmed to room temperature over about 1 hour. The reaction solution was stirred at room temperature for 1 hour to terminate the reaction. The reaction solution was cooled to 0° C., followed by the addition of 50 ml of 2 M hydrochloric acid. The mixture was stirred at 0° C. for 30 minutes. After 200 mL of water was added thereto, filtration was performed. The resulting residue was washed with water and methanol to give 3.11 g (yield: 70%) of white compound H5.

### (4) Synthesis of Compound H7

The compounds, a reagent, and a solvent below were placed in a 300-mL recovery flask.
Compound H5: 3.00 g (10.4 mmol)
Compound H6: 1.71 g (10.4 mmol)
Toluene: 120 ml

The reaction solution was heated to 120° C. under a stream of nitrogen and stirred for 5 hours under reflux heating. After completion of the reaction, the mixture was concentrated. Heptane was added thereto, followed by filtration. The resulting product was dispersed and washed with heptane to give 2.82 g (yield: 65%) of white compound H7.

### (5) Synthesis of Compound H8

The compound, reagents, and a solvent below were placed in a 300-mL recovery flask.
Compound H7: 2.8 g (6.72 mmol)
Pd(OAc)₂ (palladium acetate): 75 mg (0.34 mmol) XPhos (2-dicyclohexylphosphino-2′,4′,6′-triisopropylbiphenyl): 320 mg (0.68 mmol)
tBuOK (potassium tert-butoxide): 1.13 g (10.8 mmol)
Xylene: 140 ml

The reaction solution was heated to 145° C. under a stream of nitrogen and stirred for 7 hours under reflux heating. After the reaction was completed, the mixture was filtered. The resulting crude product was purified by silica gel column chromatography (toluene/ethyl acetate=10/1) and then dispersed and washed with toluene to give 1.28 g (yield: 50%) of white compound H8.

### (6) Synthesis of Exemplified Compound A1

The compounds, reagents, and a solvent below were placed in a 200-mL recovery flask.
Compound H8: 1.20 g (2.63 mmol)
Compound H9: 229 mg (3.95 mmol)
Pd(OAc)₂: 29 mg (0.13 mmol)
Tri-o-tolylphosphine: 79 mg (0.26 mmol)
tBuOK: 0.59 g (5.26 mmol)
Xylene: 120 ml

The reaction solution was heated to 145° C. under a stream of nitrogen and stirred for 5 hours under reflux heating. After the reaction was completed, the mixture was filtered. The resulting crude product was purified by silica gel column chromatography (chlorobenzene), followed by recrystallization from toluene to give 0.84 g (yield: 70%) of white exemplified compound A1.

Exemplified compound A1 prepared by the above process was subjected to mass spectrometry with MALDI-TOF-MS (Autoflex LRF, manufactured by Bruker). The results indicated that the calculated value obtained from C₂₈H₁₂BN₂S₂ was 456, and the measured value (m/z) was 456, which agreed with the calculated value.

### Examples 2 to 25 (Syntheses of Exemplified Compounds)

As presented in Tables 3 to 7, exemplified compounds of Examples 2 to 25 were synthesized as in Example 1, except that compound H1 of Example 1 was changed to raw material 1, compound H2 to raw material 2, compound H6 to raw material 3, and compound H9 to raw material 4. The resulting exemplified compounds were subjected to mass spectrometry as in Example 1, and the measured values (m/z) are also presented.

TABLE 3

| Example | Exemplified compound | Raw material 1 | Raw material 2 | Raw material 3 | Raw material 4 | m/z |
|---|---|---|---|---|---|---|
| 2 | 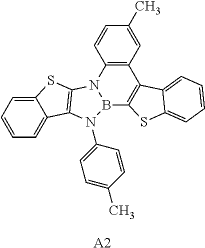 [SMILES: Cc1ccc(N2B3c4sc5ccccc5c4-c4cc(C)ccc4N3c3sc4ccccc4c32)cc1 ; "A2"] | H1 | 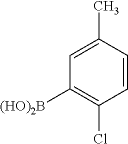 | H6 | 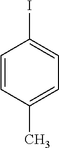 | 484 |
| 3 | 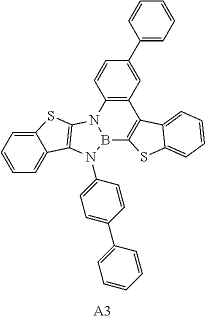 | H1 | 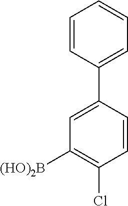 [SMILES: OB(O)c1cc(-c2ccccc2)ccc1Cl] | H6 | 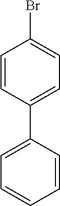 [SMILES: Brc1ccc(-c2ccccc2)cc1] | 608 |
| 4 | 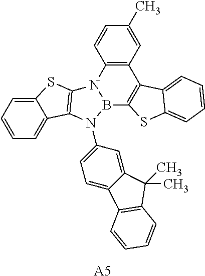 [SMILES: Cc1ccc2c(c1)-c1c(sc3ccccc13)B1N2c2sc3ccccc3c2N1c1ccc2c(c1)C(C)(C)c1ccccc1-2 ; "A5"] | H1 | 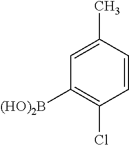 | H6 | 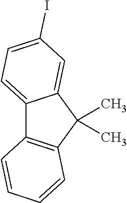 [SMILES: CC1(C)c2ccccc2-c2ccc(I)cc21] | 586 |
| 5 | 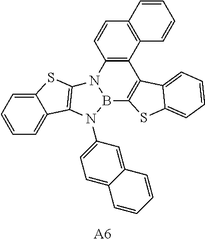 | H1 | 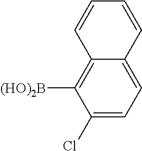 [SMILES: OB(O)c1c(Cl)ccc2ccccc12] | H6 | 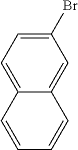 [SMILES: Brc1ccc2ccccc2c1] | 556 |
| 6 | 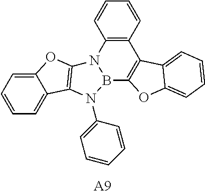 | 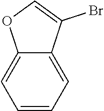 | H2 | 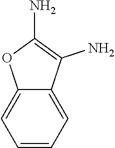 | H9 | 424 |

TABLE 4

| Ex- | | | | | | |
|---|---|---|---|---|---|---|
| ample | Exemplified compound | Raw material 1 | Raw material 2 | Raw material 3 | Raw material 4 | m/z |
| 7 | 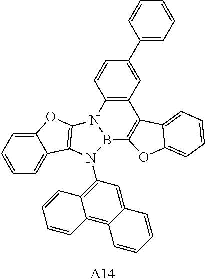 [SMILES: c1ccc(-c2ccc3c(c2)-c2c(oc4ccccc24)B2N3c3oc4ccccc4c3N2c2cc3ccccc3c3ccccc23)cc1 ; "A14"] | 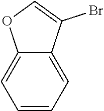 | 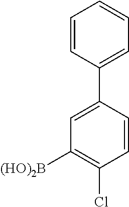 [SMILES: OB(O)c1cc(-c2ccccc2)ccc1Cl] | 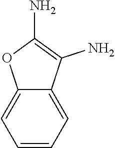 [SMILES: Nc1oc2ccccc2c1N] | 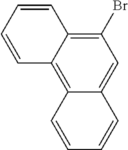 [SMILES: Brc1cc2ccccc2c2ccccc12] | 600 |
| 8 | 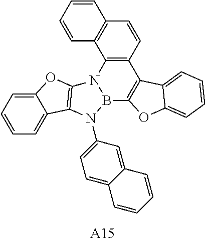 [SMILES: c1ccc2cc(N3B4c5oc6ccccc6c5-c5ccc6ccccc6c5N4c4oc5ccccc5c43)ccc2c1 ; "A15"] | 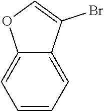 | 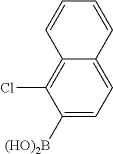 [SMILES: OB(O)c1ccc2ccccc2c1Cl] | 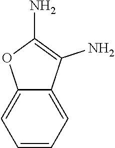 [SMILES: Nc1oc2ccccc2c1N] | 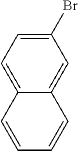 [SMILES: Brc1ccc2ccccc2c1] | 524 |
| 9 | 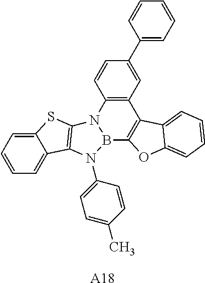 [SMILES: Cc1ccc(N2B3c4oc5ccccc5c4-c4cc(-c5ccccc5)ccc4N3c3sc4ccccc4c32)cc1 ; "A18"] | 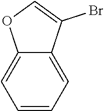 | 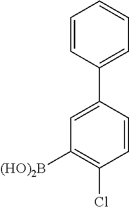 [SMILES: OB(O)c1cc(-c2ccccc2)ccc1Cl] | H6 | 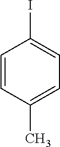 | 530 |
| 10 | 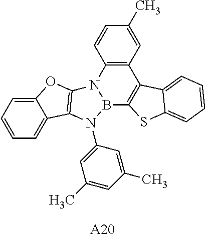 [SMILES: Cc1cc(C)cc(N2B3c4sc5ccccc5c4-c4cc(C)ccc4N3c3oc4ccccc4c32)c1 ; "A20"] | H1 | 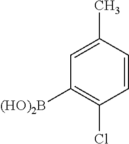 | 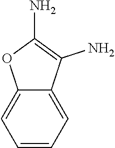 [SMILES: Nc1oc2ccccc2c1N] | 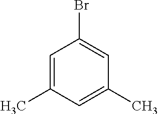 | 482 |
| 11 | 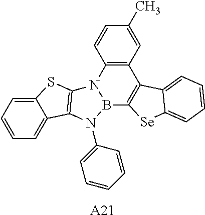 | 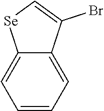 | 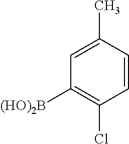 | H6 | H9 | 518 |

TABLE 5

| Ex- | | | | | | |
|---|---|---|---|---|---|---|
| ample | Exemplified compound | Raw material 1 | Raw material 2 | Raw material 3 | Raw material 4 | m/z |
| 12 | 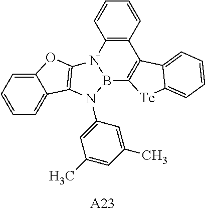 | 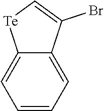 | H2 | 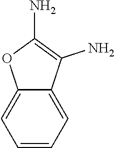 [SMILES: Nc1oc2ccccc2c1N] | 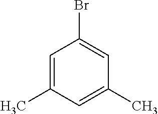 | 566 |
| 13 | 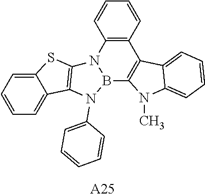 | 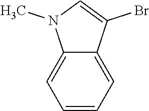 | H2 | H6 | H9 | 453 |
| 14 | 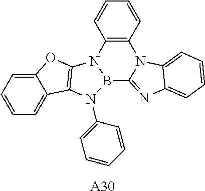 | 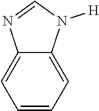 | H2 | 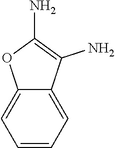 [SMILES: Nc1oc2ccccc2c1N] | H9 | 424 |
| 15 | 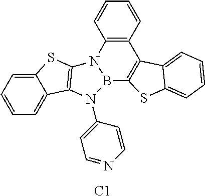 | H1 | H2 | H6 | 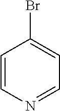 | 457 |
| 16 | 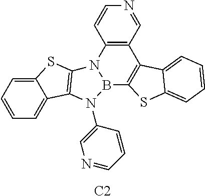 | H1 | 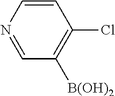 | H6 | 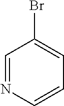 | 458 |

TABLE 6

| Ex- | | | | Raw | Raw | |
|---|---|---|---|---|---|---|
| ample | Exemplified compound | Raw material 1 | Raw material 2 | material 3 | material 4 | m/z |
| 17 | 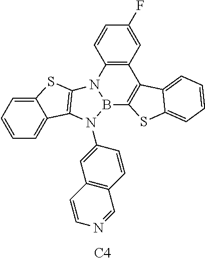 [SMILES: Fc1ccc2c(c1)-c1c(sc3ccccc13)B1N2c2sc3ccccc3c2N1c1ccc2cnccc2c1 ; "C4"] | H1 | 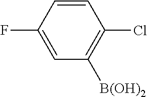 [SMILES: OB(O)c1cc(F)ccc1Cl] | H6 | 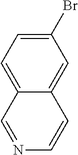 [SMILES: Brc1ccc2cnccc2c1] | 525 |
| 18 | 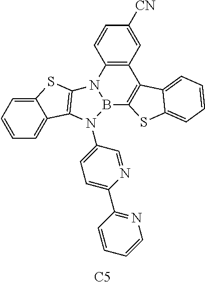 [SMILES: N#Cc1ccc2c(c1)-c1c(sc3ccccc13)B1N2c2sc3ccccc3c2N1c1ccc(-c2ccccn2)nc1 ; "C5"] | H1 | 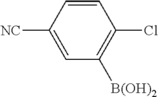 [SMILES: N#Cc1ccc(Cl)c(B(O)O)c1] | H6 | 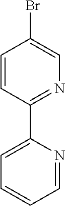 [SMILES: Brc1ccc(-c2ccccn2)nc1] | 559 |
| 19 | 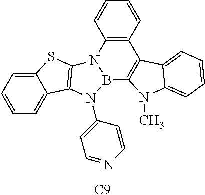 [SMILES: Cn1c2c(c3ccccc31)-c1ccccc1N1B2N(c2ccncc2)c2c1sc1ccccc21 ; "C9"] | 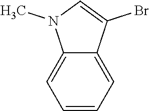 | H2 | H6 | 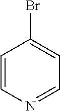 | 454 |
| 20 | 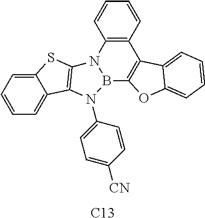 [SMILES: N#Cc1ccc(N2B3c4oc5ccccc5c4-c4ccccc4N3c3sc4ccccc4c32)cc1 ; "C13"] | 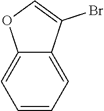 | H2 | H6 | 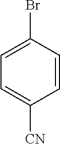 | 465 |
| 21 | 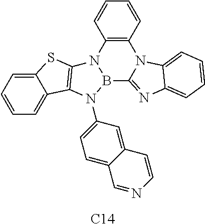 [SMILES: c1ccc2c(c1)N1B(c3nc4ccccc4n3-2)N(c2ccc3cnccc3c2)c2c1sc1ccccc21 ; "C14"] | 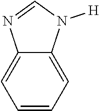 | H2 | H6 | 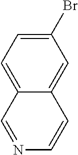 [SMILES: Brc1ccc2cnccc2c1] | 491 |

TABLE 7

| Ex- | | | | | | |
|---|---|---|---|---|---|---|
| ample | Exemplified compound | Raw material 1 | Raw material 2 | Raw material 3 | Raw material 4 | m/z |
| 22 | 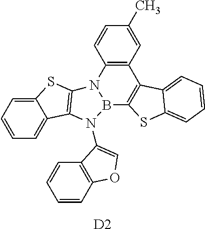 | H1 | 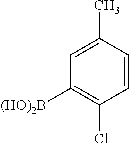 | H6 | 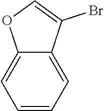 | 510 |
| 23 | 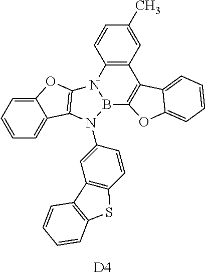 | 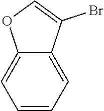 | 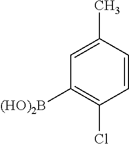 | 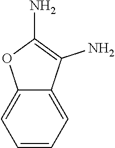 [SMILES: Nc1oc2ccccc2c1N] | 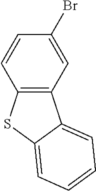 [SMILES: Brc1ccc2sc3ccccc3c2c1] | 544 |
| 24 | 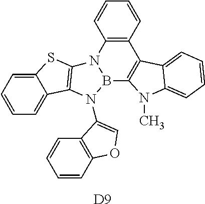 | 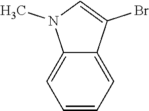 | H2 | H6 | 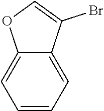 | 493 |
| 25 | 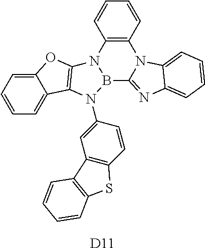 | 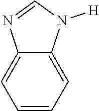 | H2 | 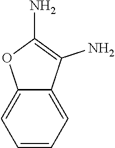 [SMILES: Nc1oc2ccccc2c1N] | 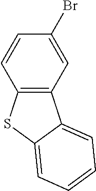 [SMILES: Brc1ccc2sc3ccccc3c2c1] | 530 |

### Example 26 (Synthesis of Exemplified Compound B1)

Exemplified compound B1 was synthesized according to the following synthesis route.

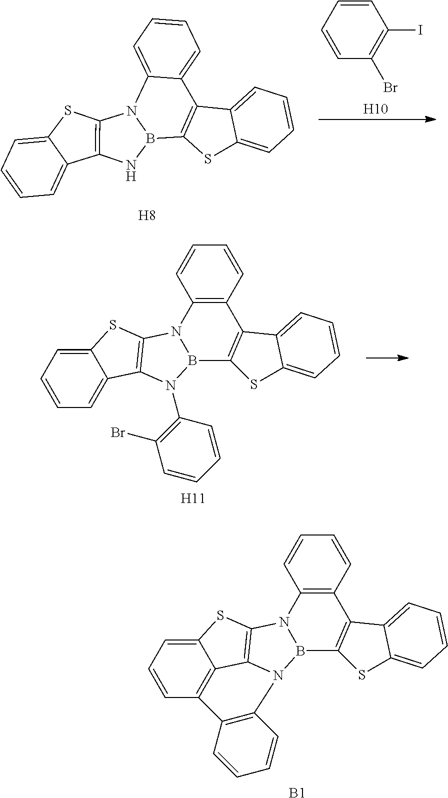

### (1) Synthesis of Compound H8

According to the method described in Example 1, H8 was synthesized from H1 through five steps.

### (2) Synthesis of Compound H11

Compounds, reagents, and a solvent below were placed in a 200-mL recovery flask.
Compound H8: 2.50 g (6.57 mmol)
Compound H10: 2.79 g (9.87 mmol)
Pd(OAc)₂: 73 mg (0.33 mmol)
Tri-o-tolylphosphine: 200 mg (0.66 mmol)
tBuOK: 1.11 g (9.86 mmol)
Xylene: 120 ml

The reaction solution was heated to 145° C. under a stream of nitrogen and stirred for 5 hours under reflux heating. After the reaction was completed, the mixture was filtered. The resulting crude product was purified by silica gel column chromatography (chlorobenzene), followed by recrystallization from toluene to give 1.76 g (yield: 50%) of white exemplified compound H1l.

### (3) Synthesis of Exemplified Compound B1

The compound, a reagent, and a solvent below were placed in a 500-mL recovery flask.
Compound H11: 1.50 g (2.80 mmol)
Aluminum chloride: 1.12 g (8.40 mmol)
Tetralin: 150 ml

The reaction solution was heated to 180° C. under a stream of nitrogen and stirred at this temperature (180° C.) for 8 hours. After completion of the reaction, 300 ml of methanol was added thereto at room temperature. The mixture was stirred for 30 minutes and then filtered. The resulting residue was recrystallized from chlorobenzene to give 254 mg (yield: 20%) of pale yellow exemplified compound B1.

Exemplified compound B1 prepared by the above process was subjected to mass spectrometry with MALDI-TOF-MS (Autoflex LRF, manufactured by Bruker). The results indicated that the calculated value obtained from C₂₈H₁₅BN₂S₂ was 454, and the measured value (m/z) was 454, which agreed with the calculated value.

### Examples 27 to 34 (Syntheses of Exemplary Compounds)

As presented in Tables 8 and 9, exemplified compounds of Examples 27 to 34 were synthesized as in Example 26, except that compound H8 of Example 26 was changed to raw material 5, and compound H10 was changed to raw material 6. The resulting exemplified compounds were subjected to mass spectrometry as in Example 1, and the measured values (m/z) are also presented.

TABLE 8

| Example | Exemplified compound | Raw material 5 | Raw material 6 | m/z |
|---|---|---|---|---|
| 27 | 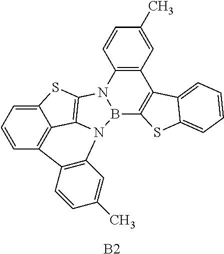 | 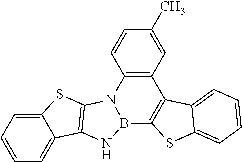 [SMILES: Cc1ccc2c(c1)-c1c(sc3ccccc13)B1Nc3c(sc4ccccc34)N12] | 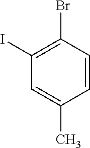 | 482 |
| 28 | 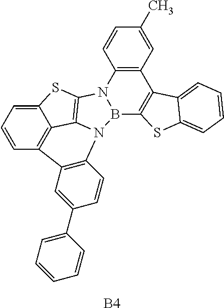 | 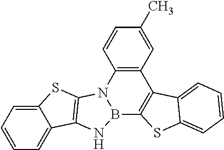 [SMILES: Cc1ccc2c(c1)-c1c(sc3ccccc13)B1Nc3c(sc4ccccc34)N12] | 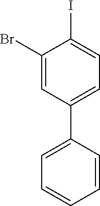 [SMILES: Brc1cc(-c2ccccc2)ccc1I] | 544 |
| 29 | 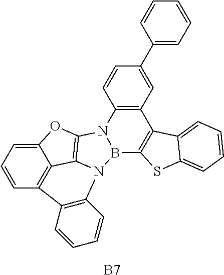 | 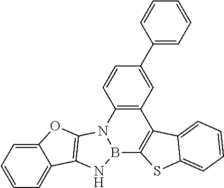 [SMILES: c1ccc(-c2ccc3c(c2)-c2c(sc4ccccc24)B2Nc4c(oc5ccccc45)N23)cc1] | H10 | 514 |
| 30 | 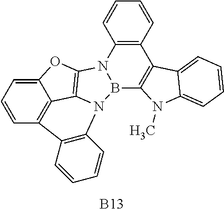 | 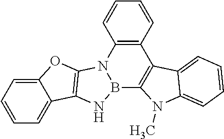 [SMILES: Cn1c2c(c3ccccc31)-c1ccccc1N1B2Nc2c1oc1ccccc21] | H10 | 435 |

TABLE 9

| Example | Exemplified compound | Raw material 5 | Raw material 6 | m/z |
|---|---|---|---|---|
| 31 | 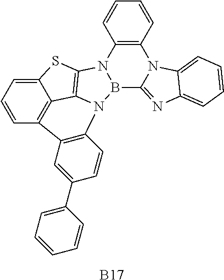 | 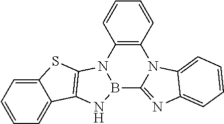 [SMILES: c1ccc2c(c1)N1B(Nc3c1sc1ccccc31)c1nc3ccccc3n1-2] | 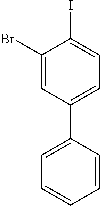 [SMILES: Brc1cc(-c2ccccc2)ccc1I] | 514 |
| 32 | 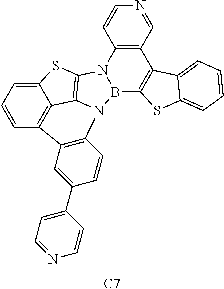 | 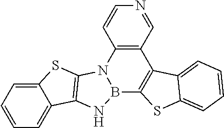 [SMILES: c1ccc2c3c(sc2c1)N1B(N3)c2sc3ccccc3c2-c2cnccc21] | 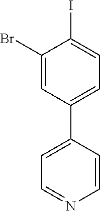 [SMILES: Brc1cc(-c2ccncc2)ccc1I] | 532 |
| 33 | 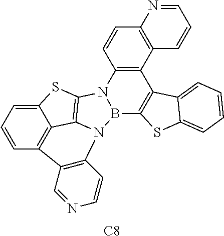 [SMILES: c1ccc2c3c(sc2c1)B1N(c2ccc4ncccc4c2-3)c2sc3cccc4c3c2N1c1ccncc1-4 ; "C8"] | 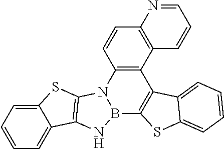 [SMILES: c1ccc2c3c(sc2c1)N1B(N3)c2sc3ccccc3c2-c2c1ccc1ncccc21] | 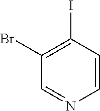 | 506 |
| 34 | 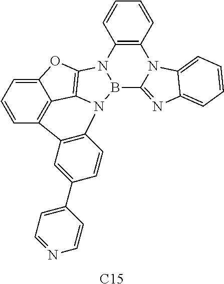 [SMILES: c1ccc2c(c1)N1B(c3nc4ccccc4n3-2)N2c3ccc(-c4ccncc4)cc3-c3cccc4oc1c2c34 ; "C15"] | 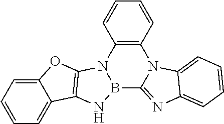 [SMILES: c1ccc2c(c1)N1B(Nc3c1oc1ccccc31)c1nc3ccccc3n1-2] | 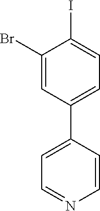 [SMILES: Brc1cc(-c2ccncc2)ccc1I] | 499 |

### Example 35

In this example, an organic light-emitting device having a bottom-emission structure was produced in which an anode, a hole injection layer, a hole transport layer, an electron-blocking layer, a light-emitting layer, a hole-blocking layer, an electron transport layer, an electron injection layer, and a cathode were sequentially formed over a substrate.

An ITO film was formed on a glass substrate and subjected to desired patterning to form an ITO electrode (anode). The ITO electrode had a thickness of 100 nm. The substrate on which the ITO electrode had been formed in this way was used as an ITO substrate in the following steps. Next, vacuum evaporation was performed by resistance heating in a vacuum chamber at 1.33×10⁻⁴ Pa (1×10⁻⁶ Torr) to successively form organic EL layers and an electrode layer presented in Table 10 over the ITO substrate.

Here, the opposing electrode (metal electrode layer, cathode) had an electrode area of 3 mm².

TABLE 10

| | | | | Thickness |
|---|---|---|---|---|
| | Material | | | (nm) |
| Cathode | Al | | | 100 |
| Electron injection | LiF | | | 1 |
| layer (EIL) | | | | |
| Electron transport | ET2 | | | 10 |
| layer (ETL) | | | | |
| Hole-blocking | ET12 | | | 20 |
| layer (HBL) | | | | |
| Light-emitting | Host | EM3 | Ratio | 30 |
| layer (EML) | Guest | A1 | by mass | |
| | | | EM3:A1 = | |
| | | | 99.3:0.7 | |

| | | |
|---|---|---|
| Electron-blocking | HT7 | 15 |
| layer (EBL) | | |
| Hole transport | HT3 | 30 |
| layer (HTL) | | |
| Hole injection | HT16 | 5 |
| layer (HIL) | | |

The characteristics of the resulting device were measured and evaluated. The light-emitting device exhibited blue light emission with a maximum current efficiency of 12.5 cd/A. With regard to measurement instruments, specifically, the current-voltage characteristics were measured with a Hewlett-Packard 4140B microammeter, and the luminance was measured with a Topcon BM7. The device was subjected to a continuous operation test at a current density of 20 mA/cm². The time when the percentage of luminance degradation reached 5% (LT95) was measured and found to be 120 hours. Table 11 presents the measurement results.

### Examples 36 to 53 and Comparative Example 1

Organic light-emitting devices were produced in the same manner as in Example 35, except that the compounds were changed to compounds given in Table 11 as appropriate. The characteristics of the resulting organic light-emitting devices were measured and evaluated as in Example 35. Table 11 presents the measurement results.

TABLE 11

| | | | | | | | | Current | | |
|---|---|---|---|---|---|---|---|---|---|---|
| | | | | EML | | | | efficiency | LT95 | Emission |
| | HIL | HTL | EBL | Host | Guest | HBL | ETL | [cd/A] | [hr] | color |
| Example 35 | HT16 | HT3 | HT7 | EM3 | A1 | ET12 | ET2 | 12.5 | 120 | Blue |
| Example 36 | HT16 | HT3 | HT12 | EM4 | A2 | ET10 | ET2 | 12.8 | 125 | Blue |
| Example 37 | HT16 | HT3 | HT8 | EM5 | A3 | ET12 | ET2 | 13.5 | 135 | Blue |
| Example 38 | HT16 | HT3 | HT12 | EM2 | A6 | ET12 | ET2 | 13.8 | 128 | Blue |
| Example 39 | HT16 | HT3 | HT12 | EM4 | A9 | ET12 | ET2 | 13.0 | 130 | Blue |
| Example 40 | HT16 | HT2 | HT10 | EM6 | A14 | ET12 | ET5 | 13.5 | 134 | Blue |
| Example 41 | HT16 | HT3 | HT12 | EM25 | A25 | ET12 | ET2 | 11.8 | 118 | Blue |
| Example 42 | HT16 | HT3 | HT8 | EM31 | A30 | ET10 | ET2 | 12.0 | 120 | Blue |
| Example 43 | HT16 | HT3 | HT12 | EM3 | B2 | ET12 | ET2 | 13.0 | 115 | Blue |
| Example 44 | HT16 | HT3 | HT12 | EM6 | B4 | ET12 | ET2 | 13.8 | 120 | Blue |
| Example 45 | HT16 | HT3 | HT12 | EM2 | B13 | ET10 | ET2 | 12.9 | 117 | Blue |
| Example 46 | HT16 | HT3 | HT12 | EM15 | B17 | ET12 | ET2 | 13.4 | 122 | Blue |
| Example 47 | HT16 | HT3 | HT12 | EM1 | C2 | ET12 | ET2 | 12.5 | 140 | Blue |
| Example 48 | HT16 | HT3 | HT12 | EM4 | C4 | ET12 | ET2 | 13.0 | 138 | Blue |
| Example 49 | HT16 | HT3 | HT12 | EM27 | C7 | ET12 | ET5 | 12.4 | 118 | Blue |
| Example 50 | HT16 | HT3 | HT12 | EM2 | C9 | ET12 | ET2 | 12.0 | 130 | Blue |
| Example 51 | HT16 | HT3 | HT9 | EM31 | D4 | ET12 | ET5 | 13.6 | 120 | Blue |
| Example 52 | HT16 | HT3 | HT12 | EM26 | D9 | ET12 | ET5 | 12.8 | 115 | Blue |
| Example 53 | HT16 | HT3 | HT9 | EM3 | D11 | ET12 | ET2 | 13.0 | 118 | Blue |
| Comparative | HT16 | HT3 | HT7 | EM3 | Comparative | ET12 | ET2 | 7.5 | 70 | Blue-violet |
| Example 1 | | | | | compound 1-a | | | | | |

From Table 11, in Comparative Example 1 in which comparative compound 1-a described in Patent Literature 1 was used, the current efficiency was 7.5 cd/A or less, and the 5% degradation lifetime (LT95) was 70 hours or less, which were inferior to the current efficiencies and the durability characteristics of the blue light-emitting devices of the examples. In contrast, the light-emitting devices of the examples in which the organic compounds of the present embodiment were used exhibited good durability characteristics. This is because each of the organic compounds according to the present embodiment has a diazaborole skeleton having a fused-ring structure, has an emission wavelength suitable for blue light emission, is stable as a molecular structure due to the fused-ring structure, has a low LUMO level, and has high stability against oxygen.

### Example 54

An organic light-emitting device was produced in the same manner as in Example 35, except that the compounds were changed to compounds given in Table 12 as appropriate.

TABLE 12

| | | | | Thickness |
|---|---|---|---|---|
| | Material | | | (nm) |
| Cathode | Al | | | 100 |
| Electron injection | LiF | | | 1 |
| layer (EIL) | | | | |
| Electron transport | ET2 | | | 10 |
| layer (ETL) | | | | |
| Hole-blocking | ET12 | | | 20 |
| layer (HBL) | | | | |
| Light-emitting | First host | EM3 | Ratio by mass | 30 |
| layer (EML) | Second | A2 | EM3:A2:GD1 = | |
| | host | | 89.5:10.0:0.5 | |
| | Guest | GD1 | | |

| | | |
|---|---|---|
| Electron-blocking | HT7 | 15 |
| layer (EBL) | | |
| Hole transport | HT3 | 30 |
| layer (HTL) | | |
| Hole injection | HT16 | 5 |
| layer (HIL) | | |

The resulting light-emitting device exhibited good green light emission. The device was subjected to a continuous operation test at a current density of 100 mA/cm² in the same manner as in Example 35. The time when the percentage of luminance degradation reached 5% (LT95) was measured and found to be more than 500 hours. Table 13 presents the measurement results.

### Examples 55 to 62, Comparative Example 2, and Comparative Example 3

Organic light-emitting devices were produced in the same manner as in Example 35, except that the compounds were changed to compounds given in Table 13 as appropriate. For the resulting light-emitting devices, LT95 was measured in the same manner as in Example 54. Table 13 presents the measurement results. In Examples 60 to 62, only the first host was used as the host, and the guest content of each light-emitting layer was set to be equal to that in Examples 55 to 59.

TABLE 13

| | EML | | | Emission | LT95 |
|---|---|---|---|---|---|
| | First host | Second host | Guest | color | [hr] |
| Example 54 | EM3 | A2 | GD1 | Green | 510 |
| Example 55 | EM4 | A14 | GD1 | Green | 550 |
| Example 56 | EM26 | D4 | GD1 | Green | 530 |
| Example 57 | EM3 | A5 | RD1 | Red | 610 |
| Example 58 | EM4 | B4 | RD1 | Red | 650 |
| Example 59 | EM25 | C4 | RD1 | Red | 680 |
| Example 60 | A30 | — | GD1 | Green | 520 |
| Example 61 | D11 | — | GD1 | Green | 560 |
| Example 62 | C14 | — | RD1 | Red | 600 |
| Comparative | EM4 | Comparative | GD1 | Green | 350 |
| Example 2 | | compound 1-a | | | |
| Comparative | Comparative | — | RD1 | Red | 380 |
| Example 3 | compound 1-a | | | | |

Table 13 indicates that in each of Comparative Example 2 and 3, the 5% degradation lifetime was 500 hours or less, which indicates poor durability characteristics, and in each of the light-emitting devices in which the organic compounds according to the present embodiment were used, the 5% degradation lifetime was more than 500 hours, which indicates a long life. The light-emitting devices in which the organic compounds according to the present embodiment were used exhibited good durability characteristics.

### Example 63

In this Example, an organic light-emitting device having a top-emission structure was produced in which an anode, a hole injection layer, a hole transport layer, an electron-blocking layer, a first light-emitting layer, a second light-emitting layer, a hole-blocking layer, an electron transport layer, an electron injection layer, and a cathode were sequentially formed over a substrate.

A laminated film of Al and Ti was formed on a glass substrate to a thickness of 40 nm by a sputtering method, and was patterned using photolithography to form an anode. Here, the opposing electrode (metal electrode layer, cathode) had an electrode area of 3 mm². Subsequently, the cleaned substrate on which the electrode had been formed and materials were attached to a vacuum evaporation apparatus (available from ULVAC, Inc.). The apparatus was evacuated to 1.3×10⁻⁴ Pa (1×10⁻⁶ Torr), and then UV/ozone cleaning was performed. Thereafter, each layer was formed so as to achieve the layer configuration given in Table 14. Finally, sealing was performed in a nitrogen atmosphere.

TABLE 14

| | | | | Thickness |
|---|---|---|---|---|
| | Material | | | (nm) |
| Cathode | Mg | | Ratio by mass | 10 |
| | Ag | | Mg:Ag | |
| | | | 50:50 | |
| Electron injection | LiF | | | 1 |
| layer (EIL) | | | | |
| Electron transport | ET2 | | | 30 |
| layer (ETL) | | | | |
| Hole-blocking | ET12 | | | 75 |
| layer (HBL) | | | | |
| Second | Second host | EM1 | Ratio by mass | 10 |
| light-emitting | Second guest | A1 | EM1:A1 = | |
| layer (2nd EML) | (blue dopant) | | 99.4:0.6 | |
| First light-emitting | First host | EM1 | Ratio by mass | 10 |
| layer (1st EML) | First guest | RD1 | EM1:RD1:GD6 = | |
| | (red dopant) | | 97.2:0.3:2.5 | |
| | Third guest | GD6 | | |
| | (green dopant) | | | |

| | | |
|---|---|---|
| Electron-blocking | HT8 | 10 |
| layer (EBL) | | |
| Hole transport | HT2 | 20 |
| layer (HTL) | | |
| Hole injection | HT16 | 5 |
| layer (HIL) | | |

The resulting light-emitting device exhibited good white light emission. A continuous operation test was conducted at an initial luminance of 1,000 cd/m², and the percentage of luminance degradation after 100 hours was measured in the same manner as in Example 35. Table 15 presents the results.

### Examples 64 to 71 and Comparative Example 4

Organic light-emitting devices were produced in the same manner as in Example 63, except that the compounds were changed to compounds given in Table 15 as appropriate. The characteristics of the resulting organic light-emitting devices were measured and evaluated as in Example 63. Table 15 presents the measurement results.

TABLE 15

| | | | | | | Percentage |
|---|---|---|---|---|---|---|
| | 1st EML | | | 2nd EML | | of luminance |
| | First host | First guest | Third guest | Second host | Second guest | degradation [%] |
| Example 63 | EM1 | RD1 | GD6 | EM1 | A1 | 30 |
| Example 64 | EM1 | RD1 | GD7 | EM2 | A5 | 28 |
| Example 65 | EM1 | RD1 | GD5 | EM15 | A30 | 33 |
| Example 66 | EM26 | RD1 | GD6 | EM1 | B4 | 35 |
| Example 67 | EM4 | RD1 | GD6 | EM4 | B7 | 32 |
| Example 68 | EM25 | RD1 | GD6 | EM2 | B17 | 35 |
| Example 69 | EM4 | RD1 | GD6 | EM3 | C5 | 25 |
| Example 70 | EM1 | RD1 | GD7 | EM15 | C13 | 28 |
| Example 71 | EM4 | RD1 | GD5 | EM1 | C14 | 27 |
| Comparative | EM4 | RD1 | GD7 | EM3 | Comparative | 55 |
| Example 4 | | | | | compound 1-a | |

From Table 15, in the organic light-emitting device in which comparative compound 1-a was used, the percentage of luminance degradation was 55%. This is due to the fact that when the comparative compound is used as a guest, the compound has a high LUMO level and inferior stability against oxygen.

In contrast, the light-emitting devices of the examples in which the organic compounds of the present embodiment were used exhibited good durability characteristics. This is because each of the organic compounds according to the present embodiment has a diazaborole skeleton having a fused-ring structure, has a low LUMO level, and has high stability against oxygen.

As described above, it was found the organic compound according to the present embodiment has high luminous efficiency, high color purity, and a deep LUMO level (far from the vacuum rank), and can emit blue light. Therefore, when the organic compound according to the present embodiment is used, it is possible to provide an organic light-emitting device with excellent color purity, luminous efficiency, and durability characteristics.

The present invention is not limited to the above-described embodiments, and various changes and modifications can be made without departing from the spirit and scope of the present invention. Therefore, the following claims are attached in order to make the scope of the present invention public.

The organic compound of the present invention is a blue light-emitting material having good color purity and high oscillator strength, and thus high luminous efficiency. Therefore, when the organic compound is used in an organic light-emitting device, particularly in a light-emitting layer in an organic light-emitting device, it is possible to provide an organic light-emitting device that is excellent in color purity, luminous efficiency, and durability.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An organic compound represented by any of the following general formulae [1-1] and [1-2]: 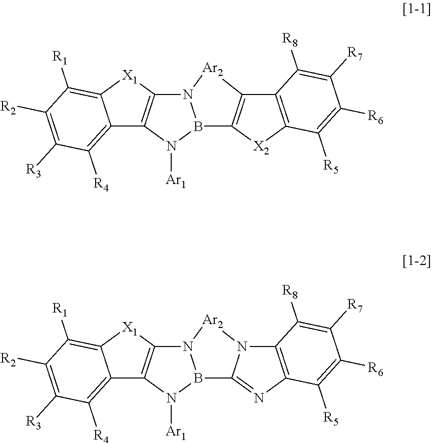
where in formulae [1-1] and [1-2], R₁ to R₈ are each independently selected from a hydrogen atom, a halogen atom, a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a cyano group, a silyl group, and a deuterium atom, provided that R₄ is optionally combined with Ar₁ to form a ring,
Ar₁ is a substituted or unsubstituted aryl group or a substituted or unsubstituted heterocyclic group,
Ar₂ is a substituted or unsubstituted divalent arylene group or a divalent linking group derived from a heterocyclic group,
X₁ and X₂ are each independently selected from an oxygen atom, a sulfur atom, a selenium atom, a tellurium atom, and a nitrogen atom having substituent Z, and the substituent Z is selected from a hydrogen atom, a substituted or unsubstituted alkyl group, a substituted or unsubstituted aryl group, a substituted or unsubstituted heteroaryl group, and a deuterium atom.

2. The organic compound according to claim 1, wherein the organic compound is represented by any of the following general formulae [2-1] and [2-2]:

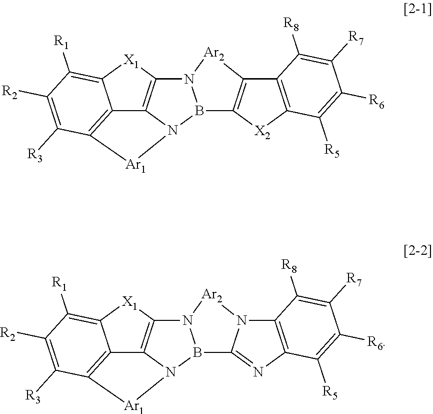

3. The organic compound according to claim 1, wherein the organic compound is represented by any of the following general formulae [3-1] and [3-2]: 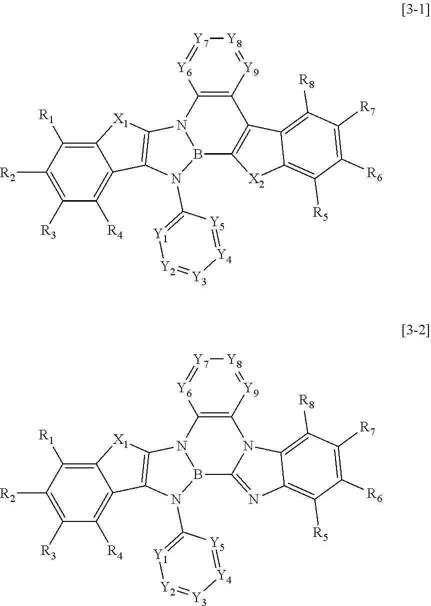
where in each of formulae [3-1] and [3-2], Y₁ to Y₉ are each independently a carbon atom or a nitrogen atom, each of the carbon atom and the nitrogen atom has a hydrogen atom or substituent W₁ and constitutes a ring, when adjacent elements are carbon atoms, these carbon atoms further optionally form a ring, and
the substituent W₁ is selected from a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a cyano group, a silyl group, and a deuterium atom.

4. The organic compound according to claim 2, wherein the organic compound is represented by any of the following general formulae [4-1] and [4-2]: 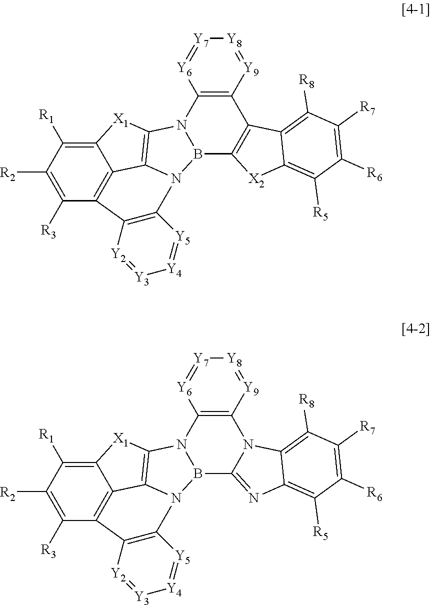
where in each of formulae [4-1] and [4-2], Y₂ to Y₉ are each independently a carbon atom or a nitrogen atom, each of the carbon atom and the nitrogen atom has a hydrogen atom or substituent W₂ and constitutes a ring, when adjacent elements are carbon atoms, these carbon atoms further optionally form a ring, and
the substituent W₂ is independently selected from a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a cyano group, a silyl group, and a deuterium atom.

5. The organic compound according to claim 1, wherein the organic compound is represented by any of the following general formulae [5-1] and [5-2]: 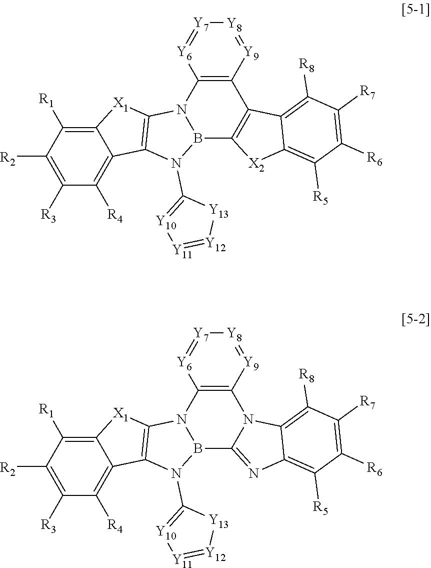
where in each of formulae [5-1] and [5-2], Y₆ to Y₉ are each independently a carbon atom or a nitrogen atom, each of the carbon atom and the nitrogen atom has a hydrogen atom or substituent W₃ and constitutes a ring,
Y₁₀ to Y₁₃ are each a carbon atom, a nitrogen atom, an oxygen atom, or a sulfur atom, each of the carbon atom, the nitrogen atom, the oxygen atom, and the sulfur atom has a hydrogen atom or substituent Q₁ and constitutes a ring, one of Y₁₀ to Y₁₃ is the nitrogen atom, the oxygen atom, or the sulfur atom,
when adjacent elements of Y₆ to Y₁₃ are carbon atoms, these carbon atoms further optionally form a ring, and
the substituents W₃ and Q₁ are each independently selected from a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a cyano group, a silyl group, and a deuterium atom.

6. The organic compound according to claim 1, wherein the organic compound is represented by any of the following general formulae [6-1] and [6-2]: 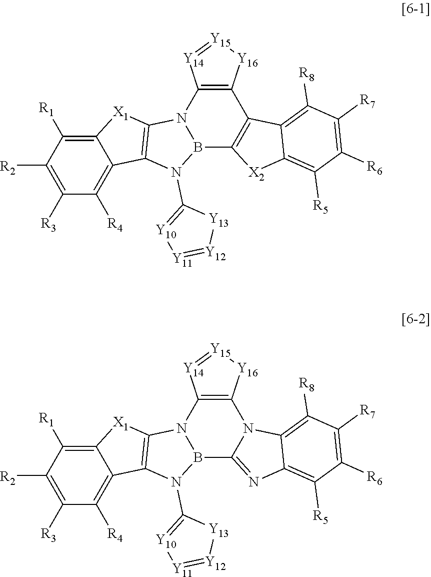
where in each of formulae [6-1] and [6-2], Y₁₀ to Y₁₆ are each independently a carbon atom, a nitrogen atom, an oxygen atom, or a sulfur atom, each of the carbon atom, the nitrogen atom, the oxygen atom, and the sulfur atom has a hydrogen atom or substituent Q₂ and constitutes a ring, one of Y₁₀ to Y₁₃ and one of Y₁₄ to Y₁₆ are each the nitrogen atom, the oxygen atom, or the sulfur atom,
when adjacent elements of Y₁₀ to Y₁₆ are carbon atoms, these carbon atoms further optionally form a ring, and
the substituent Q₂ is independently selected from a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a cyano group, a silyl group, and a deuterium atom.

7. The organic compound according to claim 3, wherein the organic compound is represented by the following general formula [7]:

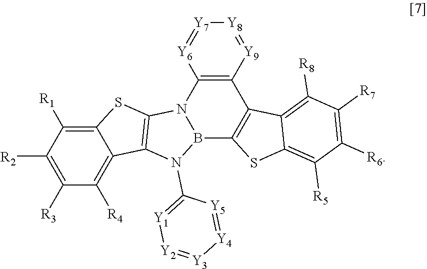

8. The organic compound according to claim 3, wherein the organic compound is represented by the following general formula [8]:

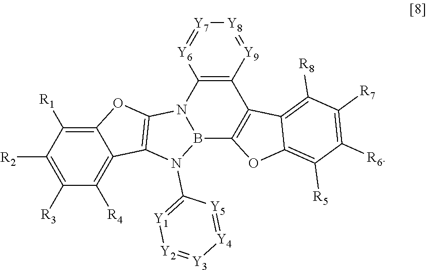

9. The organic compound according to claim 3, wherein the organic compound is represented by the following general formula [9]: 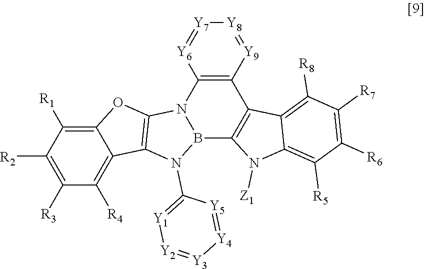
where in formula [9], substituent Z₁ is selected from a hydrogen atom, a substituted or unsubstituted alkyl group, a substituted or unsubstituted aryl group, a substituted or unsubstituted heteroaryl group, and a deuterium atom.

10. The organic compound according to claim 3, wherein the organic compound is represented by the following general formula [10]:

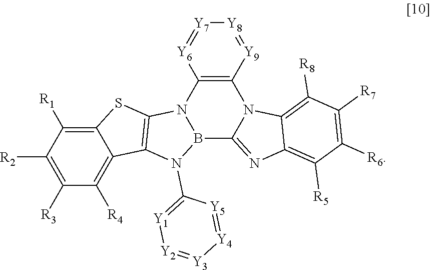

11. The organic compound according to claim 3, wherein the organic compound is represented by the following general formula [11]:

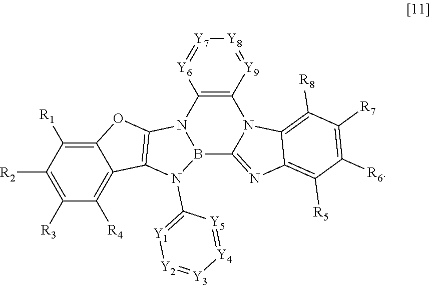

12. The organic compound according to claim 3, wherein the organic compound is represented by the following general formula [12]: 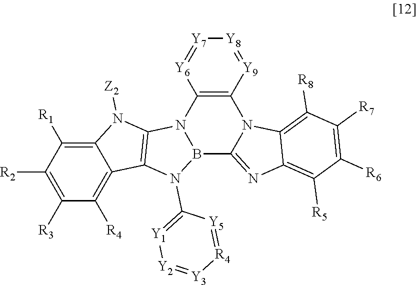
where in formula [12], substituent Z₂ is selected from a hydrogen atom, a substituted or unsubstituted alkyl group, a substituted or unsubstituted aryl group, a substituted or unsubstituted heteroaryl group, and a deuterium atom.

13. The organic compound according to claim 1, wherein in each of general formulae [1-1] and [1-2], Ar₁ is an aryl group having 10 to 14 carbon atoms or a heteroaryl group having 5 to 12 carbon atoms, and Ar₂ is an arylene group having 6 to 12 carbon atoms or a heteroarylene group having 5 carbon atoms.

14. The organic compound according to claim 13, wherein in each of general formulae [1-1] and [1-2], Ar₁ is a naphthyl group, a biphenyl group, a phenanthryl group, a dibenzothienyl group, a pyridyl group, or an isoquinolyl group, and Ar₂ is a divalent linking group derived from a phenyl group, a naphthyl group, a biphenyl group, or a pyridyl group.

15. An organic light-emitting device, comprising a pair of electrodes, and an organic compound layer disposed between the pair of electrodes, wherein at least one layer of the organic compound layer contains the organic compound according to claim 1.

16. The organic light-emitting device according to claim 15, wherein the layer containing the organic compound is a light-emitting layer.

17. The organic light-emitting device according to claim 16, wherein the light-emitting layer contains a first compound, and the first compound is a hydrocarbon compound.

18. The organic light-emitting device according to claim 17, wherein the first compound contains a fused polycyclic group having three or more rings.

19. The organic light-emitting device according to claim 18, wherein the first compound contains at least one of an anthracene skeleton, a fluoranthene skeleton, and a triphenylene skeleton.

20. The organic light-emitting device according to claim 15, wherein the organic light-emitting device emits blue light.

21. The organic light-emitting device according to claim 16, further comprising a second light-emitting layer stacked on the light-emitting layer serving as a first light-emitting layer, wherein the second light-emitting layer emits light of a color different from a color of light emitted from the first light-emitting layer.

22. The organic light-emitting device according to claim 21, wherein the organic light-emitting device emits white light.

23. A display apparatus, comprising multiple pixels, at least one of the multiple pixels including the organic light-emitting device according to claim 15 and a transistor coupled to the organic light-emitting device.

24. A photoelectric conversion apparatus, comprising an optical unit including multiple lenses, an image pickup device configured to receive light passing through the optical unit, and a display unit configured to display an image captured by the image pickup device,
wherein the display unit includes the organic light-emitting device according to claim 15.

25. An electronic apparatus, comprising a display unit including the organic light-emitting device according to claim 15, a housing provided with the display unit, and a communication unit disposed in the housing and configured to communicate with an outside.

26. A lighting apparatus, comprising a light source including the organic light-emitting device according to claim 15, and a light diffusion unit or an optical filter configured to transmit light emitted from the light source.

27. A moving object, comprising a lighting unit including the organic light-emitting device according to claim 15, and a body provided with the lighting unit.

28. An exposure light source for an electrophotographic image-forming apparatus, comprising the organic light-emitting device according to claim 15.
